(19) United States
(12) Patent Application Publication
(10) Pub. No.: US 2015/0162474 A1
(43) Pub. Date: Jun. 11, 2015

(54) SOLAR CELL MODULE AND SOLAR POWER GENERATION DEVICE

(71) Applicant: SHARP KABUSHIKI KAISHA, Osaka-shi, Osaka (JP)

(72) Inventors: Hideki Uchida, Osaka-shi (JP); Hideomi Yui, Osaka-shi (JP); Seiji Ohhashi, Osaka-shi (JP); Tsuyoshi Maeda, Osaka-shi (JP); Osamu Kawasaki, Osaka-shi (JP); Shohei Katsuta, Osaka-shi (JP)

(21) Appl. No.: 14/404,077

(22) PCT Filed: May 31, 2013
(86) PCT No.: PCT/JP2013/065295

§ 371 Date: Nov. 26, 2014

(30) Foreign Application Priority Data
Jun. 1, 2012 (JP) 2012-125933
Jun. 5, 2012 (JP) 2012-127931
Jun. 22, 2012 (JP) 2012-140822

(51) Int. Cl. H01L 31/055

(52) U.S. Cl. CPC H01L 31/055

(57) ABSTRACT

A solar cell module includes a light collector, a solar cell element, and a frame. The light collector includes a main surface and an end surface, allows the external light to be incident from the main surface and allows the light propagating through the inside to be emitted from the end surface. The solar cell element is provided so as to face the end surface and receives the light emitted from the end surface to perform photoelectric conversion. The frame holds a peripheral edge portion of the light collector. The light collector includes a through hole which is provided in the inside in relation to the frame when seen from the main surface side and penetrates the light collector in a thickness direction or a notched s portion which is provided in the inside in relation to the frame when seen from the main surface side and extends from the main surface to a rear surface in the peripheral edge portion.

### TECHNICAL FIELD

The present invention relates to a solar cell module and a solar power generation device.

The present application claims priority based on Japanese Patent Application No. 2012-125933 filed in Japan on Jun. 1, 2012, Japanese Patent Application No. 2012-127931 filed in Japan on Jun. 5, 2012, and Japanese Patent Application No. 2012-140822 filed in Japan on Jun. 22, 2012, and the contents of which are incorporated by reference herein.

### BACKGROUND ART

A solar power generation device is usually located outdoors, and therefore, dust, dirt, bird droppings or the like easily adheres to and contaminates a light incident surface that takes solar light (external light) into the inside of the device. In the solar power generation device which is contaminated with dust and the like, the power generation amount (output) is decreased as a result of the external light being blocked due to the contamination and a decrease in the amount of light taken into the device.

Such dust and the like are washed away by rainwater at the time of rainfall by providing the solar power generation device such that the light incident surface is an inclined surface. In an area other than the equator, since an orbit in diurnal motion of the sun does not pass through the zenith, a light incident surface of a solar power generation device is provided so as to be inclined with respect to the ground in most cases in order for the light incident surface to face the sun. When the solar power generation device is disposed in this manner, since the light incident surface of the solar power generation device is an inclined surface, the light incident surface is washed by rainwater at the time of rainfall so that the dust and the like are washed away.

However, when a step protrudes to the light incident surface side due to a member such as a frame constituting the solar power generation device on the lower side in the plane direction of the light incident surface, the washed-away dust and the like are accumulated because rainwater is stored in the step portion and then evaporated. Accordingly, the power generation amount is decreased in the solar power generation device. Particularly, in a solar power generation device in the related art in which a plurality of power generation elements are arranged on a light incident surface and respective power generation elements are serially connected to one another, if power generation elements positioned on the lower side of the light incident surface are covered with such dust and the like described above, the power generation amount of the whole device is extremely decreased.

In light of the problem described above, a solar power generation device having a configuration in which rainwater that is easily stored on a light incident surface is sufficiently discharged has been proposed (for example, see PTLs 1 to 4).

Further, a solar energy converter described in PTL 5 is known as a solar power generation device in which a solar cell element is disposed on an end surface of a light collector and performs power generation by allowing light propagating through the inside of the light collector to be incident on the solar cell element. Such a solar energy converter performs power generation by causing a phosphor to emit light using solar light incident on a light-transmitting substrate and allowing fluorescence radiated from the phosphor to propagate to a solar cell provided on the end surface of the light-transmitting substrate.

In addition, PTL 6 discloses a solar cell module including a frame which is provided along each side of a solar cell panel and fixes a peripheral edge portion of the solar cell panel.

### CITATION LIST

### Patent Literature

PTL 1: Japanese Unexamined Patent Application Publication No. 9-228595

PTL 2: Japanese Unexamined Patent Application Publication No. 2003-188399

PTL 3: Japanese Unexamined Patent Application Publication No. 2011-159927

PTL 4: Japanese Unexamined Patent Application Publication No. 2005-209960

PTL 5: Japanese Unexamined Patent Application Publication No. 58-49860

PTL 6: Japanese Unexamined Patent Application Publication No. 2011-54744

### SUMMARY OF INVENTION

### Technical Problem

However, from a viewpoint of realizing both prevention of contamination from remaining on the light incident surface and efficient power generation, there is room for improvement in the solar power generation devices described in patent literatures described above.

Further, when a solar cell panel and a solar cell element are not sufficiently fixed by a frame, the frame is displaced due to external force and an impact may be applied to the solar cell element in some cases.

Meanwhile, when the solar cell panel and the solar cell element are rigidly fixed by the frame, excessive stress may be applied to the solar cell element due to the fixation in some cases.

Moreover, when the solar cell panel and the solar cell element are held and fixed by the frame without any gaps, there is no place for the stress, which is generated due to warp, bending, thermal expansion, or the like of the solar cell panel, to escape and thus the excessive stress may be applied to the solar cell element in some cases.

In these cases, the solar cell element may be damaged.

In light of the above-described problems, an object of the present invention is to provide a solar cell module capable of realizing both the prevention of contamination from remaining on a light incident surface and efficient power generation. Further, another object is to provide a solar cell device which includes such a solar cell module and easily maintains high power generation efficiency for a long period of time.

Further, still another object of the present invention is to provide a solar cell module capable of suppressing damage to a solar cell element and a solar power generation device using the solar cell module.

### Solution to Problem

In order to solve the above-described problems, according to an aspect of the present invention, there is provided a solar cell module including: a light collector which includes an end surface, allows external light to be incident from the main surface, and allows the light to propagate through the inside to be emitted from the end surface; a solar cell element facing the end surface and receiving the light emitted from the end surface to perform photoelectric conversion; and a frame which holds a peripheral edge portion of the light collector, in which the light collector includes a through hole which is provided in the inside in relation to the frame when seen from the main surface side and penetrates the light collector in a thickness direction, or includes a notched portion which is provided in the inside in relation to the frame when seen from the main surface side and extends from the main surface to a rear surface in the peripheral edge portion.

Further, according to the aspect of the present invention, the through hole or the notched portion and the solar cell element may be provided on opposite sides with respect to a center line of the light collector.

Further, according to the aspect of the present invention, the surface of the through hole or the notched portion may be a reflective surface that reflects the light propagating through the inside of the light collector.

Further, according to the aspect of the present invention, the surface of the through hole or the notched portion may be formed to be orthogonal to the main surface.

Further, according to the aspect of the present invention, the main surface may be subjected to a hydrophilic treatment.

Further, according to the aspect of the present invention, the solar cell module may include a plurality of solar cell elements, and at least some of the plurality of solar cell elements may be connected in parallel with each other.

Further, according to the aspect of the present invention, the light collector includes the notched portion, a plurality of the light collectors may allow each of the notched portions adjacent to one another to be arranged in a concentric circle shape such that a large-sized light collector in a concave shape is formed, and the plurality of notched portions may be integrated with one another to form a through hole penetrating the large-sized light collector.

Further, according to the aspect of the present invention, at least the main surface of the light collector may be in a concave shape, and the through hole which penetrates the light collector in the thickness direction may be provided in a position most recessed in the main surface.

Further, according to the aspect of the present invention, the solar cell module may further include a position restricting member that restricts a relative position between the light collector and the frame, the light collector may include the through hole, the through hole may be provided in a portion in which the light collector is overlapped with the frame when seen from a direction normal to the main surface, and the position restricting member may be provided in the through hole.

Further, according to the aspect of the present invention, the position restricting member may restrict the relative position between the light collector and the frame in a direction parallel to the main surface.

Further, according to the aspect of the present invention, the penetrating member may be a screw.

Further, according to the aspect of the present invention, a screw hole may be provided in a portion in which the frame is overlapped with the through hole, and the screw may be fixed to the screw hole through the through hole.

Further, according to the aspect of the present invention, the frame may include a first sub-frame and a second sub-frame, and the screw hole may be provided in a portion in which the first sub-frame is overlapped with the through hole.

Further, according to the aspect of the present invention, a forming material of the penetrating member may be a metal.

Further, according to the aspect of the present invention, a reflective film may be formed on the surface of the penetrating member.

Further, according to the aspect of the present invention, a reflective film may be formed between the through hole and the penetrating member.

Further, according to the aspect of the present invention, a shape of the light collector may be a rectangle in a plan view, when a length of a long side of the light collector is set as L31, a length of a short side of the light collector is set as L32, a distance from the short side of the light collector to a position in which the light collection amount is 10% of the maximum light collection amount in the longitudinal direction is set as M31, and a distance from the long side of the light collector to a position in which the light collection amount is 10% of the maximum light collection amount in the short direction is set as M32, the distance M31 may satisfy a relationship of “M31=L31/10” and the distance M32 may satisfy a relationship of “M32=L32/10”, and in this case, the through hole may be arranged in an arrangement region to which the distances M31 and M32 are set.

Further, according to the aspect of the present invention, the frame may be formed so as to cover the solar cell element.

Further, according to the aspect of the present invention, an inner wall surface of the frame may be separated from the solar cell element.

Further, according to the aspect of the present invention, a space may be provided between the inner wall surface of the frame and a surface on the opposite side of the end surface of the solar cell element.

Further, according to the aspect of the present invention, when an interval of the space is set as d3, a maximum value of a temperature difference of the light collector due to a change in temperature per unit time is set as ΔT, a distance from a position restricting portion to the end surface of the light collector is set as L3, and a linear expansion coefficient of the light collector is set as K, the interval d3 may satisfy a relationship of “d3>ΔT·L3K.”

Further, according to the aspect of the present invention, a buffering material may be provided between the inner wall surface of the frame and the surface on the opposite side of the end surface of the solar cell element.

Further, according to the aspect of the present invention, a reflective layer may be provided between the light collector and the frame.

Further, according to the aspect of the present invention, the reflective layer may be arranged in a portion between the light collector and the frame, and a portion in which the reflective layer is not arranged may be provided with an air layer being interposed between the light collector and the frame.

Further, according to the aspect of the present invention, a reflector which reflects light transmitted from a second main surface side of the light collector may be provided on the second main surface side which is the opposite side of the first main surface of the light collector.

Further, according to the aspect of the present invention, the light collector may be a phosphor light collector containing a phosphor which absorbs incident light and emits fluorescence.

Further, according to the aspect of the present invention, a solar power generation device including the solar cell module described above may be provided.

According to another aspect of the present invention, there is provided a solar cell module including: a light collector which includes a first main surface and an end surface, allows external light to be incident from the first main surface, and allows the light to propagate through the inside to be collected on the end surface; a solar cell element which receives the light collected on the end surface of the light collector; and a frame which holds the end surface of the light collector, in which the frame is arranged so as to cover the solar cell element, the solar cell element is fixed to one of the light collector and the frame and not fixed to the other, and a space is provided between the other and the solar cell element.

Further, in the solar cell module according to the another aspect of the present invention, the light collector may have a second main surface on the opposite side of the first main surface of the light collector, and the solar cell element may be fixed to the first main surface or the second main surface of the light collector.

Further, in the solar cell module according to the another aspect of the present invention, a reflective layer which reflects light propagating through the inside of the light collector may be further provided, one of the first main surface and the second main surface of the light collector may be fixed to the solar cell element, and the reflective layer may be provided in a portion facing the solar cell element in the other one of the first main surface and the second main surface side.

Further, in the solar cell module according to the another aspect of the present invention, a reflective layer which reflects light propagating through the inside of the light collector may be provided on the end surface of the light collector or the inner surface of the frame facing the end surface of the light collector.

Further, in the solar cell module according to the another aspect of the present invention, the reflective layer may have a function of scattering the light.

Further, in the solar cell module according to the another aspect of the present invention, the frame may hold the end portion of the light collector such that the end portion thereof is interposed between the first main surface side and the second main surface side which is on the opposite side of the first main surface of the light collector.

Further, in the solar cell module according to the another aspect of the present invention, the end surface of the light collector and the inner surface of the frame may be arranged with an elastic member provided therebetween.

Further, in the solar cell module according to the another aspect of the present invention, when a thickness of the elastic member is set as t2, a maximum value of a temperature difference of the light collector due to a change of the temperature per unit time is set as δT, a length of the light collector is set as L2, and a linear expansion coefficient of the light collector is set as K, the thickness t2 may satisfy a relationship of “t2>δT×L2×K.”

Further, in the solar cell module according to the another aspect of the present invention, a drying agent may be further provided in a space between the frame and the solar cell element.

Further, in the solar cell module according to the another aspect of the present invention, at least a part of the outer surface of the frame may be a reflective surface.

Further, in the solar cell module according to the another aspect of the present invention, the end surface may be a first inclined surface which is inclined with respect to the first main surface or the second main surface, and a second inclined surface parallel to the first inclined surface may be formed on the inner surface of the frame.

Further, in the solar cell module according to the another aspect of the present invention, a reflective layer which reflects light propagating through the inside of the light collector toward the solar cell element may be provided on the first inclined surface or the second inclined surface.

Further, in the solar cell module according to the another aspect of the present invention, the light collector may have a second main surface on the opposite side of the first main surface of the light collector, the end surface may be an inclined surface which is inclined with respect to the first main surface or the second main surface, and the solar cell element may be fixed to the inclined surface of the light collector.

Further, in the solar cell module according to the another aspect of the present invention, a gap may be formed between the inclined surface and the inner surface of the frame, and when a size of the gap is set as d2, a maximum value of a temperature difference of the light collector due to a change of the temperature per unit time is set as δT, a length of the light collector is set as L2, and a linear expansion coefficient of the light collector is set as K, the size d2 of the gap may satisfy a relationship of “d2>δT×L2×K.”

Further, in the solar cell module according to the another aspect of the present invention, the light collector may include a second main surface on the opposite side of the first main surface of the light collector, and the area of a portion where the light collector is fixed to the frame on the first main surface side may be different from the area thereof on the second main surface side.

Further, in the solar cell module according to the another aspect of the present invention, a gap between the other member to which the solar cell element is not fixed between the light collector and the frame and the solar cell element may be filled with a transparent filler having elasticity.

Further, in the solar cell module according to the another aspect of the present invention, the solar cell element may be fixed to the frame, a gap between the solar cell element and the light collector may be an air layer, and a portion facing the solar cell element of the light collector may be a scattering surface.

Further, in the solar cell module according to the another aspect of the present invention, the light collector may include a second main surface on the opposite side of the first main surface of the light collector, and the frame may be divided into a lower frame to which the second main surface side is fixed and an upper frame to which the first main surface side is fixed.

According to the another aspect of the present invention, a solar power generation device includes the solar cell module.

According to still another aspect of the present invention, there is provided a solar cell module including: a light collector which includes a first main surface and an end surface, allows external light to be incident from the first main surface, and allows the light to propagate through the inside to be emitted from the end surface; a solar cell element which is provided on the end surface and receives the light emitted from the end surface to generate power; a frame which holds the light collector; and a position restricting member which is provided in a portion in which the light collector is overlapped with the frame when seen from a direction normal to the first main surface and restricts a relative position between the light collector and the frame.

Further, in the solar cell module according to the still another aspect of the present invention, the position restricting member may restrict a relative position between the light collector and the frame in a direction parallel to the first main surface.

Further, in the solar cell module according to the still another aspect of the present invention, a through hole may be provided in the light collector, the position restricting member may be a penetrating member which penetrates the through hole, and the penetrating member may be fixed to the frame.

Further, in the solar cell module according to the still another aspect of the present invention, the penetrating member may be a screw.

Further, in the solar cell module according to the still another aspect of the present invention, a screw hole may be provided in a portion in which the frame is overlapped with the through hole, and the screw may be fixed to the screw hole through the through hole.

Further, in the solar cell module according to the still another aspect of the present invention, the frame may include a first sub-frame and a second sub-frame, and the screw hole may be provided in a portion in which the first sub-frame is overlapped with the through hole.

Further, in the solar cell module according to the still another aspect of the present invention, a forming material of the penetrating member may be a metal.

Further, in the solar cell module according to the still another aspect of the present invention, a reflective film may be further included on the surface of the penetrating member.

Further, in the solar cell module according to the still another aspect of the present invention, a reflective film may be further included between the through hole and the penetrating member.

Further, in the solar cell module according to the still another aspect of the present invention, the through hole may be arranged in an outer peripheral portion of the light collector.

Further, in the solar cell module according to the still another aspect of the present invention, a shape of the light collector may be a rectangle in a plan view, when a length of a long side of the light collector is set as L31, a length of a short side of the light collector is set as L32, a distance from the short side of the light collector to a position in which the light collection amount is 10% of the maximum light collection amount in the longitudinal direction is set as M31, and a distance from the long side of the light collector to a position in which the light collection amount is 10% of the maximum light collection amount in the short direction is set as M32, the distance M31 may satisfy a relationship of “M31=L31/10” and the distance M32 may satisfy a relationship of “M32=L32/10”, and in this case, the through hole may be arranged in an arrangement region to which the distances M31 and M32 are set.

Further, in the solar cell module according to the still another aspect of the present invention, the frame may be formed so as to cover the solar cell element.

Further, in the solar cell module according to the still another aspect of the present invention, an inner wall surface of the frame may be separated from the solar cell element.

Further, in the solar cell module according to the still another aspect of the present invention, a space may be provided between the inner wall surface of the frame and a surface on the opposite side of the end surface of the solar cell element.

Further, in the solar cell module according to the still another aspect of the present invention, when an interval of the space is set as d3, a maximum value of a temperature difference of the light collector due to a change in temperature per unit time is set as ΔT, a distance from a position restricting portion to the end surface of the light collector is set as L3, and a linear expansion coefficient of the light collector is set as K, the interval d3 may satisfy a relationship of “d3>ΔT·L3·K.”

Further, in the solar cell module according to the still another aspect of the present invention, a buffering material is provided between the inner wall surface of the frame and the surface on the opposite side of the end surface of the solar cell element.

Further, in the solar cell module according to the still another aspect of the present invention, a reflective layer may be provided between the light collector and the frame.

Further, in the solar cell module according to the still another aspect of the present invention, the reflective layer may be arranged in a portion between the light collector and the frame, and a portion in which the reflective layer is not arranged may be provided with an air layer being interposed between the light collector and the frame.

Further, in the solar cell module according to the still another aspect of the present invention, the light collector may include a second main surface on the opposite side of the first main surface of the light collector and a reflector which reflects light transmitted through the second main surface side of the light collector on the second main surface on the opposite side of the first main surface of the light collector.

Further, in the solar cell module according to the still another aspect of the present invention, the light collector may be a phosphor light collector containing a phosphor which absorbs incident light and emits fluorescence.

According to the still another aspect of the present invention, a solar power generation device includes the solar cell module.

### Advantageous Effects of Invention

According to the aspects of the present invention, it is possible to provide a solar cell module capable of establishing prevention of contamination from remaining on a light incident surface and efficient power generation. Further, it is possible to provide a solar cell device which includes such a solar cell module and easily maintains high power generation efficiency for a long period of time. Furthermore, it is possible to provide a solar cell module capable of preventing a solar cell element from being damaged and a solar power generation device using the solar cell module.

### BRIEF DESCRIPTION OF DRAWINGS

FIG. 1A is a perspective view illustrating a solar cell module according to a first embodiment.

FIG. 1B is a plan view illustrating the solar cell module according to the first embodiment.

FIG. 2A is an explanatory view for describing a method of acquiring a center line of a light collector.

FIG. 2B is an explanatory view for describing the method of acquiring a center line of a light collector.

FIG. 3 is a cross-sectional view illustrating the solar cell module.

FIG. 4 is a schematic view illustrating a state of disposition of the solar cell module.

FIG. 5A is an explanatory view for describing a model test showing the influence of a decrease in the amount of power generation with respect to a position where dust or the like adheres.

FIG. 5B is an explanatory view for describing a model test showing the influence of a decrease in the amount of power generation with respect to a position where dust or the like adheres.

FIG. 5 is an explanatory view for describing a model test showing the influence of a decrease in the amount of power generation with respect to a position where dust or the like adheres.

FIG. 6A is a perspective view illustrating the solar cell module according to the first embodiment.

FIG. 6B is a plan view illustrating the solar cell module according to the first embodiment.

FIG. 6C is a schematic view illustrating the solar cell module according to the first embodiment.

FIG. 7A is a perspective view illustrating a solar cell module according to a second embodiment.

FIG. 7B is a plan view illustrating the solar cell module according to the second embodiment.

FIG. 8A is a perspective view illustrating the solar cell module according to the second embodiment.

FIG. 8B is a plan view illustrating the solar cell module according to the second embodiment.

FIG. 9 is an explanatory view illustrating a solar cell module according to a third embodiment.

FIG. 10 is an explanatory view illustrating a solar cell module according to a fourth embodiment.

FIG. 11A is a perspective view illustrating the solar cell module.

FIG. 11B is an explanatory view illustrating the solar cell module.

FIG. 12 is an exploded perspective view illustrating a solar cell module according to a fifth embodiment of the present invention.

FIG. 13 is a plan view illustrating a solar cell module according to the fifth embodiment of the present invention.

FIG. 14 is a cross-sectional view taken along line A2-A2 of FIG. 12.

FIG. 15 is a cross-sectional view illustrating a solar cell module according to a sixth embodiment of the present invention.

FIG. 16 is a cross-sectional view illustrating a solar cell module according to a seventh embodiment of the present invention.

FIG. 17 is a cross-sectional view illustrating a solar cell module according to an eighth embodiment of the present invention.

FIG. 18 is a cross-sectional view illustrating a solar cell module according to a ninth embodiment of the present invention.

FIG. 19 is a cross-sectional view illustrating a solar cell module according to a tenth embodiment of the present invention.

FIG. 20 is a cross-sectional view illustrating a solar cell module according to an eleventh embodiment of the present invention.

FIG. 21 is an exploded perspective view illustrating a solar cell module according to a twelfth embodiment of the present invention.

FIG. 22 is a plan view illustrating the solar cell module according to the twelfth embodiment of the present invention.

FIG. 23 is a cross-sectional view taken along line B2-B2 of FIG. 22.

FIG. 24A is a schematic view illustrating a method of positioning of a lower frame and a light collector.

FIG. 24B is a schematic view illustrating a method of positioning of the lower frame and the light collector.

FIG. 25A is a cross-sectional view illustrating a modified example of a solar cell module.

FIG. 25B is a cross-sectional view illustrating a modified example of a solar cell module.

FIG. 25C is a cross-sectional view illustrating a modified example of a solar cell module.

FIG. 26 is a cross-sectional view illustrating a solar cell module of a comparative example.

FIG. 27 is a schematic view illustrating a solar cell module according to a thirteenth embodiment of the present invention.

FIG. 28 is a cross-sectional view taken along line A-A of FIG. 27.

FIG. 29 is a plan view illustrating an arrangement position of a through hole provided in a light collector.

FIG. 30 is a graph illustrating a relationship between a position of the light collector in the longitudinal direction and the light collection amount of the light collector.

FIG. 31 is a cross-sectional view illustrating a solar cell module according to a fourteenth embodiment of the present invention.

FIG. 32 is a cross-sectional view illustrating a solar cell module according to a fifteenth embodiment of the present invention.

FIG. 33 is a cross-sectional view illustrating a solar cell module according to a sixteenth embodiment of the present invention.

FIG. 34 is a cross-sectional view illustrating a solar cell module according to a seventeenth embodiment of the present invention.

FIG. 35 is a cross-sectional view illustrating a solar cell module according to an eighteenth embodiment of the present invention.

FIG. 36A is a cross-sectional view illustrating a modified example of a position restricting member.

FIG. 36B is a cross-sectional view illustrating a modified example of a position restricting member.

FIG. 36C is a cross-sectional view illustrating a modified example of a position restricting member.

FIG. 36D is a cross-sectional view illustrating a modified example of a position restricting member.

FIG. 36E is a cross-sectional view illustrating a modified example of a position restricting member.

FIG. 36F is a cross-sectional view illustrating a modified example of a position restricting member.

FIG. 37 is a plan view illustrating a modified example of a light collector.

FIG. 38A is a plan view illustrating an arrangement position of a through hole provided on a light collector.

FIG. 38B is a plan view illustrating an arrangement position of a through hole provided on a light collector.

FIG. 39 is a configuration view schematically illustrating a solar power generation device.

### DESCRIPTION OF EMBODIMENTS

### First Embodiment

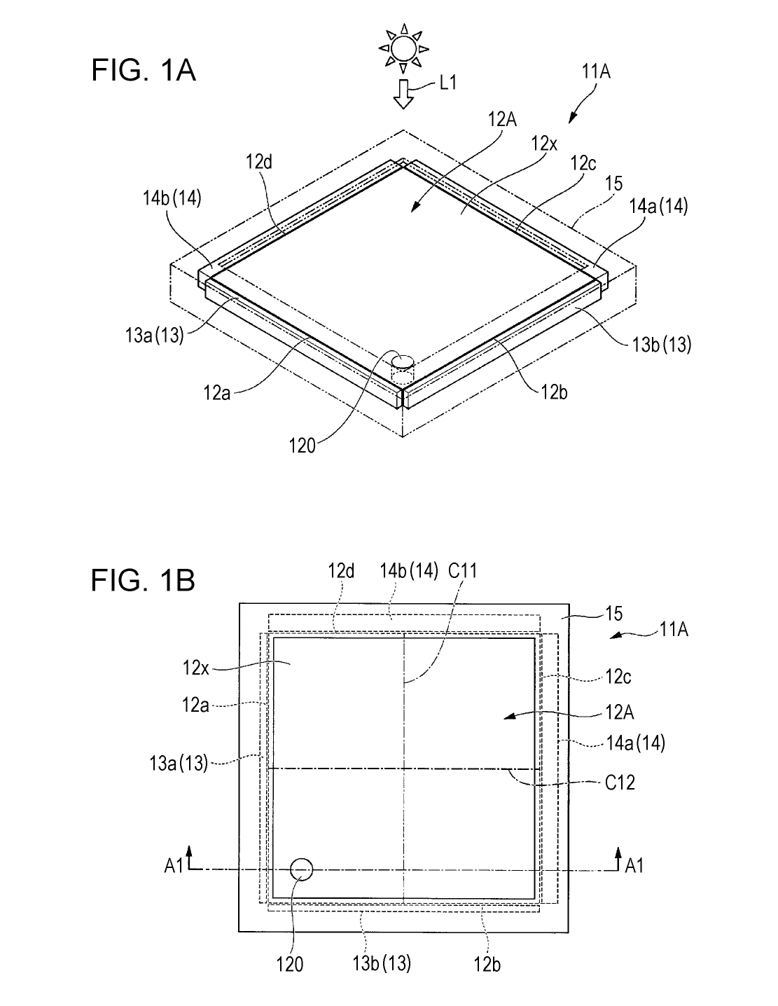

Hereinafter, a solar cell module according to a first embodiment of the present invention will be described with reference to FIGS. 1A to 6C. Further, in regard to all figures described below, for clarity of figures, dimensions or ratios of each constituent element are appropriately set to be different from the actual size thereof.

FIGS. 1A and 1B are schematic views of a solar cell module 11A according to the first embodiment. FIG. 1A is a perspective view and FIG. 1B is a plan view.

The solar cell module 11A as illustrated in the figure includes a light collector 12A having a shape of a rectangle (square) in a plan view; a reflective layer 13 and a solar cell element 14 provided on an end surface of the light collector 12A; and a frame 15 integrally holding the light collector 12A, the reflective layer 13, and the solar cell element 14 by holding a peripheral edge portion of the light collector 12A.

The light collector 12A allows external light L1 to be incident from a main surface 12x which is a light incident surface and allows the light propagating through the inside to be emitted from the end surfaces thereof. In the light collector 12A, the end surfaces in contact with the main surface 12x are a first end surface 12a, a second end surface 12b adjacent to the first end surface 12a, a third end surface 12c adjacent to the second end surface 12b and facing the first end surface 12a, and a fourth end surface 12d adjacent to the first end surface 12a and the third end surface 12c and facing the second end surface 12b.

Further, the “solar cell element” in the present specification is an element constituting the solar cell module of the present embodiment and generates the DC current by performing photoelectric conversion on light received by a light receiving surface in the inside thereof.

Moreover, the “solar cell module” in the present specification is a constituent unit including the solar cell element and the light collector described above, and the solar cell element performs photoelectric conversion using light collected on the end surface of the light collector to generate the DC current.

Further, the “solar power generation device” in the present specification described below has another configuration which functions by energizing the DC current generated by the solar cell module using a combination of one or more solar cell modules.

A reflective layer 13a is provided on the first end surface 12a and a reflective layer 13b is provided on the second end surface 12b. Further, a solar cell element 14a which faces the third end surface 12c and receives light emitted from the third end surface 12c to perform photoelectric conversion and a solar cell element 14b which faces the fourth end surface 12d and receives light emitted from the fourth end surface 12d to perform photoelectric conversion are provided. The solar cell elements 14a and 14b are connected to each other in parallel.

In addition, the light collector 12A includes a cylindrical through hole 120 penetrating the light collector 12A in the thickness direction. The through hole 120 and the solar cell elements 14a and 14b are provided on the opposite sides with respect to a center line of the light collector 12A. The through hole 120 is provided in a state of being exposed from the frame 15 in a plan view in the vicinity of a corner portion adjacent to the first end surface 12a and the second end surface 12b of the light collector 12A. The through hole 120 is provided in the inside in relation to the frame 15 in a plan view in the vicinity of the corner portion formed by the first end surface 12a and the second end surface 12b.

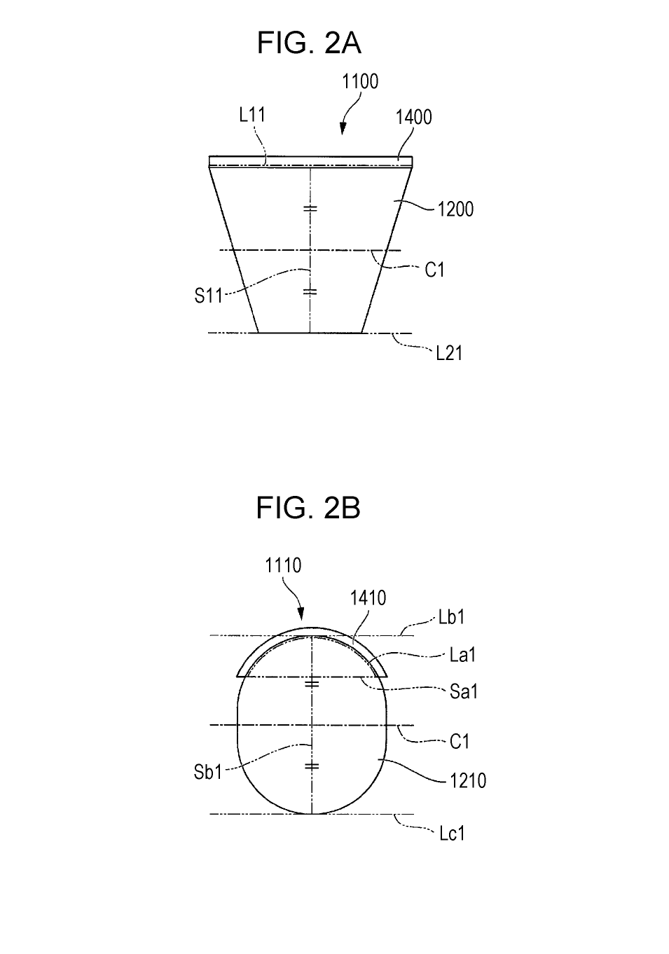

The center line of the light collector is determined as illustrated in FIGS. 2A and 2B in consideration of one solar cell element included in the solar cell module.

As a solar cell module 1100 illustrated in FIG. 2A, in a case where the light receiving surface facing the end portion of a light collector 1200 in a considered solar electronic element 1400 is flat, first, a line segment which is a line (hereinafter, also referred to as a “first reference line L11”) corresponding to the light receiving surface in the plan view is assumed.

Next, a line (hereinafter, also referred to as “opposing line L21”) parallel to first reference line L11 and in contact with the contour of the light collector 1200 in a position farthest from first reference line L11 in a plan view is assumed.

Next, line segment S11 which is orthogonal to first reference line L11 and opposing line L21 and whose both ends are an intersection with first reference line L11 and an intersection with opposing line L21 is assumed. A straight line which is a perpendicular bisector of line segment S11 and parallel to the main surface of the light collector 1200 is set as center line C1 to be acquired.

In addition, as a solar cell module 1110 illustrated in FIG. 2B, in a case where a light receiving surface of a considered solar electronic element 1410 is a curved surface, first, a line segment (a bowstring Sa1) connecting both ends of first reference line La1 which is a curved line is assumed.

Next, a line (hereinafter, also referred to as a “second reference line Lb1”) which is a line segment parallel to the bowstring Sa1 and in contact with the contour of the light collector 1210 in a position farthest from the bowstring Sa1 of first reference line La1 in the end surface on which the solar cell element is arranged is assumed.

Next, opposing line Lc1 parallel to second reference line Lb1 and in contact with the contour of the light collector 1210 in a position farthest from second reference line Lb1 in a plan view is assumed.

Next, line segment Sb1 which is orthogonal to second reference line Lb1 and opposing line Lc1 and whose both ends are an intersection with second reference line Lb1 and an intersection with the opposing line Lc1 is assumed. A straight line which is a perpendicular bisector of line segment Sb1 and parallel to the main surface of the light collector 1210 is set as center line C1 to be acquired.

For example, in a case where the light collector is a point symmetrical figure in a plan view, the center line passes through a rotation center (symmetric point) in a plan view according to the above-described definition.

In FIG. 1B, the through hole 120 and the solar cell element 14a are provided on the opposite sides with respect to a center line C11 of the light collector 12A. Moreover, the through hole 120 and the solar cell element 14b are provided on the opposite sides with respect to a center line C12 of the light collector 12A.

In the solar cell module of the present embodiment, as the shape of the light collector in a plan view, various shapes such as a rectangle, a trapezoid, a circle, an ellipse, and a polygon can be used, but the light collector having any of the shape above includes a through hole on the opposite side of the solar cell element by the center line being interposed, which is to be determined by the definition described above.

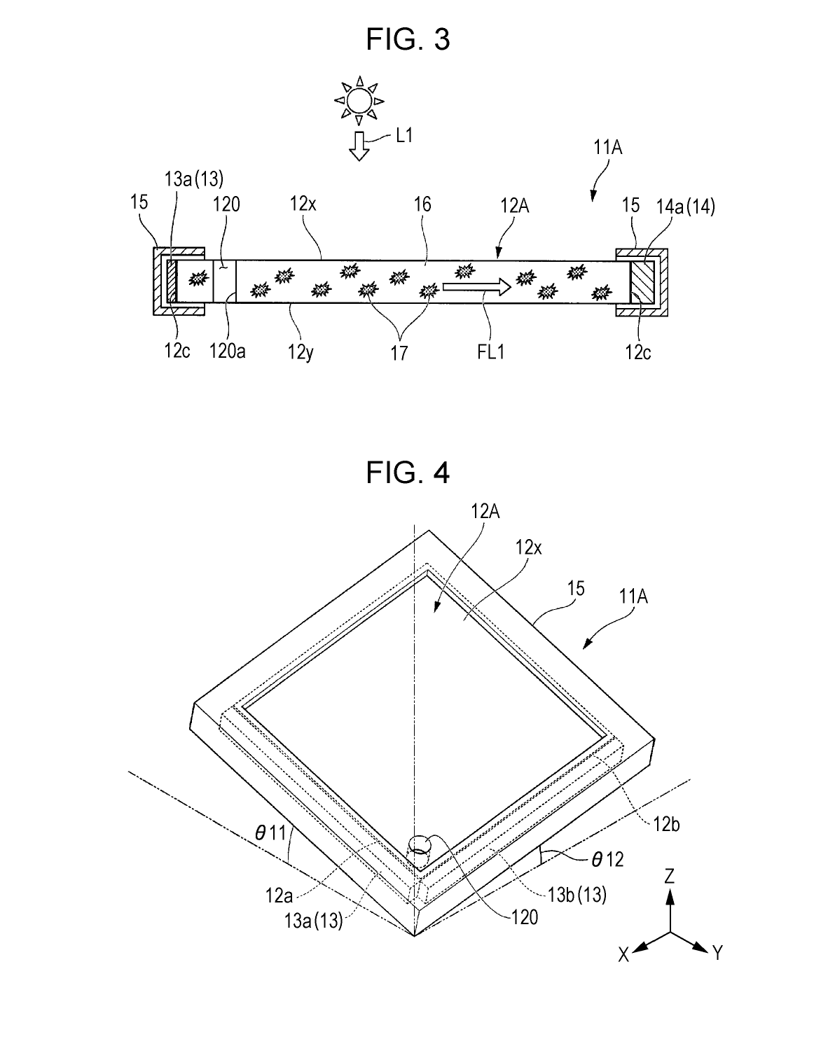

FIG. 3 is a cross-sectional view of the solar cell module 11A and a perspective cross-sectional view taken along line A1-A1 of FIG. 1B.

The light collector 12A illustrated in FIG. 3 is obtained by dispersing a phosphor 17 into a base material 16 having optical transparency. In the description below, a light collector such as the light collector 12A obtained by dispersing a phosphor into a transparent base material is referred to as a “phosphor light collector” in some cases.

As the base material 16, an acrylic resin such as PMMA, a resin material (organic material) such as a polycarbonate resin, an inorganic material such as glass or quartz, or a composite material of these can be used as long as the base material has optical transparency.

As the PMMA resin forming the base material 16, a resin made of a material that does not absorb UV rays can be used. That is, a material having transparency with respect to light having a wavelength of 400 nm or less, for example, XY-0159 (trade name, manufactured by Mitsubishi Rayon Co., Ltd.) can be used.

Solar light includes light of a massive amount of UV rays (particularly, 400 nm or less), but many resins and glass absorb UV rays. Further, in recent years, a UV absorber is mixed into these materials to absorb UV rays for improving light resistance.

In a case of a material absorbing UV rays in this manner, when solar light is used as external light which is radiated to the solar cell module, a large amount of light (approximately 10% of light corresponding to UV rays among total amount of solar light to be radiated) is absorbed in the inside of the light collector 12A so as not to be used for power generation. Here, it is possible to improve power generation efficiency using a material (material having transparency with respect to light having a wavelength of 400 nm or less) which hardly absorbs light in a UV ray region as the base material 16.

The phosphor 17 is an optical functional material that absorbs UV light or visible light and emits fluorescence in a visible light region or an infrared light region to be radiated.

Preferable examples of organic phosphors include a coumarin-based pigment, a perylene-based pigment, a phthalocyanine-based pigment, a stilbene-based pigment, a cyanine-based pigment, a polyphenylene-based pigment, a xanthene-based pigment, a pyridine-based pigment, an oxazine-based pigment, a chrysene-based pigment, a thioflavin-based pigment, a perylene-based pigment, a pyrene-based pigment, an anthracene-based pigment, an acridone-based pigment, an acridine-based pigment, a fluorene-based pigment, a terphenyl-based pigment, an ethene-based pigment, a butadiene-based pigment, a hexatriene-based pigment, an oxazole-based pigment, a coumarin-based pigment, a stilbene-based pigment, a di- and triphenyl methane-based pigment, a thiazole-based pigment, a thiazine-based pigment, a naphthalimide-based pigment, and an anthraquinone-based pigment. Specific examples thereof include coumarin-based pigments such as 3-(2′-benzothiazolyl)-7-diethylaminocoumarin (coumarin 6), 3-(2′-benzoimidazolyl)-7-N,N-diethylaminocoumarin (coumarin 7), 3-(2′-N-methylbenzoimidazolyl)-7-N,N-diethylaminocoumarin (coumarin 30), and 2,3,5,6-1H,4H-tetrahydro-8-trifluoromethylquinolizine (9,9a,1-gh)coumarin (coumarin 153); naphthaleneimide-based pigments such as basic yellow 51 which is a coumarin pigment-based dye, solvent yellow 11, and solvent yellow 116; rhodamine-based pigments such as rhodamine B, rhodamine 6G, rhodamine 3B, rhodamine 101, rhodamine 110, sulforhodamine, basic violet 11, and basic red 2; pyridine-based pigments such as 1-ethyl-2-[4-(p-dimethylaminophenyl)-1,3-butadienyl]pyridium perchloride (pyridine 1); cyanine-based pigments; and oxazine-based pigments.

These pigments can be used alone or in combination of two or more kinds thereof. In the case where two or more kinds thereof are used, the amount of external light absorbed by the whole pigments to be used can be increased and the external light can be efficiently used by selecting pigments whose absorption wavelength bands of respective pigments are not overlapped with one another.

Further, various kinds of dyes (direct dyes, acidic dyes, basic dyes, and disperse dyes) can be used as a phosphor as long as the dyes are fluorescent. The phosphor 17 is approximately uniformly dispersed into the base material 16.

In such a light collector 12A, the phosphor 17 absorbs at least some of the external light L1 incident on the inside of the light collector 12A and emits the light through conversion into fluorescence FL1. The emitted fluorescence FL1 propagates through the inside of the light collector 12A, is emitted from the end surface (third end surface 12c) on which the solar cell element 14 is arranged, and then is incident on the solar cell element 14 to be used for power generation.

A surface 120a of the through hole 120 provided in the light collector 12A may be a reflective surface that reflects the fluorescence FL1 propagating through the inside of the light collector. For example, the surface 120a can be used as a reflective surface by covering the surface 120a with a reflection material such as a dielectric multilayer film such as a metal film made of silver or aluminum, or an Enhanced Specular Reflector (ESR) reflective film (manufactured by 3M Japan Limited). In this manner, it is possible to prevent leakage of the fluorescence FL1 to the outside of the light collector 12A from the surface 120a.

Further, the surface 120a of the through hole 120 may be formed to be orthogonal to the main surface 12x of the light collector 12A. When the through hole 120 is formed in this manner, it is possible to prevent leakage of the fluorescence FL1 reflected on the surface 120a to the outside from the main surface 12x or the rear surface of the light collector 12A.

Further, illustration thereof is omitted, but a reflective layer that reflects light leaking to the outside of the light collector 12A from the rear surface on the inside of the light collector 12A may be provided on the rear surface facing the main surface 12x of the light collector 12A.

The reflective layer 13a illustrated in FIG. 3 can be formed using a reflection material such as a metal film made of silver or aluminum, or an ESR reflective film (manufactured by 3M Japan Limited). The reflective layer 13a is provided such that the reflective layer 13a is in contact with the end surface of the light collector 12A through an air layer or is in direct contact with the end surface thereof without an air layer therebetween.

In a case where the fluorescence FL1 propagating through the light collector 12A reaches the first end surface 12a, the reflective layer 13a reflects the fluorescence FL1 to the inside of the light collector 12A, and the fluorescence FL1 is emitted from the third end surface 12c on which the solar cell element 14a is arranged or from the fourth end surface 12d on which the solar cell element 14b illustrated in FIGS. 1A and 1B is arranged. In this manner, it is possible to efficiently perform photoirradiation on the solar cell element 14.

The reflective layer 13a may be a mirror reflective layer that performs mirror-reflection on incident light or may be a scattering reflective layer that performs scattering reflection on incident light. In a case where a scattering reflective layer is used for the reflective layer 13a, since the light amount of light directly heading for a direction of the solar cell element 14 is increased, light collection efficiency with respect to the solar cell element 14 is increased so that the power generation amount is increased. Further, since reflected light is scattered, a change in power generation amount due to the time or the season is averaged. In addition, as a scattering reflective layer, microfoam polyethylene terephthalate (PET) (manufactured by Furukawa Electric Co., Ltd.) or the like can be used.

In addition, a configuration which is the same as that of the above-described reflective layer 13a can be employed to the reflective layer 13b illustrated in FIGS. 1A and 1B.

The solar cell element 14a is arranged such that the light receiving surface faces the third end surface 12c of the light collector 12A.

It is preferable that the solar cell element 14a be adhered (optically adhered) such that light loss in the interface with the third end surface 12c can be prevented to a minimum.

As the solar cell element 14a, a known solar cell such as a silicon-based solar cell, a compound-based solar cell, a quantum dot solar cell, or an organic solar cell can be used. Among these, a compound-based solar cell or a quantum dot solar cell is preferable because power generation with high efficiency is possible.

Further, it is preferable that the solar cell element 14a be capable of performing photoelectric conversion on the wavelength of the fluorescence FL1 emitted by the phosphor 17 included in the light collector 12A with high efficiency.

Examples of the compound-based solar cell include solar cells using InGaP, GaAs, InGaAs, AlGaAs, Cu(In,Ga)Se2, Cu(In,Ga)(Se,S)₂, CuInS2, CdTe, or CdS. Among these, a GaAs solar cell is preferable. Further, examples of the quantum dot solar cell include solar cells using Si or InGaAs.

Further, a configuration which is the same as that of the above-described solar cell element 14a can be employed to the solar cell element 14b illustrated in FIGS. 1A and 1B.

FIG. 4 is a schematic view illustrating a state of arrangement of the solar cell module 11A. As illustrated in FIG. 4, the solar cell module 11A may be arranged by being inclined such that the elevation angle when seen from the first end surface 12a side is θ11 and the elevation angle when seen from the second end surface 12b side is θ12 with the corner portion on which the through hole 120 is arranged downward from a state in which the solar cell module is parallel to a horizontal surface (XY plane) using a support (not illustrated). For example, θ11 is 30° and θ12 is 10°.

When the solar cell module 11A is arranged in this manner, rainwater and dust or the like are discharged to the rear surface side of the light collector 12A through the through hole 120 while dust or the like adhered to the main surface 12x of the light collector 12A is washed away by rainwater.

In order for the main surface 12x to be easily washed by rainwater, the main surface 12x of the light collector 12A may be subjected to a hydrophilic treatment using a generally known method in a range without damaging a function of the solar cell module 11A that performs power generation by allowing external light to be incident on the light collector 12A from the main surface 12x.

In addition, in the present specification, the term “hydrophilicity” means that a contact angle acquired using a θ/2 method as a measurement principle is in the range of 0° to 15°. Further, the term “hydrophilic treatment” means a physical or chemical operation for providing hydrophilicity to the main surface 12x.

The main surface 12x to which the hydrophilic treatment is applied is hydrophilic and the rain falling on the main surface 12x easily wets and spreads across the whole main surface 12x. Accordingly, dust or the like adhered to the main surface 12x is not frequently washed away in a sparse manner, and thus, the dust or the like of the whole main surface 12x can be effectively washed away.

In order for dust or the like adhered to the main surface 12x to be discharged through the through hole 120, the solar cell module 11A is necessarily arranged by being inclined such that the side on which the through hole 120 is provided is positioned downward. Accordingly, the dust or the like adhered to the main surface 12x, which has not been washed away by rainwater, can be easily accumulated around the through hole 120.

However, in the solar cell module 11A, since the solar cell element is provided on the opposite side of the through hole 120 with respect to the center line of the light collector 12A, it is possible to prevent a decrease in power generation efficiency due to the dust or the like adhered to the vicinity of the through hole 120.

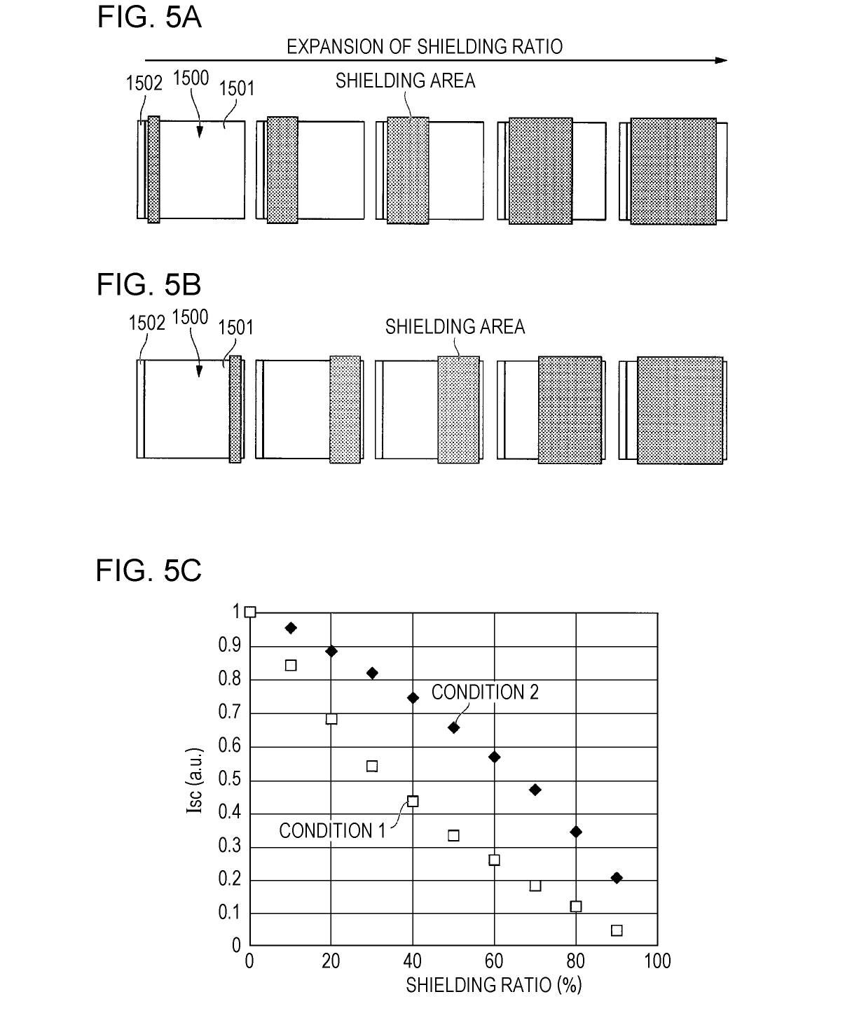

FIGS. 5A to 5C are explanatory views for describing a model test indicating the influence of a decrease in power generation amount with respect to a position of dust or the like adhered to the main surface.

As illustrated in FIGS. 5A and 5B, in the model test, a solar cell element 1502 is provided on one surface of a light collector 1501 having a square shape in a plan view and a solar cell module 1500 using the remaining three end surfaces as light absorbing surfaces is prepared. A light collector 1501 is a phosphor light collector similar to the light collector 12A.

A short-circuit current of the solar cell module 1500 with respect to a shielding ratio (ratio (%) of a shielded region with respect to the whole main surface of the light collector) is measured by shielding a part of the main surface of the light collector 1501 shielded as a model of dust or the like and then changing the shielded region.

In the test, the influence of a decrease in power generation amount with respect to the position of dust or the like adhered to the main surface is verified by comparing a case (condition 1, indicating a schematic view of FIG. 5A) where the shielding ratio of a shielded region is changed by expanding the region from the end surface side on which the solar cell element is provided with a case (condition 2, indicating a schematic view of FIG. 5B) where the shielding ratio thereof is changed by expanding the region from the end surface side facing the end surface on which the solar cell element is provided.

FIG. 5C is a graph showing the results of the model test, and the horizontal axis represents a shielding ratio (%) and the vertical axis represents a measured short-circuit current (arbitrary unit, a.u.). As is evident from the graph, even when the shielding ratios are the same as each other, it is understood that the condition 2 in which a position separated away from the solar electronic element is shielded has a smaller decrease in short-circuit current when compared to the condition 1 in which the vicinity of the solar cell element is shielded.

That is, dust or the like is easily adhered to the vicinity of the through hole 120 in the solar cell module 11A of the present embodiment, but the through hole 120 is provided on the opposite side of the solar cell element with respect to the center line of the light collector 12A so that the dust or the like is easily accumulated on a position separated away from the solar cell element. Accordingly, it is possible to prevent a decrease in power generation amount due to the dust or the like adhered to the vicinity of the through hole 120.

As described above, according to the solar cell module 11A of the present embodiment, contamination is unlikely to remain on the main surface 12x so that efficient power generation can be continuously performed.

Further, in the present embodiment, the solar cell element 14a is provided on the third end surface 12c of the solar cell module 11A, but a plurality of solar cell elements may be provided on the third end surface 12c. In the same manner, a plurality of solar cell elements may be provided on the fourth end surface 12d.

In this case, the plurality of solar cell elements provided on the same end surface may be connected in series.

Moreover, in the present embodiment, two solar cell elements 14a and 14b are used, but one solar cell element may be used. For example, in a case where only the solar cell element 14a is used, a reflective layer may be provided instead of the solar cell element 14b.

Further, the solar cell elements may be provided instead of the reflective layer 13 such that four solar cell elements are arranged so as to face all of four end surfaces of the light collector 12A.

In this case, due to the influence of contamination which is easily accumulated around the through hole 120, the power generation amount of the solar cell elements (solar cell elements 14a and 14b in the present embodiment) provided on the third end surface 12c and the fourth end surface 12d which are relatively far from the through hole 120 is larger than the power generation amount of the solar cell elements provided on the first end surface 12a and the second end surface 12b which are relatively close to the through hole 120.

Therefore, the solar cell elements provided on the third end surface 12c and the fourth end surface 12d may be connected in parallel with the solar cell elements provided on the first end surface 12a and the second end surface 12b. In this manner, it is possible to prevent a decrease in power generation efficiency of the whole power cell module due to the influence of the solar cell element whose power generation amount is small.

In addition, in the present embodiment, the shape of the through hole 120 is a cylindrical shape, but various shapes can be employed when water flowing through the main surface 12x can be discharged to the rear surface side. For example, a tubular through hole having a shape such as a rectangle, a polygon, an ellipse, or a square whose corners are rounded in a plan view can be employed.

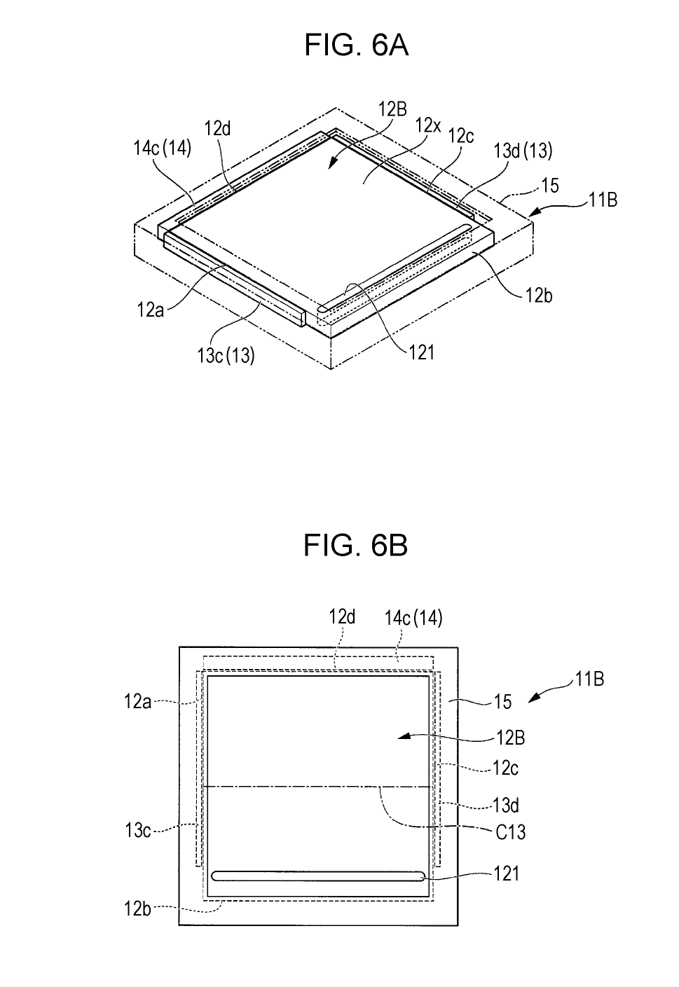

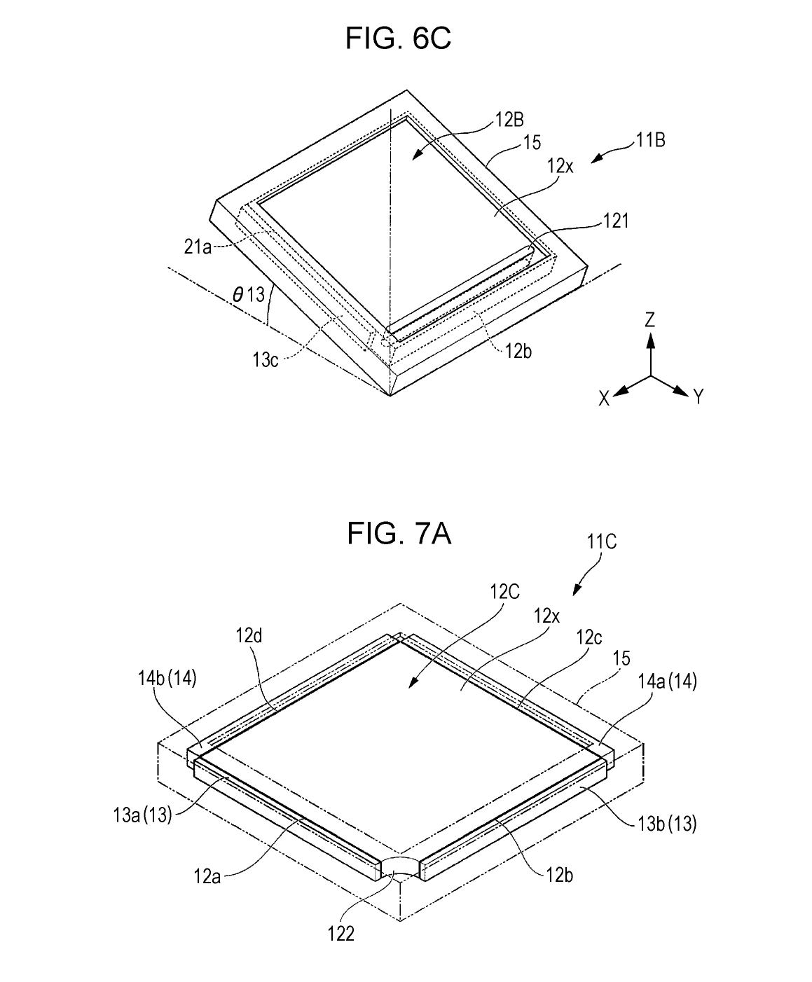

FIGS. 6A to 6C are explanatory views illustrating the solar cell module 11B with different shapes of through holes from each other. FIG. 6A is a perspective view corresponding to FIG. 1A, FIG. 6B is a plan view corresponding to FIG. 1B, and FIG. 6C is a schematic view corresponding to FIG. 4.

As illustrated in FIGS. 6A and 6B, the light collector 12B included in the solar cell module 11B includes a tubular through hole 121 having a square shape whose corners are rounded in a plan view. The through hole 121 is provided by being extended along the second end surface 12b in the vicinity of the second end surface 12b and is exposed from the frame 15 in a plan view. The through hole 121 is provided by being extended along the second end surface 12b in the vicinity of the second end surface 12b and is positioned in the inside in relation to the frame 15 in a plan view. Further, it is preferable that the main surface of the light collector 12B be subjected to a hydrophilic treatment.

In the through hole 121, it is preferable that the surface thereof be a reflective surface reflecting fluorescence propagating through the inside of the light collector 12B in the same manner as that of the through hole 120 illustrated in FIGS. 1A and 1B. Further, the through hole 121 may be formed to be orthogonal to the main surface of the light collector 12B.

In the light collector 12B, a reflective layer 13c is provided on the first end surface 12a and a reflective layer 13d is provided on the third end surface 12c. Configurations which are the same as those of the reflective layers 13a and 13b can be employed to the reflective layers 13c and 13d.

Moreover, the solar cell element 14c is provided so as to face the fourth end surface 12d facing the second end surface 12b. In this manner, the through hole 121 and the solar cell element 14c are provided on opposite sides with respect to the center line C13 of the light collector 12B.

As illustrated in FIG. 6C, the solar cell module 11B may be arranged by being inclined such that the elevation angle when seen from the first end surface 12a side is θ13 with the side of the second end surface 12b on which the through hole 121 is arranged downward from a state in which the solar cell module is parallel to a horizontal surface (XY plane) using a support (not illustrated). For example, θ13 is 30°.

When the solar cell module 11B is arranged by being inclined in this manner, rainwater and dust or the like are discharged to the rear surface side of the light collector 12B through the through hole 121 while dust or the like adhered to the main surface 12x of the light collector 12B is washed away by rainwater.

Even in a case of the solar cell module 11B described above, contamination is unlikely to remain on the main surface 12x so that efficient power generation can be continuously performed.

### Second Embodiment

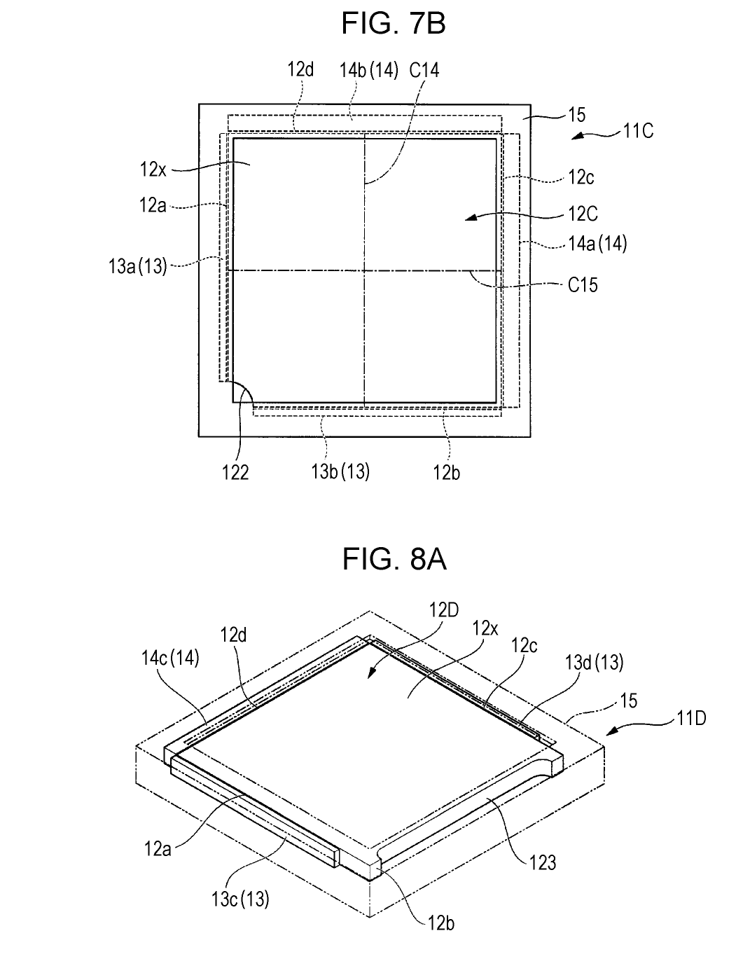

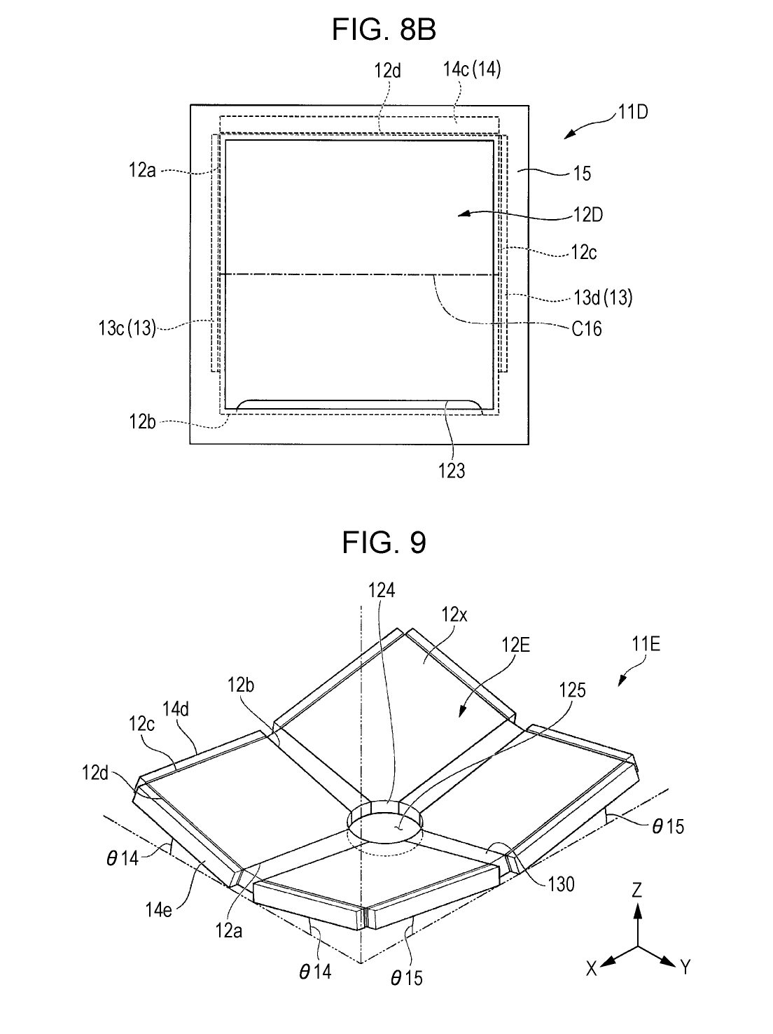

FIGS. 7A to 8B are explanatory views illustrating a solar cell module according to a second embodiment. The constituent elements common to the first embodiment and the present embodiment are denoted by the same reference numerals, and detailed description thereof will not be repeated.

FIGS. 7A and 7B are explanatory views illustrating a solar cell module 11C of the present embodiment. FIG. 7A is a perspective view corresponding to FIG. 1A and FIG. 7B is a plan view corresponding to FIG. 1B. As illustrated in FIGS. 7A and 7B, a light collector 12C included in the solar cell module 11C includes a notched portion 122 which has a shape of an arc in a plan view and covers an area from the main surface to the rear surface of the light collector 12C on a corner interposed between a first end surface 12a and the second end surface 12b.

Further, the term “notched portion” means a concave portion locally generated in the peripheral edge portion of the light collector.

The notched portion 122 is exposed from the frame 15 in a plan view. The notched portion 122 is positioned in the inside in relation to the frame 15 in a plan view. Accordingly, the notched portion 122 and the frame 15 form a through hole from the main surface side to the rear surface side of the light collector 12C.

In the notched portion 122, it is preferable that the surface thereof be a reflective surface that reflects fluorescence propagating through the inside of the light collector 12C. In addition, the notched portion 122 may be formed to be orthogonal to the main surface of the light collector 12C. Moreover, it is preferable that the main surface of the light collector 12C be subjected to a hydrophilic treatment.

In the light collector 12C, in the same manner as that of the solar cell module 11A of the first embodiment, the reflective layer 13a is provided on the first end surface 12a and the reflective layer 13b is provided on the second end surface 12b.

Further, the solar cell element 14a is provided on the third end surface 12c and the solar cell element 14b is provided on the fourth end surface 12d. Accordingly, the notched portion 122 and the solar cell element 14a are provided on the opposite sides with respect to a center line C14 of the light collector 12C. In addition, the notched portion 122 and the solar cell element 14b are provided on the opposite sides with respect to a center line C15 of the light collector 12C.

Such a solar cell module 11C may be arranged by being inclined such that the corner on which the notched portion 122 is formed is positioned downward in the same manner as that of the solar cell module 11A of the first embodiment. In this manner, rainwater and dust or the like are discharged to the rear surface side of the light collector 12C through the through hole formed by the notched portion 122 and the frame 15 while dust or the like adhered to the main surface 12x of the light collector 12C is washed away by rainwater.

Even in a case of the solar cell module 11C described above, contamination is unlikely to remain on the main surface 12x so that efficient power generation can be continuously performed.

Further, in the present embodiment, the shape of the notched portion 122 is an arc shape in a plan view, but various shapes can be employed when the notched portion is provided by being exposed from the frame 15 in a plan view and can form a through hole reaching from the main surface side to the rear surface side of the light collector together with the frame 15.

In addition, in the present embodiment, the notched portion 122 is provided on the corner being interposed between the first end surface 12a and the second end surface 12b, but the notched portion may be provided on the end surface of the light collector.

FIGS. 8A and 8B are explanatory views illustrating a solar cell module 11D with a different formation position of the notched portion. FIG. 8A is a perspective view corresponding to FIG. 6A and FIG. 8B is a plan view corresponding to FIG. 6B.

As illustrated in FIGS. 8A and 8B, the light collector 12D included in the solar cell module 11D is positioned on the second end surface 12b, is extended along the second end surface 12b, and includes a notched portion 123 reaching from the main surface to the rear surface of the light collector 12D. The notched portion 123 is exposed from the frame 15 in a plan view. The notched portion 123 is positioned in the inside in relation to the frame 15 in a plan view. Further, it is preferable that the main surface of the light collector 12D be subjected to a hydrophilic treatment.

In the notched portion 123 similar to the notched portion 122, it is preferable that the surface thereof be a reflective surface that reflects fluorescence propagating through the inside of the light collector 12D. In addition, the notched portion 123 may be formed to be orthogonal to the main surface of the light collector 12D.

The solar cell element 14c is provided so as to face the fourth end surface 12d that faces the second end surface 12b. Accordingly, the notched portion 123 and the solar cell element 14c are provided on the opposite sides with respect to a center line C16 of the light collector 12D.

Such a solar cell module 11D may be arranged by being inclined such that the second end surface 12b side on which the notched portion 123 is formed is positioned downward in the same manner as that of the solar cell module 11B of the first embodiment. In this manner, rainwater and dust or the like are discharged to the rear surface side of the light collector 12D through the through hole formed by the notched portion 123 and the frame 15 while dust or the like adhered to the main surface 12x of the light collector 12D is washed away by rainwater.

Even in a case of the solar cell module 11D described above, contamination is unlikely to remain on the main surface 12x so that efficient power generation can be continuously performed.

### Third Embodiment

FIG. 9 is an explanatory view illustrating a solar cell module 11E according to a third embodiment of the present invention. The solar cell module 11E illustrated in the figure includes four light collectors 12E having a similar shape to that of the light collector 12C of the solar cell module 11C of the second embodiment described above. In addition, the solar cell module 11E is held in a state in which the peripheral edge portion is surrounded by a frame (not illustrated).

Four light collectors 12E include a notched portion 124 corresponding to the notched portion 122 of the light collector 12C on each corner and form a large-sized light collector by allowing each notched portion 124 to be adjacent such that each notched portion faces each other to be arranged in a concentric circle shape.

In the light collector 12E, a joining member 130 is provided on the first end surface 12a and the second end surface 12b which are adjacent to the notched portion 124, and the light collectors 12E adjacent to each other through the joining member 130 are joined to each other. In this manner, four notched portions 124 included in each of the light collectors 12E integrally form a through hole 125 penetrating the large-sized light collector in the thickness direction.

In the notched portion 124, it is preferable that the surface thereof be a reflective surface that reflects fluorescence propagating through the inside of the light collector 12E. In addition, the notched portion 124 may be formed to be orthogonal to the main surface of the light collector 12E. Moreover, it is preferable that the main surface of the light collector 12E be subjected to a hydrophilic treatment.

The first end surface 12a and the second end surface 12b on which the joining member 130 is provided may be a reflective surface reflecting fluorescence propagating through the inside of the light collector 12E in the same manner as that of the notched portion 124. For example, the first end surface 12a and the second end surface 12b can be used as a reflective surface by covering the first end surface 12a and the second end surface 12b with a reflection material such as a dielectric multilayer film, for example, a metal film made of silver or aluminum, or an ESR reflective film (manufactured by 3M Japan Limited). In the configuration described above, the processing is easy when the notched portion 124, the first end surface 12a, and the second end surface 12b are covered with the same reflection material.

In this case, the joining member 130 can be formed using a resin material such as an adhesive that adheres the light collectors 12E to each other.

In addition, the joining member 130 may include a member whose surface is a light reflective surface and an adhesive layer having optical transparency for adhering the member to the light collector 12E.

Moreover, in each of the light collectors 12E, the solar cell element 14d is provided on the third end surface 12c and the solar cell element 14e is provided on the fourth end surface 12d. Accordingly, the notched portion 124 and the solar cell element 14d are provided on the opposite sides with respect to a center line of the light collector 12E. In addition, the notched portion 124 and the solar cell element 14e are provided on the opposite sides with respect to the center line of the light collector 12E.

The solar cell modules 11E may be joined by being inclined such that the elevation angles when seen from the solar cell element 14 side are θ14 and θ15 with the first end surface 12a and the second end surface 12b in contact with the joining member 130 arranged downward from a state in which the light collector 12E is parallel to a horizontal surface (XY plane). For example, θ14 and θ15 are 10° respectively.

In the solar cell module 11E, a large-sized light collector has a concave shape. Accordingly, rainwater and dust or the like are collected in the through hole 125 formed by the notched portion 124 and the frame 15 and then discharged to the rear surface side (rear surface side of the large-sized light collector) of the light collector 12E through the through hole 125 while the dust or the like adhered to the main surface 12x of the light collector 12E is washed away by rainwater.

Even in a case of the solar cell module 11E described above, contamination is unlikely to remain on the main surface 12x so that efficient power generation can be continuously performed.

Further, in the solar cell module 11E, four light collectors 12E are used to form one large-sized light collector, but the number of light collectors constituting a large-sized light collector may be two or more.

In addition, in the solar cell module 11E, the shape of the light collector constituting the large-sized light collector is a square in a plan view, but the shape thereof is not limited thereto and various shapes may be employed.

### Fourth Embodiment

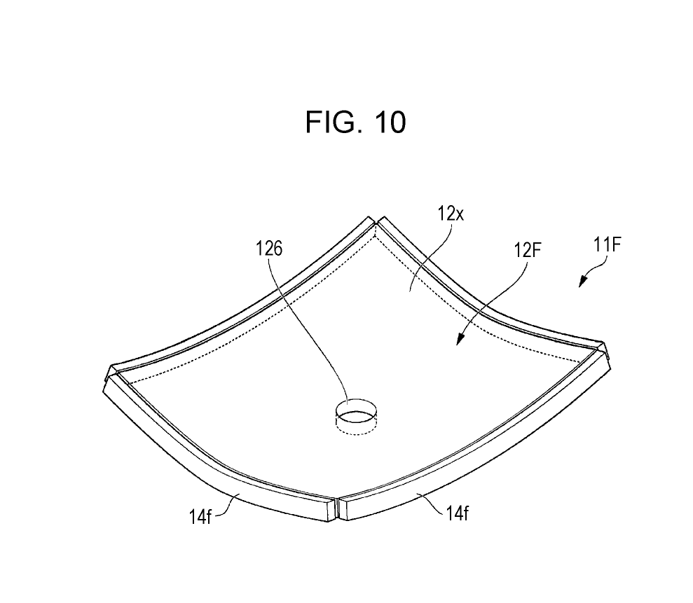

FIG. 10 is an explanatory view for describing a solar cell module 11F according to a fourth embodiment of the present invention. The solar cell module 11F illustrated in the figure includes a light collector 12F having a square shape in a plan view and solar cell elements 14f respectively provided on four end surfaces of the light collector 12F. The light collector 12F is a phosphor light collector similarly to the light collector 12A. Further, as the solar cell element 14f, the same element described in the section of the solar cell module 11A of the first embodiment can be used.

In the light collector 12F, the main surface 12x is formed in a concave shape and a through hole 126 penetrating the light collector 12F in the thickness direction is provided in a position most recessed on the main surface 12x. Further, the “position most recessed on the main surface” means the highest position on the main surface in the height direction when the light collector 12F is placed to form a convex on the horizontal surface. In the light collector 12F of the present embodiment, the rear surface has a curved shape in addition to the main surface 12x, but only the main surface 12x may be formed in a concave shape in the light collector.

A position on which the through hole 126 is formed may have the smallest radius of curvature in the main surface 12x of the light collector 12F.

In the light collector, light propagating through the inside is totally reflected without being discharged to the outside from the inside of the light collector and then discharged from the end surface in a case where the total reflection condition related to the main surface and the rear surface is satisfied. However, when the main surface and the rear surface of the light collector are curved similarly to the light collector 12F of the present embodiment, light propagating through the inside may be discharged to the outside because the total reflection condition related to the main surface and the rear surface of the light collector is not satisfied in some cases. Since light leakage described above easily occurs in a site whose radius of curvature is small in the light collector, the optical loss can be decreased by forming a through hole in such as site.

In the through hole 126, it is preferable that the surface thereof be a reflective surface which reflects fluorescence propagating through the inside of the light collector 12F. Further, it is preferable that the main surface of the light collector 12F be subjected to a hydrophilic treatment.

In the solar cell module 11F having such a configuration, rainwater and dust or the like are discharged to the rear surface side of the light collector 12F through the through hole 126 while dust or the like adhered to the main surface 12x of the light collector 12F is washed away by rainwater. For this reason, even in a case of the solar cell module 11F described above, contamination is unlikely to remain on the main surface 12x so that efficient power generation can be continuously performed.

In addition, in each of the embodiments described above, the light collector is a phosphor light collector, but the light collector is not limited thereto.

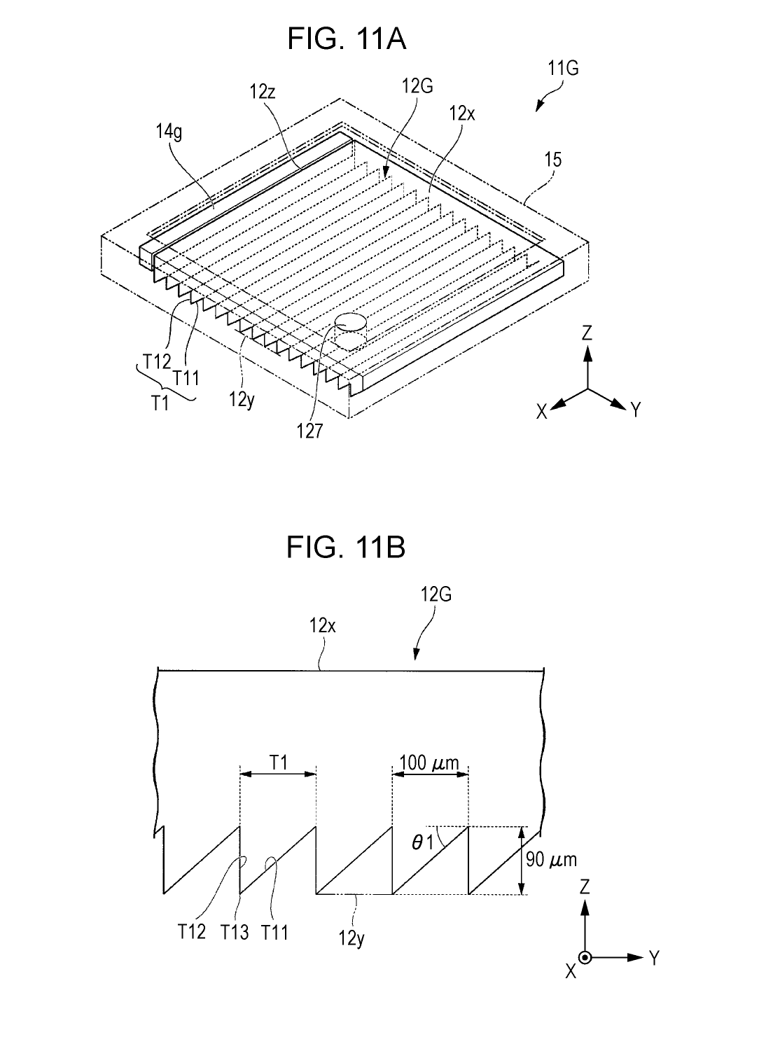

FIGS. 11A and 11B are explanatory views for describing a solar cell module 11G. FIG. 11A is a perspective view corresponding to FIG. 1A. The solar cell module 11G includes a light collector 12G, a solar cell element 14g provided on an end surface 12z of the light collector 12G, and a frame 15.

The light collector 12G is a plate-like member having a square shape in a plan view, which includes a main surface 12x μvertical (parallel to the XY plane) to the Z axis and a rear surface 12y. As the light collector 12G, an organic material or an inorganic material having high transparency such as an acrylic resin, a polycarbonate resin, or glass can be used.

A plurality of grooves T1 having a function of changing the traveling direction of light in a direction toward the end surface 12z by reflecting light incident from the main surface 12x are provided in a state of being extended in the X direction on the rear surface 12y of the light collector 12G. The grooves T1 are grooves in a shape of a V character including an inclined surface T11 which is obliquely inclined with respect to a surface parallel to the XY plane and a surface T12 which intersects with the inclined surface T11. In FIGS. 11A and 11B, for clarity of the figure, only a small number of grooves T1 are illustrated, but multiple fine grooves T1 respectively having a width of approximately 100 μm are formed in reality.

The light collector 12G including such grooves T1 is formed by performing injection molding on a resin material having high optical transparency in a visible light region.

The inclined surface T11 is a reflective surface that changes the traveling direction of light in the direction toward the end surface 12z through total reflection of external light L1 (for example, solar light) incident from the main surface 12x. The external light L1 incident at an angle which is almost vertical to the main surface 12x is reflected on the inclined surface T11 and then propagates through the inside of the light collector 12G in the approximately Y direction.

Such grooves T1 are provided in plural on the rear surface 12y of the light collector 12G in the Y direction such that the inclined surface T11 and the surface T12 are brought into contact with each other. In FIG. 11A, the shape and the size of the plurality of grooves T1 provided on the rear surface 12y are the same as one another, but the shape and the size thereof may be changed within a range without damaging the object of the present invention.

FIG. 11B is a cross-sectional view of the grooves T1 provided on the rear surface 12y of the light collector 12G. As illustrated in the figure, the grooves T1 are grooves in a shape of a V character, in which the inclined surface T11 at an angle of δ with respect to the Y axis and the surface T12 vertical to the Y axis intersect each other in a ridge line T13. The surface T12 is arranged on the end surface 12z side with respect to the ridge line T13 and the inclined surface T11 is arranged on the opposite side to the end surface 12z.

For example, the angle θ of the inclined surface T11 is 42°, the width of the grooves T1 in the Y direction is 100 μm, the depth of the grooves T1 in the Z direction is 90 μm, and the refractive index of the light collector 12G is 1.5. However, the angle θ1, the width of the grooves T1 in the Y direction, the depth of the grooves T1 in the Z direction, and the refractive index of the light collector 12G are not limited thereto.

The solar cell element 14g is provided so as to face the end surface 12z of the light collector 12G. Further, in the light collector 12G, a through hole 127 penetrating the light collector 12G in the thickness direction is provided in the vicinity of the corner in the end surface facing the end surface 12z on which the solar cell element 14g is provided. The through hole 127 is provided by being exposed from the frame 15 in a plan view. The shape of the through hole 127 can be employed from various shapes which can be employed to the above-described phosphor light collector in addition to the shape illustrated in FIGS. 11A and 11B.

Further, illustration is omitted, but a reflective layer that reflects light leaking to the outside of the light collector 12G from the end surface other than the end surface 12z in the inside of the light collector 12G may be provided on the end surface other than the end surface 12z of the light collector 12G.

Such a solar cell module 11G may be arranged by being inclined such that the corner on which the through hole 127 is formed is positioned downward in the same manner as that of the solar cell module 11A of the first embodiment. In this manner, rainwater and dust or the like are discharged to the rear surface 12y side of the light collector 12G through the through hole formed by the notched portion 122 and the frame 15 while dust or the like adhered to the main surface 12x of the light collector 12G is washed away by rainwater.

Even in a case of the solar cell module 11G described above, contamination is unlikely to remain on the main surface 12x so that efficient power generation can be continuously performed.

Moreover, as illustrated in FIGS. 11A and 11B, the light collector that reflects light on the inclined surface formed on the rear surface 12y and introduces the light to the end surface may include a notched portion formed on the phosphor light collector described above in addition to the through hole.

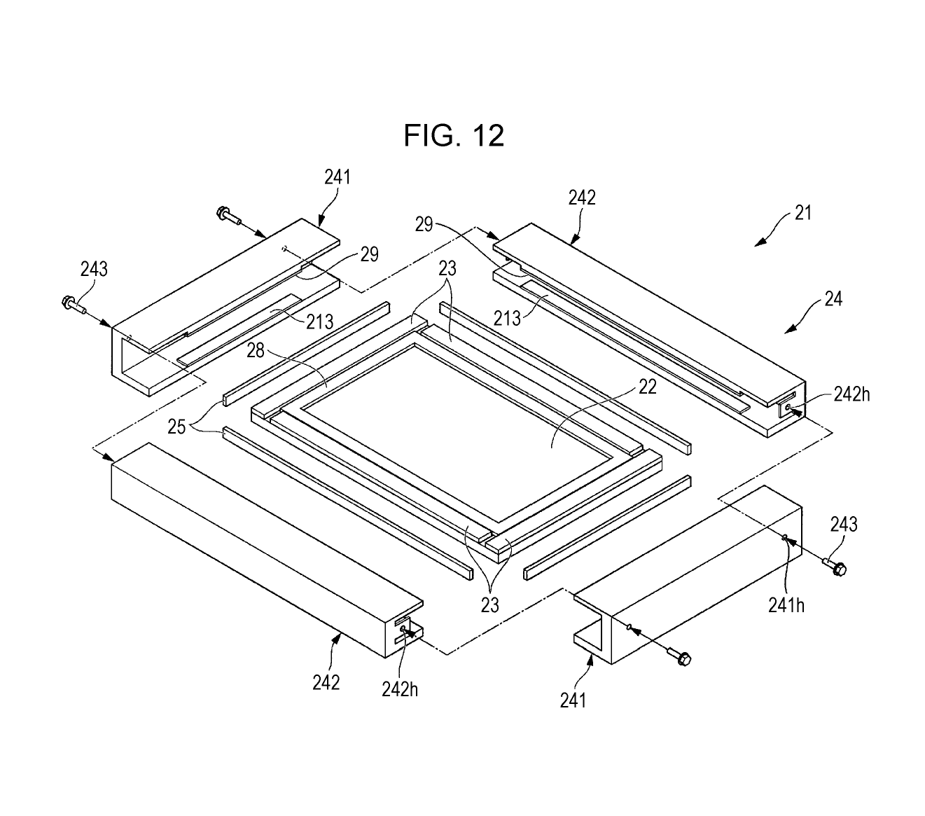

Hereinafter, the fifth embodiment of the present invention will be described with reference to FIGS. 12 to 14.

Further, in regard to all figures described below, for clarity of respective constituent elements, the scale of size of each constituent element is set to be different from the actual size thereof.

### Fifth Embodiment

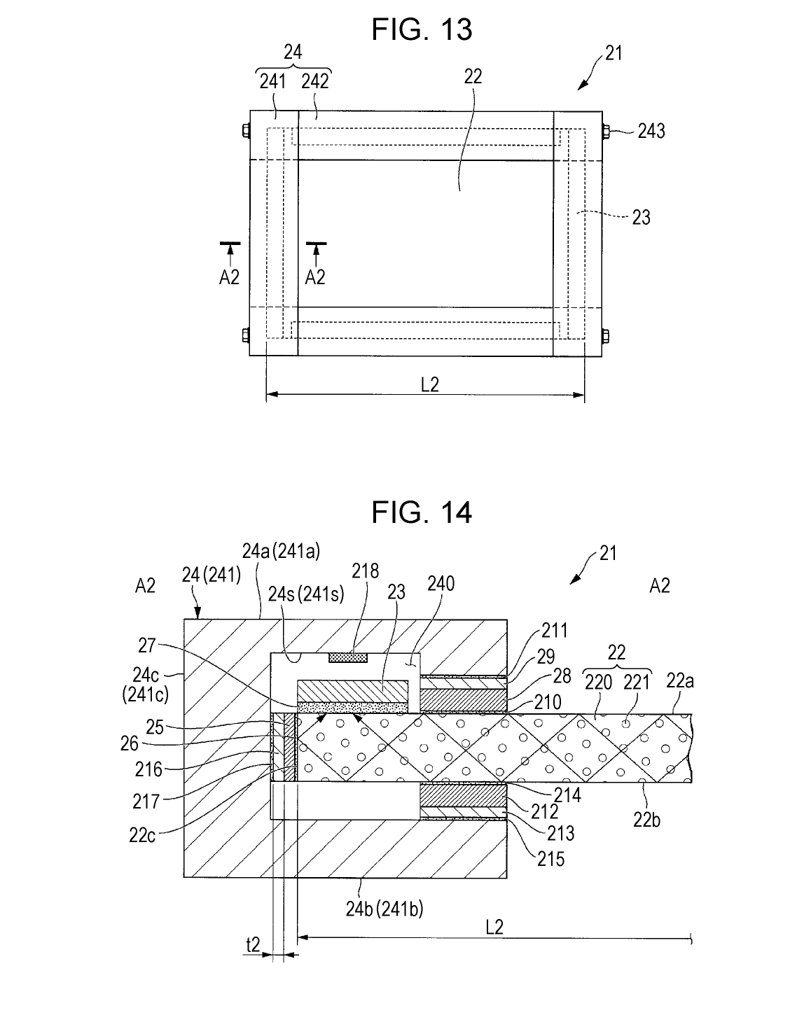

FIG. 12 is an exploded perspective view illustrating a solar cell module 21 according to a fifth embodiment of the present invention. FIG. 13 is a plan view illustrating the solar cell module 21. FIG. 14 is a cross-sectional view taken along line A2-A2 of FIG. 13.

As illustrated in FIG. 12, the solar cell module 21 includes a light collector 22, a solar cell element 23, and a frame 24.

The light collector 22 is a plate member having a shape of a rectangle in a plan view. The light collector 22 includes a first main surface 22a, a second main surface 22b, and an end surface 22c as illustrated in FIG. 14. The first main surface 22a is a light incident surface.

The second main surface 22b is a surface on the opposite side of the first main surface 22a. The end surface 22c is a light emission surface. In addition, as an example of the size of the light collector 22, the length of the long side is approximately 100 cm, the length of the short side is approximately 90 cm, and the thickness is approximately 4 mm.

The light collector 22 is a phosphor light collector allowing a phosphor 221 to be dispersed to a transparent base material 220 as illustrated in FIG. 13. A material which is the same as that of the base material 16 according to the first embodiment can be applied to the transparent base material 220. For example, the transparent base material 220 is made of an organic material having high transparency, for example, an acrylic resin such as PMMA, or a polycarbonate resin; or an inorganic material having transparency such as glass. In the present embodiment, a PMMA resin (refractive index:1.49) is used as the transparent base material 220. The light collector 22 is formed by allowing the phosphor 221 to be dispersed to the PMMA resin. Further, the refractive index of the light collector 22 is 1.50 which is approximately the same as that of the PMMA resin because the amount of the dispersed phosphor 221 is small.

The phosphor 221 is a photofunctional material that absorbs UV light or visible light and emits the UV light or the visible light to be radiated. As the photofunctional material, an organic phosphor is exemplified.

As the organic phosphor, the same material as the phosphor 17 of the first embodiment can be applied.

In the same manner as the phosphor 17 of the first embodiment, the organic phosphor may use one kind of a pigment or two or more kinds of pigments. In a case where two or more kinds of pigments are used, the amount of external light absorbed by all of the pigments to be used can be increased and the external light can be efficiently used by selecting pigments whose absorption wavelength bands of respective pigments are not overlapped with one another.

In addition, an inorganic phosphor can be used as the phosphor.

Further, various kinds of dyes (direct dyes, acidic dyes, basic dyes, and disperse dyes) can be used as a phosphor as long as the dyes are fluorescent.

In the case of the present embodiment, one kind of phosphor 221 is dispersed into the inside of the light collector 22. The phosphor 221 radiates red fluorescence by absorbing orange light. In the present embodiment, as the phosphor 221, Lumogen R305 (trade name, manufactured by BASF Corporation) is used. The phosphor 221 absorbs light having a wavelength of approximately 600 nm or less. The emission spectrum of the phosphor 221 has a peak wavelength at 610 nm.

Moreover, the present embodiment is not limited to the case where one kind of phosphor is used, and a plurality of kinds (two or three or more kinds) of phosphors may be used.

As illustrated in FIG. 12, a reflective layer 25 is provided on the four end surface 22c of the light collector 22. The reflective layer 25 reflects light (light radiated from the phosphor 221) traveling toward the outside from the inside of the light collector 22 to the inside of the light collector 22. As the reflective layer 25, a reflective layer formed of a dielectric multilayer film such as an ESR reflective film (manufactured by 3M Japan Limited) can be used. When the material is used, a high reflectance of 98% or more in visible light can be realized. Moreover, as the reflective layer 25, a reflective layer made of a metal film such as aluminum (AL), copper (Cu), gold (Au), or silver (Ag) may be used.

The reflective layer 25 is bonded to the end surface 22c of the light collector 22 by a transparent adhesive 26 as illustrated in FIG. 14. A thermosetting adhesive such as an ethylene-vinyl acetate copolymer (EVA), an epoxy-based adhesive, a silicone-based adhesive, or a polyimide-based adhesive is preferable for the transparent adhesive 26. In addition, the refractive index of the transparent adhesive 26 is 1.50 which is approximately the same as that of the light collector 22.

In addition, the reflective layer 25 may be directly formed on the end surface 22c of the light collector 22. Further, the reflective layer 25 may be held by being interposed between the inner wall surface of the frame 24 and the end surface 22c of the light collector 22. In this manner, it is not necessary to arrange a transparent adhesive 26.

The solar cell element 23 is arranged along four sides of the light collector 22 as illustrated in FIG. 12. The light receiving surface of the solar cell element 23 faces the first main surface 22a of the end portion of the light collector 22. As an example, the width of the solar cell element 23 is approximately 4 mm.

As the solar cell element 23, a known solar cell such as a silicon-based solar cell, a compound-based solar cell, a quantum dot solar cell, or an organic solar cell can be used. Among these, a compound-based solar cell or a quantum dot solar cell is preferable as the solar cell element 23 because power generation with high efficiency is possible. Particularly, a GaAs solar cell which is a compound-based solar cell showing high efficiency at a peak wavelength (610 nm) of the emission spectrum of the phosphor 221 is desirable. Alternatively, a compound-based solar cell exemplified as the solar cell element 14a of the first embodiment can be used. However, another kind of solar cell such as a Si-based solar cell or an organic solar cell can be used according to the cost or usage thereof.

The solar cell element 23 is fixed to the light collector 22 and not fixed to the frame 24. The solar cell element 23 is bonded to the first main surface 22a of the light collector 22 by the transparent adhesive 27 as illustrated in FIG. 14. An ethylene-vinyl acetate copolymer (EVA) can be used for the transparent adhesive 27. In addition, the refractive index of the transparent adhesive 27 is 1.50 which is approximately the same as that of the light collector 22. Moreover, a thermosetting adhesive such as an epoxy-based adhesive, a silicone-based adhesive, or a polyimide-based adhesive may be used for the transparent adhesive 27.

In FIG. 12, the example in which the solar cell elements 23 are disposed along four sides of the light collector 22 has been described, but the solar cell element 23 may be disposed along one side or three sides of the light collector 22.

The frame 24 is a frame having a shape of a rectangle in a plan view as illustrated in FIG. 13. The frame 24 holds the end portion of the light collector 22. The frame 24 is arranged so as to cover the solar cell element 23. The thickness of the frame 24 is approximately 2 mm. A forming material of the frame 24 is a metal such as Al. Alternatively, various materials can be used as the forming material of the frame 24. Particularly, it is preferable to use a material with high strength and light in weight.

In the present embodiment, the frame 24 is divided for each side of the light collector 22 as illustrated in FIG. 12. The frame 24 includes a first sub-frame 241 and a second sub-frame 242. The first sub-frame 241 is arranged along the short side of the light collector 22. Two first sub-frames 241 for two short sides which face each other are respectively arranged. The second sub-frame 242 is arranged along the long side of the light collector 22. Two second sub-frames 242 for two long sides which face each other are respectively arranged.

As illustrated in FIG. 14, the frame 24 holds the light collector 22 by interposing between the first main surface 22a side and the second main surface side 22b. Here, the configuration of the frame 24 will be described with reference to the figure of the first sub-frame 241. The first sub-frame 241 includes a top plate portion 241a, a bottom plate portion 241b, and a side wall portion 241c. Further, the configuration of the second sub-frame 242 has the same configuration as that of the first sub-frame 241.

The top plate portion 241a, the bottom plate portion 241b, and the side wall portion 241c are integrally formed. The top plate portion 241a is arranged so as to cover the solar cell element 23. One end portion of the top plate portion 241a is connected to the side wall portion 241c. Another end portion of the top plate portion 241a is extended to a portion over the solar cell element 23. The another end portion of the top plate portion 241a is thick. The bottom plate portion 241b is arranged so as to face the top plate portion 241a by interposing the light collector 22 therebetween. One end portion of the bottom plate portion 241b is connected to the side wall portion 241c. Another end portion of the bottom plate portion 241b is extended to a portion overlapped with another end portion of the top plate portion 241a of the light collector 22. The length of the light collector 22 of the bottom plate portion 241b in the longitudinal direction is substantially equivalent to the length of the light collector 22 of the top plate portion 241a in the longitudinal direction.

As illustrated in FIG. 12, the end portion of the first sub-frame 241 is provided with the through hole 241h. A portion in which the through hole 241h of the first sub-frame 241 is overlapped with the end portion of the second sub-frame 242 is provided with a screw hole 242h. A fixing member 243 such as a screw is fixed to the screw hole 242h through the through hole 241h. In this manner, the end portion of the first sub-frame 241 is fixed to the end portion of the second sub-frame 242.

As illustrated in FIG. 14, a reflective layer 28 and a buffering layer 29 are provided between another end portion of the top plate portion 241a of the frame 24 and the first main surface 22a of the light collector 22.

The reflective layer 28 reflects light (light radiated from the phosphor 221) traveling toward the outside from the inside of the light collector 22 to the inside of the light collector 22. As the reflective layer 28, a reflective layer formed of a dielectric multilayer film such as ESR or a reflective layer made of a metal film such as Al, Cu, Au, or Ag may be used.

The reflective layer 28 is bonded to the first main surface 22a of the light collector 22 by a transparent adhesive 210. A thermosetting adhesive such as an ethylene-vinyl acetate copolymer (EVA), an epoxy-based adhesive, a silicone-based adhesive, or a polyimide-based adhesive is preferable for the transparent adhesive 210. In addition, the refractive index of the transparent adhesive 210 is desirably 1.50 which is approximately the same as that of the light collector 22 for propagation of guided light from the light collector 22 without loss. Specifically, a one-pack transparent epoxy resin EH1600-G2 (manufactured by INABATA Co., Ltd.) whose refractive index after curing is 1.51 is used as the transparent adhesive 210 of the present embodiment. The adhesive of the present embodiment is not limited thereto.

Moreover, the reflective layer 28 may be directly formed on the first main surface 22a of the light collector 22. In addition, the reflective layer 28 may be held by being interposed between another end portion of the top plate portion 241a of the frame 24 and the first main surface 22a of the light collector 22. In this manner, it is not necessary to arrange the transparent adhesive 210.

The buffering layer 29 absorbs the stress applied between another end portion of the top plate portion 241a of the frame 24 and the first main surface 22a of the light collector 22. As the buffering layer 29, a rubber sheet such as a silicon rubber sheet can be used. Alternatively, various materials can be used as a forming material of the buffering layer 29. Particularly, a material having a high waterproof property is preferably used.

The buffering layer 29 is bonded to another end portion of the top plate portion 241a of the frame 24 by an adhesive 211.

A thermosetting adhesive such as an ethylene-vinyl acetate copolymer (EVA), an epoxy-based adhesive, a silicone-based adhesive, or a polyimide-based adhesive is preferable for the adhesive 211. Further, the buffering layer 29 may not be completely fixed by the adhesive 211. The position of the buffering layer 29 may not be displaced when the light collector 22 is held by being interposed using the frame 24.

A reflective layer 212 and a buffering layer 213 are provided between another end portion of the bottom plate portion 241b of the frame 24 and the second main surface 22b of the light collector 22.

The reflective layer 212 reflects light (light radiated from the phosphor 221) traveling toward the outside from the inside of the light collector 22 to the inside of the light collector 22. As the reflective layer 212, a reflective layer which is the same as the reflective layer 28 can be used.

The reflective layer 212 is bonded to the second main surface 22b of the light collector 22 by a transparent adhesive 214. As the transparent adhesive 214, an adhesive which is the same as the transparent adhesive 210 can be used.

Moreover, the reflective layer 212 may be directly formed on the second main surface 22b of the light collector 22. Further, the reflective layer 212 may be held by being interposed between another end portion of the bottom plate portion 241b of the frame 24 and the second main surface 22b of the light collector 22. In this manner, it is not necessary to arrange a transparent adhesive 214.

The buffering layer 213 absorbs the stress applied between another end portion of the top plate portion 241b of the frame 24 and the second main surface 22b of the light collector 22. As the buffering layer 213, a layer which is the same as the buffering layer 29 can be used.

The buffering layer 213 is bonded to another end portion of the bottom plate portion 241b of the frame 24 by an adhesive 215. An adhesive which is the same as the adhesive 211 can be used for the adhesive 215. Further, the buffering layer 213 may not be completely fixed by the adhesive 215. The position of the buffering layer 213 may not be displaced when the light collector 22 is held by being interposed using the frame 24.

Further, a portion in which the reflective layer 212 and the buffering layer 213 are not arranged is provided with an air layer being interposed between the bottom plate portion 241b of the frame 24 and the second main surface 22b of the light collector 22.

As illustrated in FIG. 14, the inner wall surface 24s of the frame 24 is separated from the end surface 22c of the light collector 22.

Here, an arrangement relationship between the inner wall surface 24s of the frame 24 and the end surface 22c of the light collector 22 is described with reference to the figure illustrating that the inner wall surface 241s of the side wall portion 241c of the first sub-frame 241 is separated from the end surface 22c of the light collector 22. In addition, an arrangement relationship between the inner wall surface of the sidewall portion of the second sub-frame 242 and the end surface 22c of the light collector 22 is the same as the arrangement relationship described above, and accordingly, description thereof will not be repeated.

In the present embodiment, a buffering layer 216 (elastic member) is provided between the side wall portion 241c of the frame 24 and the reflective layer 25 provided on the end surface 22c of the light collector 22.

The buffering layer 216 absorbs the stress applied between the side wall portion 241c of the frame 24 and the end surface 22c of the light collector 22. As the buffering layer 216, a rubber sheet such as a silicon rubber sheet can be used. Alternatively, various materials can be used as the forming material of the buffering layer 216. Particularly, it is preferable to use a material having high elastic force so as to alleviate displacement of a relative position between the frame 24 and the light collector 22, the stress due to curvature of at least one of the frame 24 and the light collector 22, and influence of expansion or contraction of the light collector 22 due to an increase of the temperature. For example, materials having viscosity such as gel, a silicon resin, an urethane resin, and rubber can be used.

The buffering layer 216 is bonded to the inner wall surface 241s of the side wall portion 241c of the frame 24 by an adhesive 217. An elastic adhesive is preferable for the adhesive 217.

Moreover, it is preferable a thickness t2 of the buffering layer 216 be set such that a constant interval can be secured between the inner wall surface 241s of the first sub-frame 241 and the end surface 22c of the light collector 22 even when the light collector 22 is thermally expanded due to a change of the temperature per unit time.

When the maximum value of a temperature difference of the light collector 22 due to a change of the temperature per unit time is set as δT, the length of the light collector 22 is set as L2, and the linear expansion coefficient of the light collector 22 is set as K, the expansion amount of the light collector 22 due to the change of the temperature can be obtained by a relationship of “δT×L2×K.” The maximum value of the temperature difference of the light collector 22 due to the change of the temperature per unit time can be set as follows. For example, when one day is set as the unit time, a temperature difference between the temperature (maximum temperature) of the light collector 22 at the time when the temperature is high during the daytime and the temperature (minimum temperature) of the light collector 22 at the time when the temperature is low during the nighttime is set as a maximum value of the temperature difference of the light collector 22.

When one year is set as the unit time, in consideration of the temperature change of seasons, a temperature difference between the temperature (maximum temperature) of the light collector 22 at the time when the temperature is high during the summer time and the temperature (minimum temperature) of the light collector 22 at the time when the temperature is low during the winter time is set as a maximum value of the temperature difference of the light collector 22.

For example, in a case where the maximum value δT of the temperature difference of the light collector 22 due to the temperature change per unit time is set as 50° C. and the length L2 of the light collector 22 in the longitudinal direction is set as 1 m, when a linear expansion coefficient K at the time when an acrylic plate is used as the light collector 22 is 80×10⁻⁶ m/° C., the light collector 22 expands by a length of 4 mm. Accordingly, it is necessary to make a space of 4 mm or greater for the constant interval between the inner wall surface 241s of the first sub-frame 241 and the end surface 22c of the light collector 22.

Meanwhile, when the distance between the inner wall surface 241s of the sub-frame 241 and the end surface 22c of the light collector 22 is exceedingly large, a ratio of the size of the frame 24 to the size of the solar cell module 21 becomes larger.

As a result, since a ratio of a light receiving area becomes small, the power generation efficiency with respect to the size of the solar cell module 21 is degraded.

Moreover, the buffering layer 216 is a protection member of the light collector 22 during a process of preparing the solar cell module 21. In this manner, it is possible to prevent the light collector 22 from being damaged due to contact with the frame 24 or another member.

In order to maximize the effect of protection using the buffering layer 216, it is desirable to fill the buffering layer 216 between the inner wall surface 241s of the first sub-frame 241 and the end surface 22c of the light collector 22.

Accordingly, when the maximum value of the temperature difference of the light collector 22 due to the temperature change per unit time is set as δT, the length of the light collector 22 in the longitudinal direction is set as L2, and the linear expansion coefficient of the light collector 22 is set as K, it is preferable to satisfy the following expression (1).

t2>δT×L2×K (1)

In the above-described conditions of the present invention, the thickness t2 of the buffering layer 216 is 4 mm. In this case, it is preferable that the thickness t2 of the buffering layer 216 be set to be greater than 4 mm.

Certainly, the above-described conditions are desirable, but it is possible to make the thickness t2 of the buffering layer 216 small by sufficiently securing the distance between the inner wall surface 241s of the first sub-frame 241 and the end surface 22c of the light collector 22. For example, it is possible to avoid damage due to thermal expansion or damage during a process by setting the distance as 1.5 cm and the thickness t2 of the buffering layer 216 as 2 mm.

A space 240 is provided between the inner wall surface 241s of the top plate portion 241a of the first sub-frame 241 and the solar cell element 23. The space 240 is provided with an air layer interposed therebetween.

A drying agent 218 is provided on the inner wall surface 241s of the top plate portion 241a of the first sub-frame 241. Silica gel can be used for the drying agent 218. Alternatively, a molecular sieve can be used as the drying agent 218. Further, the space 240 may be filled with dry nitrogen.

As described above, according to the solar cell module 21 of the present embodiment, the solar cell element 23 is fixed to the first main surface 22a of the light collector 22 and not fixed to the frame 24. Consequently, it is possible to prevent the stress from being applied to the solar cell element 23 due to displacement of the relative position between the light collector 22 and the frame 24. Accordingly, it is possible to prevent damage of the solar cell element 23.

Moreover, according to the present embodiment, since the frame 24 is formed so as to cover the solar cell element 23, it is possible to prevent foreign matters such as dust or rainwater from entering the solar cell element 23.

In addition, according to the present embodiment, the frame 24 holds the end portion of the light collector 22 by interposing the end portion thereof between the first main surface 22a side and the second main surface 22b side. Therefore, it is possible to prevent displacement of the frame 24 due to the external force and prevent an impact from being applied to the solar cell element 23.

Accordingly, it is possible to prevent damage of the solar cell element 23.

Further, according to the present embodiment, a buffering layer 216 is provided between the side wall portion 241c of the frame 24 and the reflective layer 25 provided on the end surface 22c of the light collector 22. Accordingly, in a case where an impact is applied to the frame 24 or the light collector 22 due to the external force, the impact applied to the solar cell element 23 can be absorbed by the buffering layer 216. Therefore, it is possible to prevent damage of the solar cell element 23.

Further, according to the present embodiment, since the drying agent 218 is provided in the space 240, the moisture of the space 240 can be eliminated. Consequently, degradation in quality of the solar cell element 23 due to the humidity can be prevented.

In addition, according to the present embodiment, since the space 240 is provided between the inner wall surface 24s of the top plate portion 241a of the frame 24 and the solar cell element 23, when an impact is applied to the frame 24 or the light collector 22 due to the external force, it is possible to prevent the impact from being applied to the solar cell element 23 because of the space 240. Further, the stress generated due to deflection, curvature, thermal expansion, or the like of the light collector 22 can escape because of the space 240. Therefore, it is possible to prevent damage of the solar cell element 23.

Moreover, according to the present embodiment, as illustrated in FIG. 14, light propagating through the light collector 22 is reflected on the surface of the reflective layer 25, the surface of the reflective layer 28, and the surface of the reflective layer 212 and then returns to the inside of the light collector 22 again. Accordingly, light loss can be decreased.

In addition, according to the present embodiment, a portion in which the reflective layer 212 and the buffering layer 213 are not arranged is provided with an air layer being interposed between the bottom plate portion 241b of the frame 24 and the second main surface 22b of the light collector 22. Since a refractive index difference between the refractive index of the light collector 22 and the refractive index of the air layer is large, the light propagating through the light collector 22 is easily totally reflected on the interface between the light collector 22 and the air layer. Accordingly, light loss can be decreased. For example, when the refractive index of the light collector 22 is set as 1.5 and the refractive index of the air layer is set as 1.0, the critical angle on the interface between the light collector 22 and the air layer is approximately 42° from Snell's law. Since conditions of the critical angle are satisfied while the incident angle of light into the interface is larger than 42° which is the critical angle thereof, the light is totally reflected on the interface.

Further, the light collector 22 of the present embodiment is configured of a phosphor light collector containing a phosphor which absorbs incident light and emits fluorescence, but the configuration is not limited thereto. For example, the light collector 22 may be configured of a light collector containing no phosphor. Further, the light collector may be configured of a light collector on which a reflective surface that reflects incident light and changes the travelling direction of the light is provided.

Moreover, in the present embodiment, the example in which the reflective layer 212 is provided in a portion of the frame 24 has been described, but the present embodiment is not limited thereto. For example, the reflective layer may be provided on the whole inner surface of the frame.

### Sixth Embodiment

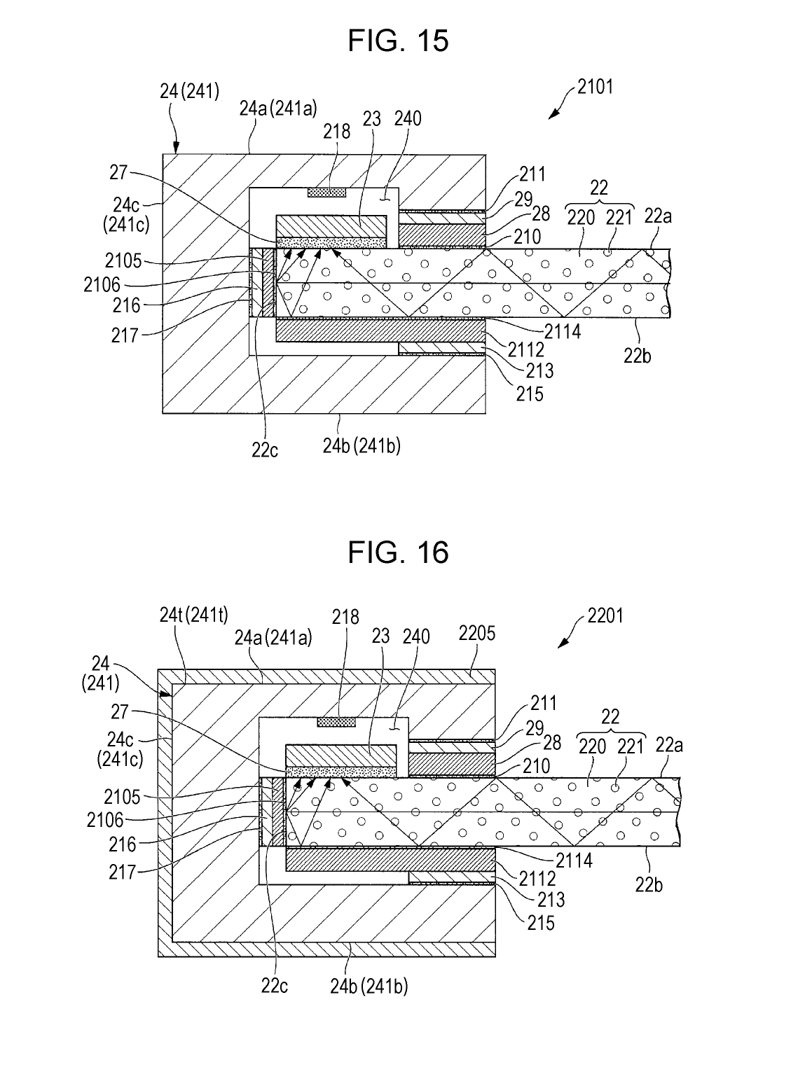

FIG. 15 is a cross-sectional view illustrating a solar cell module 2101 according to a sixth embodiment of the present invention.

The basic configuration of the solar cell module 2101 of the present embodiment is the same as that of the fifth embodiment, but arrangement of a scattering reflective layer 2105 instead of the reflective layer 25 arranged on the end surface 22c of the light collector 22 and arrangement of a reflective layer 2112 having a length different from that of the reflective layer 212 arranged on the second main surface 22b of the light collector 22 are different from those of the fifth embodiment. Accordingly, description of the basic configuration of the solar cell module 2101 will not be repeated in the present embodiment.

In the present embodiment, as illustrated in FIG. 15, a scattering reflective layer 2105 is provided on the end surface 22c of the light collector 22. The scattering reflective layer 2105 scatters and reflects incident light. For example, as the scattering reflective layer 2105, microfoam polyethylene terephthalate (PET) (manufactured by Furukawa Electric Co., Ltd.) or the like can be used.

The reflective layer 2112 is provided on the second main surface 22b of the light-reflecting plate 22. The reflective layer 2112 is arranged from a portion facing the solar cell element 23 in the second main surface 22b of the light collector 22 to a portion facing the reflective layer 28. As the reflective layer 2112, a reflective layer formed of a dielectric multilayer film such as ESR or a reflective layer made of a metal film such as Al, Cu, Au, or Ag may be used. Furthermore, a scattering reflective layer that scatters and reflects incident light may be used for the reflective layer.

The reflective layer 2112 is bonded to the second main surface 22b of the light collector 22 by a transparent adhesive 2114.

A thermosetting adhesive such as an ethylene-vinyl acetate copolymer (EVA), an epoxy-based adhesive, a silicone-based adhesive, or a polyimide-based adhesive is preferable for the transparent adhesive 2114. In addition, the refractive index of the transparent adhesive 2114 is desirably 1.50 which is approximately the same as that of the light collector 22 for propagation of guided light from the light collector 22 without loss. Specifically, a one-pack transparent epoxy resin EH1600-G2 (manufactured by INABATA Co., Ltd.) whose refractive index after curing is 1.51 is used as the transparent adhesive 2114 of the present embodiment. The adhesive of the present embodiment is not limited thereto.

Moreover, the reflective layer 2112 may be directly formed on the second main surface 22b of the light collector 22. In this manner, it is not necessary to arrange the transparent adhesive 2114.

When a reflective layer without a function of scattering light to the end surface of the light collector is arranged, light almost vertically incident on the end surface is almost vertically reflected on the surface of the reflective layer. The reflection light is not incident on the solar cell element and travels toward the end portion on the opposite side of the end surface on which the reflective layer of the light collector is arranged.

Meanwhile, according to the solar cell module 2101 of the present embodiment, the light incident at an angle almost vertical to the end surface 22c of the light collector 22 can be scattered and reflected by the scattering reflective layer 2105. A part of the scattered and reflected light is incident on the solar cell element 23. Further, a part of the scattered and reflected light travels toward the second main surface 22b on the opposite side of the solar cell element 23. The light incident on a portion facing the solar cell element 23 of the second main surface 22b is reflected by the reflective layer 2112. The light which is incident at an angle that does not satisfy the total reflection condition in light scattered and reflected downwardly from the scattering reflective layer 2105 can be guided to the solar cell element 23 by the reflective layer 2112. With this configuration, the light amount of light travelling directly to the solar cell element 23 can be increased. Accordingly, the light collection efficiency with respect to the solar cell element 23 is improved and then the power generation amount is increased.

### Seventh Embodiment

FIG. 16 is a cross-sectional view illustrating a solar cell module 2201 according to a seventh embodiment of the present invention.

The basic configuration of the solar cell module 2201 of the present embodiment is the same as that of the sixth embodiment, but formation of a reflective layer 2205 on the outer surface of the frame 24 is different from the case of the sixth embodiment. Accordingly, description of the basic configuration of the solar cell module 2201 will not be repeated in the present embodiment.

In the present embodiment, as illustrated in FIG. 16, the reflective layer 2205 is formed along an outer wall surface 24t of the frame 24. The reflective layer 2205 is formed from the outer wall surface 24t of a top plate portion 24a of the frame 24 and the outer 24t of a bottom plate portion 4b to the outer wall surface 24t of a side wall portion 24c.

In addition, the reflective layer 2205 may be formed over the whole surface of the outer wall surface 24t of the frame 24 or may be formed only a surface exposed to solar light.

For example, as the reflective layer 2205, a white scattering layer can be used. Moreover, a reflective layer can be formed on the frame 24 or can be adhered thereto. Further, the surface of the frame itself can be made into a mirror reflective surface by performing mirror-finishing on the surface.

Further, a retro-reflective layer can be disposed as the reflective layer. Light can be reflected to an opposite direction to the direction in which the light is incident by the retro-reflective layer. Therefore, in a case where a plurality of solar cell modules are adjacently arranged, it is possible to prevent the reflection light from being incident on an adjacent module.

Accordingly, a factor of increase in temperature of the solar cell element can be prevented.

The solar cell element has temperature dependency, and the power generation is decreased when the temperature is increased in general. For example, in a crystalline silicon solar cell, it is known that when the surface temperature is 75° C. due to irradiation of solar light, the power generation is decreased by 25% compared to a case where the surface temperature is 25° C.

When the solar cell element is disposed in the inside of the frame, the temperature of the solar cell element is increased in some cases in a case where the temperature of the frame is increased due to irradiation of solar light.

According to the solar cell module 2201 of the present embodiment, solar light incident on the frame 24 can be reflected by the reflective layer 2205. Consequently, increase in temperature of the frame 24 can be suppressed. Therefore, it is possible to prevent increase in temperature of the solar cell element and prevent decrease in power generation.

### Eighth Embodiment

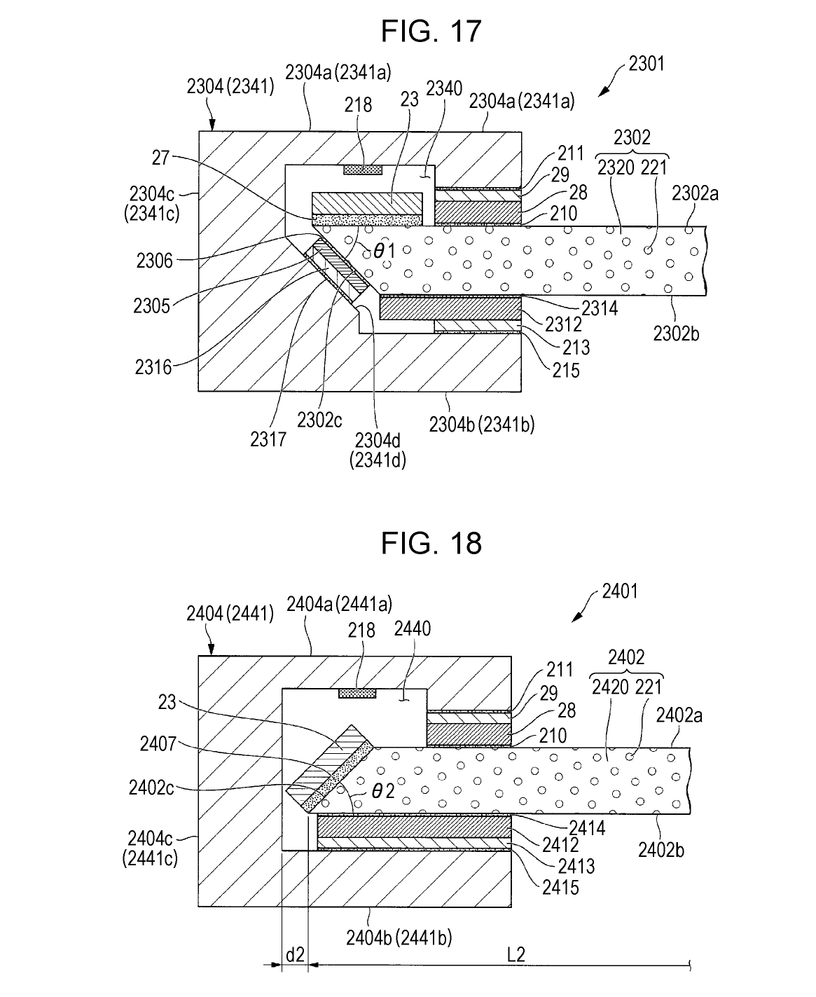

FIG. 17 is a cross-sectional view illustrating a solar cell module 2301 according to an eighth embodiment of the present invention.

The basic configuration of the solar cell module 2301 of the present embodiment is the same as that of the sixth embodiment, but points in which an end surface 2302c of a light collector 2302 is an inclined surface inclined with respect to a first main surface 2302a of the light collector 2302, an inclined surface 2304d parallel to the inclined surface 2302c of the light collector 2302 is formed on the inner surface of a frame 2304, and a reflective layer 2305 is arranged on the end surface 2302c of the light collector 2302 are different from the case of the sixth embodiment. Accordingly, description of the basic configuration of the solar cell module 2301 will not be repeated in the present embodiment.

In the present embodiment, as illustrated in FIG. 17, the end surface 2302c of the light collector 2302 is inclined at an acute angle with respect to the first main surface 2302a of the light collector 2302. An angle θ 1 between the end surface 2302c of the light collector 2302 and the first main surface 2302a of the light collector 2302 is, for example, approximately 45°.

The inclined surface 2304d formed on the inner surface of the frame 2304 is parallel with the inclined surface 2302c of the light collector 2302. The area of the inclined surface 2304d of the frame 2304 is substantially equivalent to the area of the inclined surface 2302c of the light collector 2302.

The reflective layer 2305 is provided on the inclined surface 2302c of the light collector 2302. The reflective layer 2305 reflects light (light radiated from the phosphor 221) traveling toward the outside from the inside of the light collector 2302 to the inside of the solar cell element 23. As the reflective layer 2305, a reflective layer formed of a dielectric multilayer film such as ESR or a reflective layer made of a metal film such as Al, Cu, Au, or Ag may be used.

The reflective layer 2305 is bonded to the inclined surface 2302c of the light collector 2302 by a transparent adhesive 2306. A thermosetting adhesive such as an ethylene-vinyl acetate copolymer (EVA), an epoxy-based adhesive, a silicone-based adhesive, or a polyimide-based adhesive is preferable for the transparent adhesive 2306. In addition, the refractive index of the transparent adhesive 2306 is 1.50 which is approximately the same as that of the light collector 2302.

Moreover, the reflective layer 2305 may be directly formed on the inclined surface 2302c of the light collector 2302.

In addition, the reflective layer 2305 may be held by being interposed between the inclined surface 2304d of the frame 2304 and the inclined surface 2302c of the light collector 22. In this manner, it is not necessary to arrange the transparent adhesive 2306.

A buffering layer 2316 is provided between the inclined surface 2304d of the frame 2304 and the reflective layer 2305 provided on the inclined surface 2302c of the light collector 2302.

The buffering layer 2316 absorbs the stress applied between the inclined surface 2304d of the frame 2304 and the inclined surface 2302c of the light collector 2302. As the buffering layer 2316, materials having viscosity, for example, a rubber sheet such as a silicon rubber sheet, gel, a silicon resin, an urethane resin, and rubber can be used.

The buffering layer 2316 is bonded to the inclined surface 2304d of the frame 2304 by an adhesive 2317. An elastic adhesive is preferable for the adhesive 2317.

Moreover, it is preferable the thickness of the buffering layer 2316 be set such that a constant interval can be secured between the inclined surface 2304d of the frame 2341 and the inclined surface 2302c of the light collector 2302 even when the light collector 2302 is thermally expanded due to the temperature change per unit time.

According to the solar cell module 2301 of the present embodiment, since the inclined surface 2302c of the light collector 2302 is inclined at an acute angle with respect to the first main surface 2302a of the light collector 2302, light incident on the inclined surface 2302c is easily reflected in a vertical direction. Accordingly, when compared to a case in which the end surface of the light collector is a right angle with respect to the first main surface of the light collector, the light amount of light traveling directly to the solar cell element 23 can be increased. Therefore, light collection efficiency with respect to the solar cell element 23 is improved and the power generation amount is increased. Since a surface to which the light collector 2302 and the frame 2304 are fixed is increased, the light collector 2302 and the frame 2304 can be rigidly fixed thereto.

Further, according to the present embodiment, since the inclined surface 2304d of the frame 2304 coincides with the inclined surface 2302c of the light collector 2302, the light collector 2302 can be stably disposed in the frame 2304. Further, the light collector 2302 and the frame 2304 are easily fixed.

### Ninth Embodiment

FIG. 18 is a cross-sectional view illustrating a solar cell module 2401 according to a ninth embodiment of the present embodiment.

The basic configuration of the solar cell module 2401 of the present embodiment is the same as that of the sixth embodiment, but points in which an end surface 2402c of a light collector 2402 is an inclined surface inclined with respect to a second main surface 2402b of the light collector 2402, the solar cell element 23 is fixed to the end surface 2402c of the light collector 2402, a gap is formed between the inclined surface 2402c of the light collector 2402 and the inner surface of the frame 2404, and the area of a fixed portion of the light collector 2402 due to the frame 2404 is different from the area of the first main surface 2402a of the light collector 2402 or the area of the second main surface 2402b of the light collector 2402 are different from the case of the sixth embodiment. Accordingly, description of the basic configuration of the solar cell module 2401 will not be repeated in the present embodiment.

In the present embodiment, as illustrated in FIG. 18, the end surface 2402c of the light collector 2402 is inclined at an acute angle with respect to the second main surface 2402b of the light collector 2402. An angle θ 2 between the end surface 2402c of the light collector 2402 and the second main surface 2402b of the light collector 2402 is, for example, approximately 45°.

The solar cell element 23 is bonded to the inclined surface 2402c of the light collector 2402 by a transparent adhesive 2407. A thermosetting adhesive such as an ethylene-vinyl acetate copolymer (EVA), an epoxy-based adhesive, a silicone-based adhesive, or a polyimide-based adhesive is preferable for the transparent adhesive 2407. In addition, the refractive index of the transparent adhesive 2407 is 1.50 which is approximately the same as that of the light collector 2402.

In the present embodiment, there are two sites to which the light collector 2402 is fixed by the frame 2404 on the upper side of the first main surface 2402a and the lower side of the second main surface 2402b. In regard to the area of the fixed portion of the light collector 2402 by the frame 2404, the area of the second main surface 2402b of the light collector 2402 is larger than the area of the first main surface 2402a of the light collector 2402. The area of the fixed portion is the contact area of a portion in which the frame 2404 faces the light collector 2402. Specifically, the buffering layer 2413 and the adhesive 2415 are arranged over the portion facing the reflective layer 2412 on the second main surface 2402b of the light collector 2402.

In the present embodiment, a gap is formed between the inclined surface 2402c of the light collector 2402 and the inner surface of the frame 2404.

Moreover, it is preferable a size d2 of the gap be set such that a constant interval can be secured between the inner wall surface of the frame 2404 and the inclined surface 2402c of the light collector 2402 even when the light collector 2402 is thermally expanded due to the temperature change per unit time.

When the maximum value of a temperature difference of the light collector 2402 due to a change of the temperature per unit time is set as δT, the length of the light collector 2402 is set as L2, and the linear expansion coefficient of the light collector 2402 is set as K, the expansion amount of the light collector 2402 due to the change of the temperature can be obtained by a relationship of “δT×L2×K.” The maximum value of the temperature difference of the light collector 2402 due to the change of the temperature per unit time can be set as follows. For example, when one day is set as the unit time, a temperature difference between the temperature (maximum temperature) of the light collector 2402 at the time when the temperature is high during the daytime and the temperature (minimum temperature) of the light collector 2402 at the time when the temperature is low during the nighttime is set as a maximum value of the temperature difference of the light collector 2402.

When one year is set as the unit time, in consideration of the temperature change of seasons, a temperature difference between the temperature (maximum temperature) of the light collector 2402 at the time when the temperature is high during the summer time and the temperature (minimum temperature) of the light collector 2402 at the time when the temperature is low during the winter time is set as a maximum value of the temperature difference of the light collector 2402.

For example, in a case where the maximum value δT of the temperature difference of the light collector 2402 due to the temperature change per unit time is set as 50° C. and the length L2 of the light collector 2402 in the longitudinal direction is set as 1 m, when a linear expansion coefficient K at the time when an acrylic plate is used as the light collector 2402 is 80×10⁻⁶ m/° C., the light collector 2402 expands by a length of 4 mm. Accordingly, it is necessary to make a space of 4 mm or greater for the constant interval between the inner wall surface of the frame 2404 and the inclined surface 2402c of the light collector 2402.

Meanwhile, when the distance between the inner wall surface of the frame 2404 and the inclined surface 2402c of the light collector 2402 is exceedingly large, a ratio of the size of the frame 2404 to the size of the solar cell module 2401 becomes larger. As a result, since a ratio of a light receiving area becomes small, the power generation efficiency with respect to the size of the solar cell module 2401 is degraded.

Accordingly, when the maximum value of the temperature difference of the light collector 2402 due to the temperature change per unit time is set as δT, the length of the light collector 2402 in the longitudinal direction is set as L2, and the linear expansion coefficient of the light collector 2402 is set as K, it is preferable to satisfy the following expression (2).

d2>δT×L2×K (2)

In the above-described conditions of the present invention, the size d of the gap is 4 mm. In this case, it is preferable that the size d2 of the gap be set to be greater than 4 mm. Further, it is preferable that the size d2 of the gap be set in consideration of the size of the solar cell element 23, the thickness of the adhesive 2407, and the like.

According to the solar cell module 2401 of the present embodiment, since the solar cell element 23 is fixed to the inclined surface 2402c of the light collector 2402, light incident on the inclined surface 2402c can be directly guided to the solar cell element 23. For this reason, when compared to the configuration in which the reflection light reflected on the end surface of the light collector is guided to the solar cell element, the light amount of the light incident on the solar cell element 23 can be increased. Therefore, the light collection efficiency with respect to the solar cell element 23 is improved and then the power generation amount is increased.

According to the present embodiment, in regard to the area of the fixed portion of the light collector 2402 by the frame 2404, the area of the side of the second main surface 2402b of the light collector 2402 is larger than the area of the side of the first main surface 2402a of the light collector 2402. Accordingly, even when there are two sites to which the light collector 2402 is fixed by the frame 2404, the light collector 2402 can be stably fixed to the frame 2404.

### Tenth Embodiment

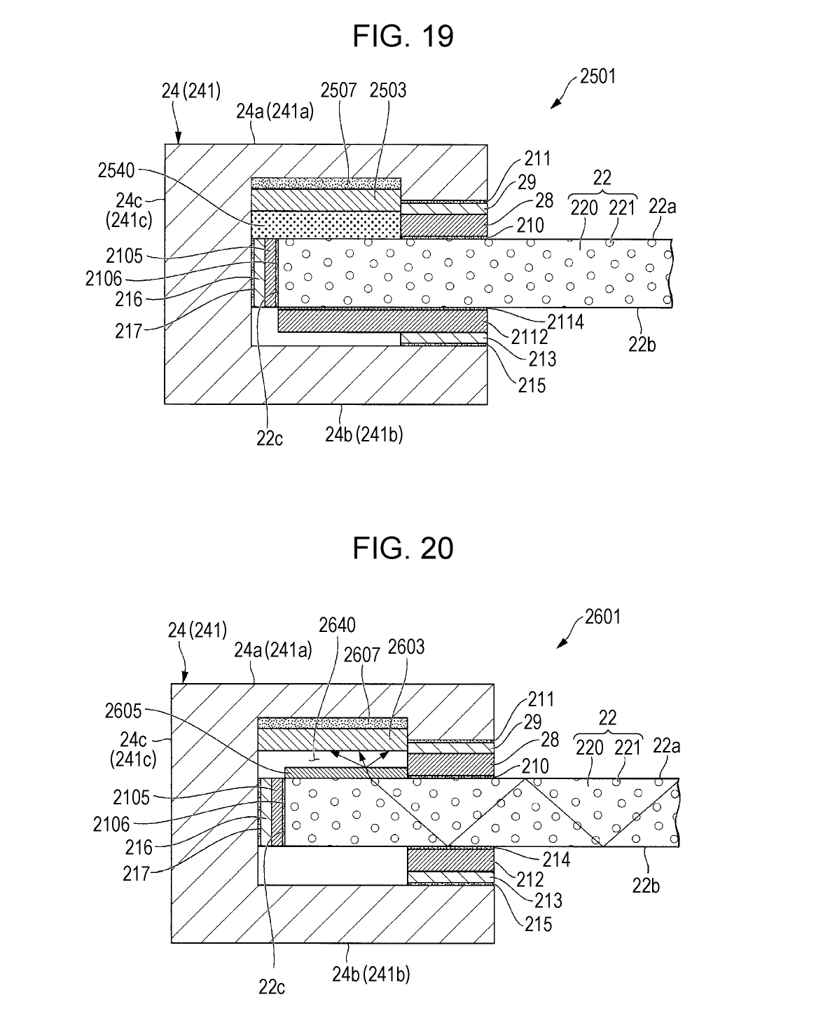

FIG. 19 is a cross-sectional view illustrating a solar cell module 2501 according to a tenth embodiment of the present embodiment.

The basic configuration of the solar cell module 2501 of the present embodiment is the same as that of the sixth embodiment, but points in which a solar cell element 2503 is fixed to the frame 24 and a space between the light collector 22 and the solar cell element 2503 is filled with a filler 2540 are different from the case of the sixth embodiment. Accordingly, description of the basic configuration of the solar cell module 2501 will not be repeated in the present embodiment.

In the present embodiment, as illustrated in FIG. 19, the solar cell element 2503 is fixed to the frame 24 and not fixed to the light collector 22. The solar cell element 2503 is bonded to the inner wall surface of the top plate portion 24a of the frame 24 by an adhesive 2507. An elastic adhesive is preferable for the adhesive 2507.

The filler 2540 is a transparent member having elasticity. For example, a silicon resin can be used as the filler 2540. Alternatively, various materials can be used as the filler 2540. Particularly, it is preferable to use a material having excellent elasticity so as to alleviate displacement of a relative position between the frame 24 and the light collector 22, the stress due to curvature of at least one of the frame 24 and the light collector 22, and influence of expansion or contraction of the light collector 22 due to an increase of the temperature. Further, it is preferable to use a liquid material whose refractive index of the filler 2540 is adjusted to the refractive index of the light collector 22. For example, matching oil having a refractive index of 1.5 can be used.

A method of filling a filler 2540 is performed by the following procedures. First, through holes are made in a portion of the frame 24. The through holes are holes to which screws can be fixed. The through holes are formed in plural.

Some of the plurality of through holes are set as injection openings of the filler 2540 and some of the remaining through holes are set as discharge openings of the filler 2540. Next, the filler 2540 is injected into the inside of the frame 24 from the injection openings. At this time, the filler 2540 is injected until the filler overflows from the discharge openings. In this manner, the air is not allowed to remain in the inside of the frame 24. In addition, the filler 2540 is filled in the inside of the frame 24 and the through holes are sealed. The sealing is performed by fixing screws coated with butyl rubber having an excellent waterproof property to the through holes. It is possible to prevent the filler 2540 from leaking from the through holes by fixing screws to the through holes with butyl rubber. In addition, it is possible to prevent leakage of the filler 2540 and to prevent moisture or the air from entering the through holes from the outside by covering the sites to which the screws are fixed with butyl rubber to be protected.

Accordingly, according to the solar cell module 2501 of the present embodiment, in a case where an impact is applied to the frame 24 or the light collector 22 due to the external force, the impact applied to the solar cell element 2503 can be absorbed by the filler 2540. Therefore, it is possible to prevent damage of the solar cell element 2503.

### Eleventh Embodiment

FIG. 20 is a cross-sectional view illustrating a solar cell module 2601 according to an eleventh embodiment of the present embodiment.

The basic configuration of the solar cell module 2601 of the present embodiment is the same as that of the fifth embodiment, but points in which a solar cell element 2603 is fixed to the frame 24, an air layer 2640 is formed between the light collector 22 and the solar cell element 2603, and a scattering layer 2605 is formed in a portion facing the solar cell element 2603 of the light collector 22 are different from the case of the fifth embodiment. Accordingly, description of the basic configuration of the solar cell module 2601 will not be repeated in the present embodiment.

In the present embodiment, as illustrated in FIG. 20, the solar cell element 2603 is fixed to the frame 24 and not fixed to the light collector 22. The solar cell element 2603 is bonded to the inner wall surface of the top plate portion 24a of the frame 24 by an adhesive 2607. An elastic adhesive is preferable for the adhesive 2607.

As the scattering layer 2605, a layer scattering light forward, which is incident in a portion facing the solar cell element 2603 of the first main surface 22a, to the solar cell element 2603 is preferable. As the scattering layer 2605, a layer with less backward scattered light is preferable. In the present embodiment, a layer capable of suppressing backward scattered light to be 4% or less of the entire incident light is used as the scattering layer 2605.

Accordingly, according to the solar cell module 2601 of the present embodiment, in a case where an impact is applied to the frame 24 or the light collector 22 due to the external force, it is possible to prevent the impact from being applied to the solar cell element 2603 using the air layer 2640. Accordingly, when compared to the configuration of the tenth embodiment in which a space between the light collector 22 and the solar cell element 2503 is filled with the filler 2540, the damage of the solar cell element 2603 can be more decreased.

Moreover, according to the present embodiment, light incident on a portion facing the solar cell element 2603 of the first main surface 22a of the light collector 22 can be scattered in the vertical direction using the scattering layer 2605. A large part of the scattered light is incident on the solar cell element 23. With such a configuration, it is possible to collect light propagating through the light collector 22 to the solar cell element 2603 even when the solar cell element 2603 is separated from the light collector 22. Therefore, the light collection efficiency with respect to the solar cell element 2603 is improved and the power generation amount is increased.

### Twelfth Embodiment

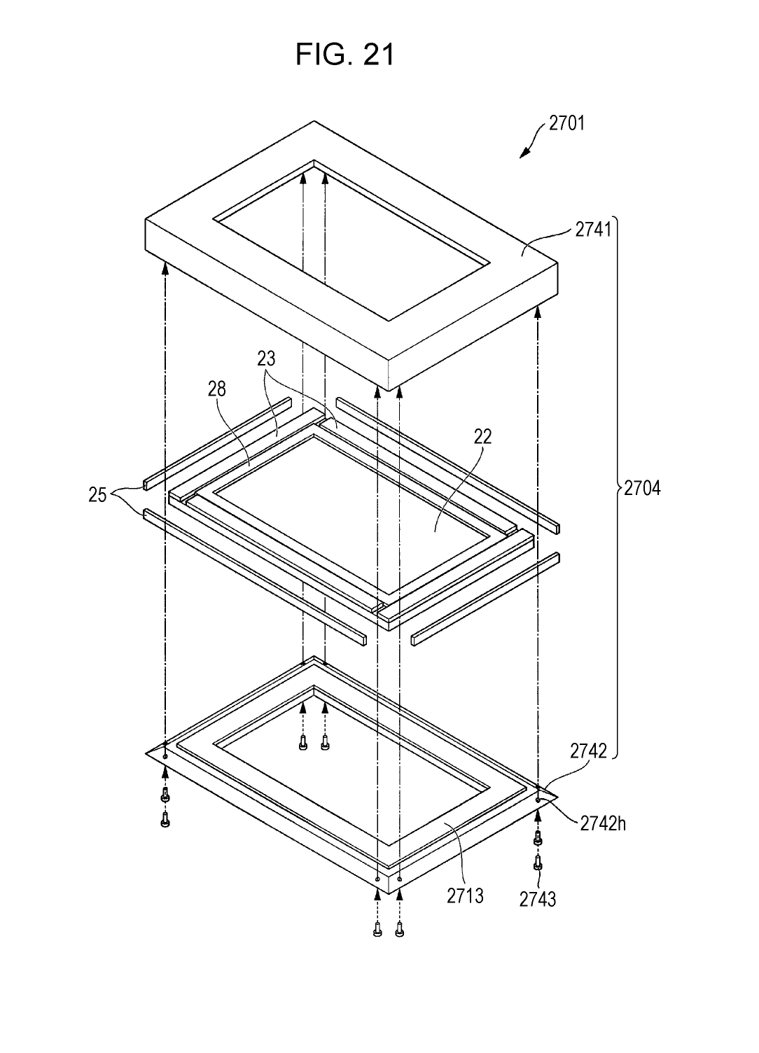

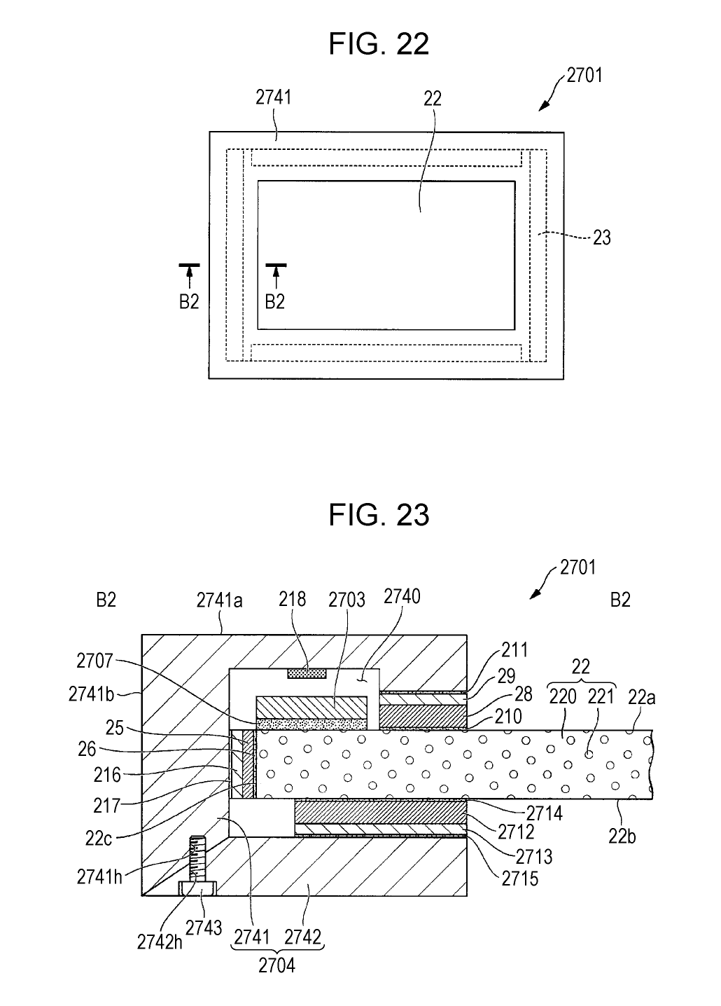

FIG. 21 is an exploded perspective view illustrating a solar cell module 2701 according to a twelfth embodiment of the present invention. FIG. 22 is a plan view illustrating the solar cell module 2701. FIG. 23 is a cross-sectional view taken along ling B2-B2 of FIG. 22.

The basic configuration of the solar cell module 2701 of the present embodiment is the same as that of the sixth embodiment, but a point in which a frame 2704 is divided into an upper frame 2741 and a lower frame 2742 is different from the case of the sixth embodiment. Accordingly, description of the basic configuration of the solar cell module 2701 will not be repeated in the present embodiment.

In the present embodiment, the frame 2704 is divided into the first main surface 22a side and the second main surface 22b side of the light collector 22 as illustrated in FIG. 21. The frame 2704 includes the upper frame 2741 and the lower frame 2742. The upper frame 2741 fixes the first main surface 22a side of the light collector 22. The lower frame 2742 fixes the second main surface 22b side of the light collector 22.

As illustrated in FIG. 23, the frame 2704 interposes the light collector 22 between the first main surface 22a side and the second main surface 22b side to be held. The upper frame 2741 includes a top plate portion 2741a and a side wall portion 2741c. The top plate portion 2741a and the side wall portion 2741c are integrally formed.

The top plate portion 2741a is arranged so as to cover the solar cell element 23. One end portion of the top plate portion 2741a is connected to a side wall portion 2741b. Another end portion of the top plate portion 2741a is extended to a portion over the solar cell element 2703. Another end portion of the top plate portion 2741a is thick. The lower frame 2742 is arranged so as to face the top plate portion 2741a of the upper frame 2741 by interposing the light collector 22 therebetween. The outer portion of the lower frame 2742 is fixed to the side wall portion 2741b of the upper frame 2741. The inner side portion of the lower frame 2742 is extended to a portion overlapped with another end portion of the top plate portion 2741a of the upper frame 2741 in the light collector 22. The length of the light collector 22 of the lower frame 2742 in the longitudinal direction is substantially equivalent to the length of the light collector 22 of the top plate portion 2741a of the upper frame 2741 in the longitudinal direction.

As illustrated in FIGS. 21 and 23, a contact surface between the end portion of the upper frame 2741 and the end portion of the lower frame 2742 is inclined. The end portion of the lower frame 2742 is provided with a through hole 2742h. As illustrated in FIG. 23, a portion in which the through hole 2742h of the lower frame 2742 is overlapped with the end portion of the upper frame 2741 is provided with a screw hole 2741h. A fixing member 2743 such as a screw is fixed to the screw hole 2741h through the through hole 2742h. In this manner, the end portion of the upper frame 2741 is fixed to the end portion of the lower frame 2742.

In the present embodiment, the solar cell element 2703 is in contact with another end portion of the top plate portion 2741a of the upper frame 2741. Accordingly, the light collector 2703 can be stably disposed in the light collector 22.

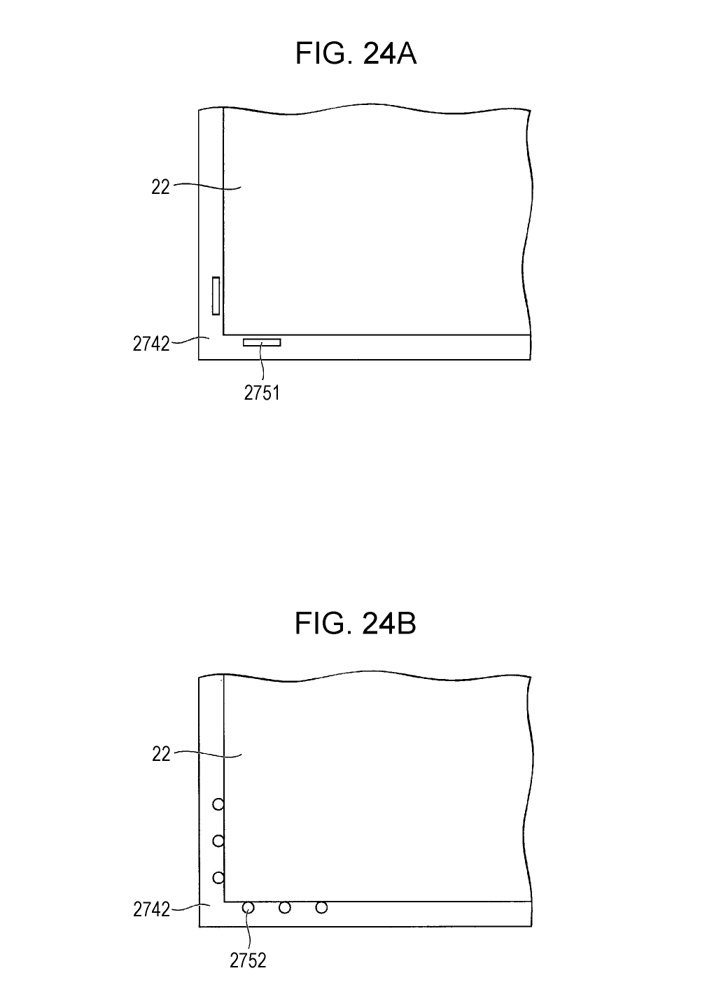

A method of assembling the frame 2704 is performed by the following procedures. First, the lower frame 2742 is fixed to the light collector 22. As a method of positioning the light collector 22 to the lower frame 2742, a method of positioning a part of a side of the light collector 22 to be set in accordance with a guide 2751 for positioning or a pin 2752 can be exemplified as illustrated in FIGS. 24A and 24B. When the guide 2751 or the pin 2752 are prepared as projections with respect to the lower frame 2742, the light collector 22 can be positioned by being fitted in and confirmation whether the positioning is completed can be easily done.

Next, the solar cell element 2703 is fixed to the end portion of the first main surface 22a of the light collector 22. Subsequently, the upper frame 2741 is covered from the upper side of the light collector 22. In regard to the positional relationship between the upper frame 2741 and the lower frame 2742, the upper frame 2741 is desirably disposed in the outside in relation to the lower frame 2742. When the lower frame 2742 is disposed in the outside in relation to the upper frame 2741, the lower frame is easily influenced by rain.

Moreover, the upper frame 2741 and the lower frame 2742 are fixed by the fixing member 2743. When the fixing member 2743 is fixed to the screw hole 2741h through the through hole 2742h, it is desirable to fix the fixing member with butyl rubber thereto. In this manner, it is possible to prevent rain from entering the inside of the solar cell module 2701. The waterproof property thereof can be more improved by applying a waterproof material such as butyl rubber to the fixed site.

When a screw is used as the fixing member 2743, the fixing strength of the upper frame 2741 and the lower frame 2742 can be adjusted by fastening power using a screw. Further, a reflective layer and a buffering layer to be arranged between the light collector 22 and the frame 2704 can be prepared in a state in which the reflective layer and the buffering layer are bonded to the light collector 22 or the frame 2704 in advance. Further, the reflective layer and the buffering layer may be interposed between the light collector 22 and the frame 2704 using the fastening power of a screw.

In addition, it is preferable to place a mark on the first main surface 22a or the second main surface 22b of the light collector 22 before the light collector 22 is fixed to the lower frame 2742. A mark capable of visual confirming on the front or back side of the light collector 22 is preferable for the mark. The mark is placed on a place not disturbing light extraction. For example, a layer that is not optically bonded is colored. In this manner, it is possible to prevent a light receiving surface of the light collector 22 from being arranged toward the opposite side.

In a case where a method of preparing a solar cell module is a method of fitting a light collector into a frame to be assembled, the light collector is curved or deformed in some cases when the light collector on which a solar cell element is disposed is fitted into the frame. Moreover, the solar cell element is brought into contact with the opening portion of the frame in some cases. In this case, a stress is applied to the solar cell element.

Meanwhile, in the solar cell module 2701 of the present embodiment, the solar cell module 2701 can be assembled by interposing the light collector 22 between the upper frame 2741 and the lower frame 2742. Accordingly, it is possible to prevent the stress from being applied to the solar cell element. Therefore, it is possible to prevent damage of the solar cell element 23.

Furthermore, the example in which the frame 2704 is divided into two frames of the upper frame 2741 and the lower frame 2742 has been described in the present embodiment as an example, but the example is not limited thereto. The frame may be divided into three or more frames if necessary.

(Modified Example of Solar Cell Element)

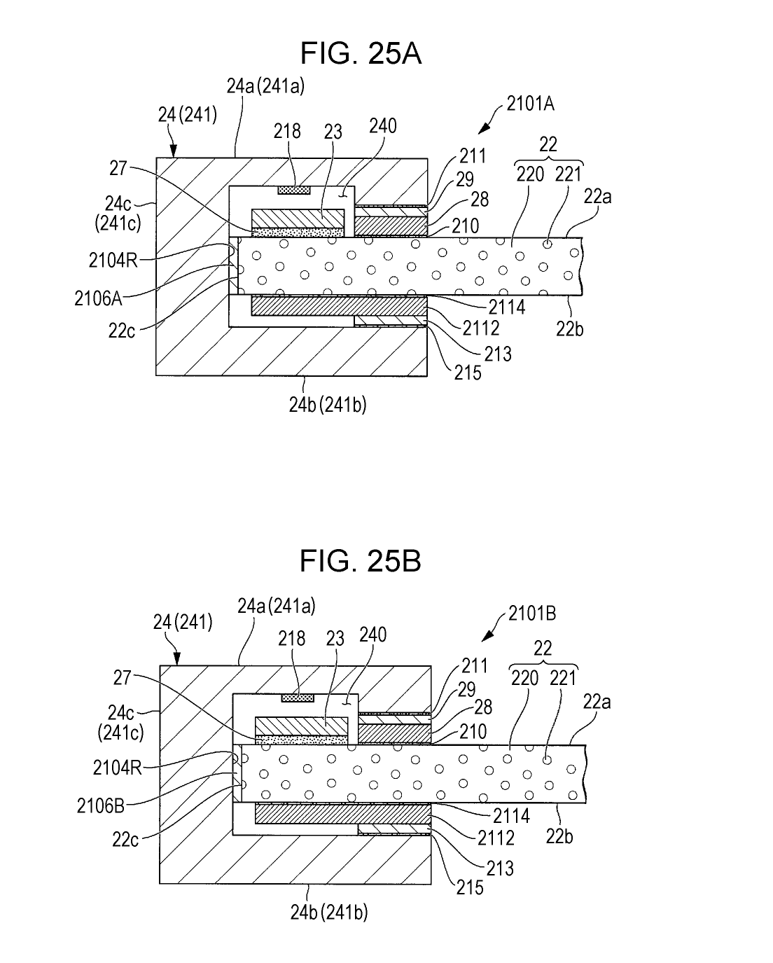

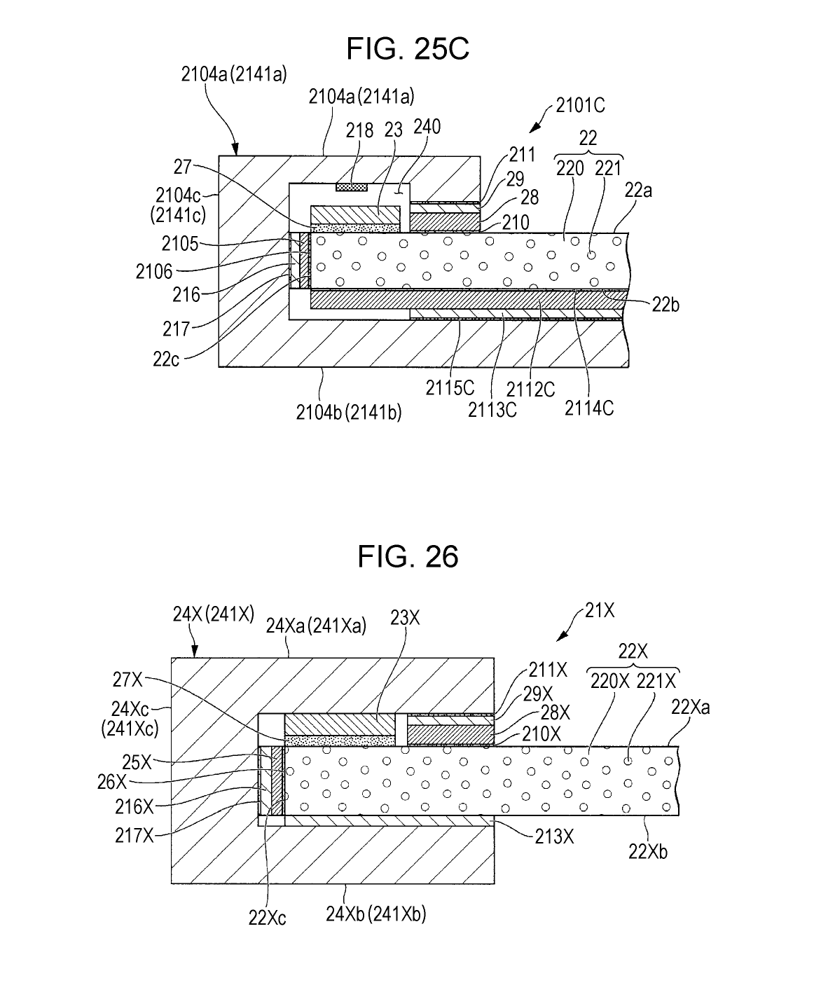

Hereinafter, modified examples of the solar cell module of the fifth embodiment to the twelfth embodiment will be described with reference to FIGS. 25A and 25B.

### First Modified Example B

FIG. 25A is a cross-sectional view illustrating a first modified example B of a solar cell module.

In the fifth embodiment, the reflective layer 25 is bonded to the end surface 22c of the light collector 22 by the transparent adhesive 26. Meanwhile, in a solar cell module 2101A of the present modified example, the reflective layer is not provided on the end surface 22c of the light collector 22 as illustrated in FIG. 25A. In the present modified example, the inner wall surface of the side wall portion 24c of the frame 24 is boned to the end surface 22c of the light collector 22 by a transparent adhesive 2106A. A portion facing the end surface 22c of the light collector 22 is mirror-finished in the inner wall surface of the side wall portion 24c of the frame 24. In this manner, the portion facing the end surface 22c of the light collector 22 is made into a mirror reflective surface 2104R in the inner wall surface of the side wall portion 24c of the frame 24.

Even in the solar cell module 2101A of the present modified example, it is possible to prevent damage of the solar cell element 23. Further, light propagating through the light collector 22 is reflected on the mirror reflective surface 2104R, the surface of the reflective layer 28, and the surface of the reflective layer 2112, and then returns to the inside of the light collector 22 again. Accordingly, light loss can be decreased. Further, since the reflective layer 25 is not required to be separately provided, the number of components can be reduced. Therefore, it is possible to reduce the cost and the weight of the solar cell module 2101A.

### Second Modified Example B

FIG. 25B is a cross-sectional view illustrating a second modified example B of a solar cell module.

In the first modified example B, the inner wall surface of the side wall portion 24c of the frame 24 is bonded to the end surface 22c of the light collector 22 by the transparent adhesive 2106A. Meanwhile, in a solar cell module 2101B of the present modified example, the inner wall surface of the side wall portion 24c of the frame 24 is bonded to the end surface 22c of the light collector 22 by the adhesive 2106B as illustrated in FIG. 25B. The adhesive 2106B is obtained by dispersing a scattering material to a transparent adhesive. In this manner, the adhesive 2106B functions as a scattering layer.

Even in the solar cell module 2101B of the present modified example, it is possible to prevent damage of the solar cell element 23. Further, light incident on the end surface 22c of the light collector 22 can be scattered and reflected by the adhesive 2106B. In this manner, the amount of light traveling directly to the solar cell element 23 can be increased. Further, since the reflective layer 25 is not required to be separately provided, the number of components can be reduced. Therefore, it is possible to reduce the cost and the weight of the solar cell module 2101B.

### Third Modified Example C

FIG. 25C is a cross-sectional view illustrating a third modified example C of a solar cell module.

In the fifth embodiment, the length of the light collector 22 of the bottom plate portion 241b of the frame 24 in the longitudinal direction is the same as that of the light collector 22 of the top plate portion 241a in the longitudinal direction. Meanwhile, in a solar cell module 2101C of the present modified example, the length of the light collector 22 of a bottom plate portion 2104b of a frame 2104 in the longitudinal direction is longer than that of the light collector 22 of a top plate portion 2104a in the longitudinal direction as illustrated in FIG. 25C. In the present embodiment, the length of the light collector 22 of the bottom plate portion 2104b of the frame 2104 in the longitudinal direction is longer than that of the end portion of a portion over the solar cell element 23 of the top plate portion 2104a by, for example, approximately 10 cm. moreover, the length of the light collector 22 of the bottom plate portion 2104b of the frame 2104 in the longitudinal direction can be increased as needed. This is because the extraction amount of solar light is not influenced even when the bottom plate portion 2104b of the frame 2104 is arranged on the second main surface 22b side of the light collector 22. For example, the bottom plate portion 2104b of the frame 2104 may be formed over the whole portion facing the second main surface 22b of the light collector 22.

Even in the solar cell module 2101C of the present modified example, it is possible to prevent damage of the solar cell element 23. In regard to the area of a fixed portion of the light collector 22 by the frame 2104, the area of the second main surface 22b side of the light collector 22 is larger than the area of the first main surface 22a side of the light collector 22. Therefore, the light collector 22 can be rigidly and stably fixed to the frame 2104.

In addition, in the present modified example, the configuration in which the light collector 22 is fixed to three sites of the first main surface 22a side, the second main surface 22b side, and the end surface 22c side by the frame 2104 has been described, but the configuration is not limited thereto. For example, the configuration of the modified example can be applied to the configuration of the ninth embodiment, in which the light collector 2402 is fixed to two sites in the vertical direction by the frame 2404. The configuration of the present modified example, is particularly effective in the configuration of the ninth embodiment. Even when the light collector 2402 is fixed to two sites in the vertical direction by the frame 2404, the light collector 2402 can be rigidly and stably fixed by the frame 2404.

### Thirteenth Embodiment

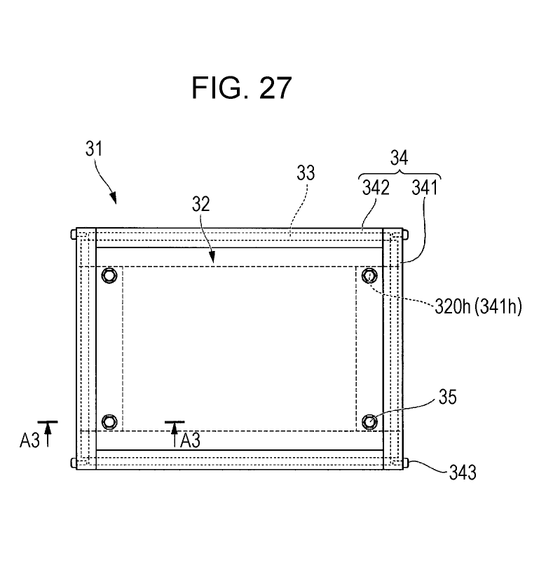

Hereinafter, a thirteenth embodiment of the present invention will be described with reference to FIGS. 27 to 30.

Further, in regard to all figures described below, for clarity of respective constituent elements, the scale of size of each constituent element is set to be different from the actual size thereof.

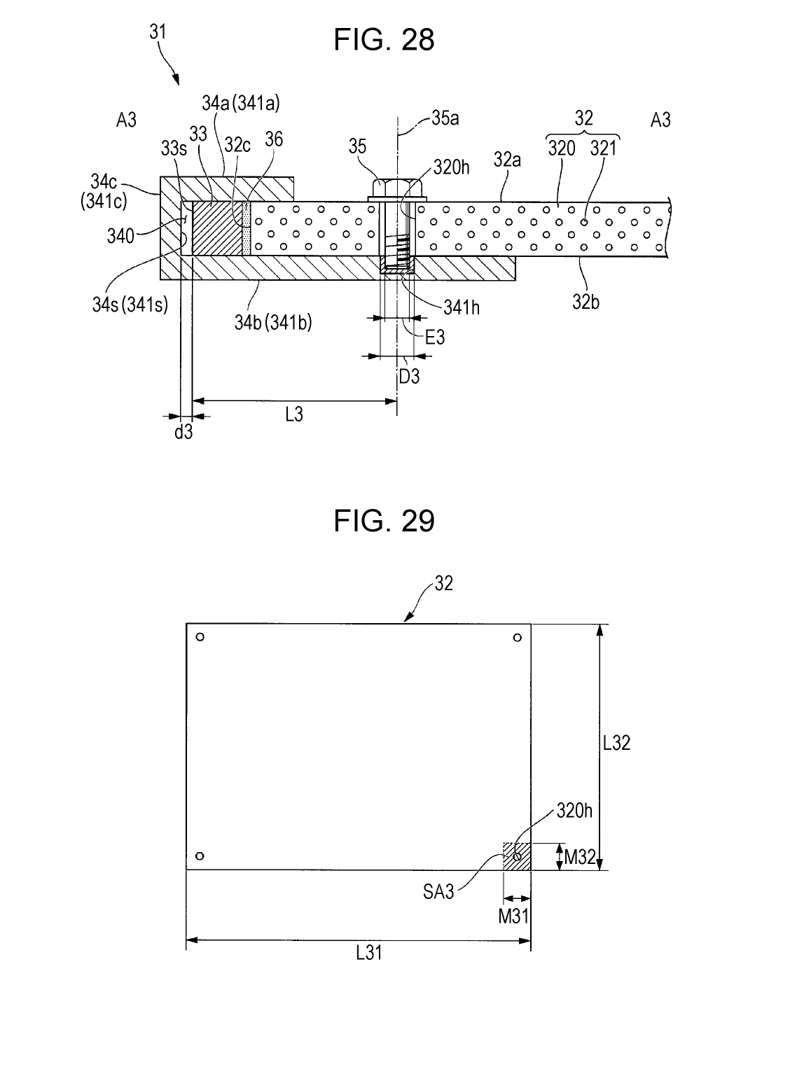

FIG. 27 is a schematic view illustrating a solar cell module 31 of a thirteenth embodiment of the present invention. FIG. 28 is a cross-sectional view taken along line A3-A3 of FIG. 27.

As illustrated in FIGS. 27 and 28, the solar cell module 31 includes a light collector 32, a solar cell element 33, a frame 34, and a position restricting member 35.

The light collector 32 is a plate member having a shape of a rectangle in a plan view. The light collector 32 includes a first main surface 32a, a second main surface 32b, and an end surface 32c as illustrated in FIG. 28. The first main surface 32a is a light incident surface. The second main surface 32b is a surface on the opposite side of the first main surface 32a. The end surface 32c is a light emission surface. In addition, as an example of the size of the light collector 32, the length of the long side is approximately 100 cm, the length of the short side is approximately 90 cm, and the thickness is approximately 4 mm.

The light collector 32 is a phosphor light collector allowing a phosphor 321 to be dispersed to a transparent base material 320 as illustrated in FIG. 28. A material which is the same as that of the base material 16 according to the first embodiment or the transparent base material 220 according to the fifth embodiment can be applied to the transparent base material (transparent resin) 320. In the present embodiment, a PMMA resin (refractive index:1.49) is used as the transparent base material 320. The light collector 32 is formed by allowing the phosphor 321 to be dispersed to the PMMA resin. Further, the refractive index of the light collector 32 is 1.50 which is approximately the same as that of the PMMA resin because the amount of the dispersed phosphor 321 is small.

The phosphor 321 is a photofunctional material that absorbs UV light or visible light and emits the UV light or the visible light to be radiated. As the photofunctional material, an organic phosphor is exemplified.

As the organic phosphor, the same material as the phosphor 17 of the first embodiment can be applied.

In the same manner as the phosphor 17 of the first embodiment, the organic phosphor may use one kind of a pigment or two or more kinds of pigments. In a case where two or more kinds of pigments are used, the amount of external light absorbed by the whole pigments to be used can be increased and the external light can be efficiently used by selecting pigments whose absorption wavelength bands of respective pigments are not overlapped with one another.

In addition, an inorganic phosphor can be used as the phosphor.

Further, various kinds of dyes (direct dyes, acidic dyes, basic dyes, and disperse dyes) can be used as a phosphor as long as the dyes are fluorescent.

In the case of the present embodiment, one kind of phosphor 321 is dispersed into the inside of the light collector 32. The phosphor 321 radiates red fluorescence by absorbing orange light. In the present embodiment, as the phosphor 321, Lumogen R305 (trade name, manufactured by BASF Corporation) is used. The phosphor 321 absorbs light having a wavelength of approximately 600 nm or less. The emission spectrum of the phosphor 321 has a peak wavelength at 610 nm.

Moreover, the present embodiment is not limited to the case where one kind of phosphor is used, a plurality kinds (two or more kinds) of phosphors may be used.

The light receiving surface of the solar cell element 33 is arranged so as to face the end surface 32c of the light collector 32. As the solar cell element 33, solar cells exemplified as the solar cell element 23 of the fifth element can be used. Among those, since power generation with high efficiency is possible, a compound-based solar cell or a quantum dot solar cell is preferable as the solar cell element 33. Particularly, a GaAs solar cell which is a compound-based solar cell showing high efficiency at a peak wavelength (610 nm) of the emission spectrum of the phosphor 321 is desirable. Alternatively, a compound-based solar cell exemplified as the solar cell element 14a of the first embodiment can be used. However, another kind of solar cell such as a Si-based solar cell or an organic solar cell can be used according to the cost or usage thereof.

The solar cell element 33 is bonded to the end surface 32c of the light collector 32 by the transparent adhesive 36. A thermosetting adhesive such as an ethylene-vinyl acetate copolymer (EVA), an epoxy-based adhesive, a silicone-based adhesive, or a polyimide-based adhesive is preferable for the transparent adhesive 36. In addition, the refractive index of the transparent adhesive 36 is 1.50 which is approximately the same as that of the light collector 32.

In FIG. 27, the example in which the solar cell element 33 is disposed on four end surfaces 34c of the light collector 32 has been described, but the solar cell element 33 may be disposed on one to three end surfaces 34c of the light collector 32. In a case where the solar cell element 33 is disposed on some of the end surfaces (one side, two sides, or three sides) of the light collector 32, it is preferable that a reflective layer be disposed on the end surface on which the solar cell element is not disposed.

A material exemplified as the reflective layer 25 of the fifth embodiment can be used as the reflective layer.

The frame 34 is a frame having a shape of a rectangle in a plan view as illustrated in FIG. 27. The frame 34 holds the light collector 32. The frame 34 is arranged so as to cover the solar cell element 33. The thickness of the frame 34 is approximately 2 mm. A forming material of the frame 34 is a metal such as Al. Alternatively, various materials can be used as the forming material of the frame 34. Particularly, it is preferable to use a material with high strength and light in weight.

The position restricting member 35 is provided on a portion in which the light collector 32 is overlapped with the frame 34 when seen from the direction normal to the first main surface 32a as illustrated in FIGS. 27 and 28. The position restricting member 35 restricts a relative position between the light collector 32 and the frame 34. Specifically, the position restricting member 35 restricts the relative position between the light collector 32 and the frame 34 in a direction parallel to the first main surface 32a and a direction vertical to the first main surface 32a.

In the present embodiment, the light collector 32 is provided with a through hole 320h as illustrated in FIG. 28. A screw is used as a penetrating member of the position restricting member 35. A screw 35 is fixed to the frame 34.

A screw hole 341h is provided in a portion in which the frame 34 is overlapped with the through hole 320h. The screw 35 is fixed to the screw hole 341h through the through hole 320h.

A metal is used for a forming material of the screw 35. Alternatively, various materials can be used as the forming material of the screw 35. Particularly it is preferable to use an alloy such as stainless steel (SUS) from a viewpoint of obtaining high strength.

In the present embodiment, the frame 34 is divided for each side of the light collector 32 as illustrated in FIG. 27. The frame 34 includes a first sub-frame 341 and a second sub-frame 342. The first sub-frame 341 is arranged along the short side of the light collector 32. Two first sub-frames 341 for two short sides which face each other are respectively arranged. The second sub-frame 342 is arranged along the long side of the light collector 32. Two second sub-frames 342 for two long sides which face each other are respectively arranged.

The screw hole 341h is provided in a portion in which the first sub-frame 341 is overlapped with the through hole 320h. The end portion of the first sub-frame 341 is fixed to the end portion of the second sub-frame 342 by the fixing member 343 such as a screw.

As illustrated in FIG. 28, the frame 34 includes a top plate portion 34a, a bottom plate portion 34b, and a side wall portion 34c. Here, the configuration of the frame 34 will be described with reference to the figure illustrating that the first sub-frame 341 includes the top plate portion 341a, the bottom plate portion 341b, and the side wall portion 341c. Further, the configuration of the second sub-frame 342 has the same configuration as that of the first sub-frame 341.

The top plate portion 341a is formed so as to cover the solar cell element 33. One end portion of the top plate portion 341a is connected to the side wall portion 341c. Another end portion of the top plate portion 341a is extended to the end portion of the first main surface 32a of the light collector 32. The bottom plate portion 341b is arranged so as to face the top plate portion 341a by interposing the light collector 32 therebetween. One end portion of the bottom plate portion 341b is connected to the side wall portion 341c. Another end portion of the bottom plate portion 341b is extended to a portion over the through hole 320h of the light collector 32. The length of the light collector 32 of the bottom plate portion 341b in the longitudinal direction is larger than that of the light collector 32 of the top plate portion 341a in the longitudinal direction. The screw hole 341h is provided in a portion that is more extended than the top plate portion 341a in the bottom plate portion 341b.

As illustrated in FIG. 28, the inner wall surface 34s of the frame 34 is separated from the solar cell element 33. Here, an arrangement relationship between the inner wall surface 34s of the frame 34 and the solar cell element 33 is described with reference to the figure illustrating that the inner wall surface 341s of the first sub-frame 341 is separated from the solar cell element 33. In addition, an arrangement relationship between the inner wall surface of the second sub-frame 342 and the solar cell element 33 is the same as the arrangement relationship described above, and accordingly, description thereof will not be repeated.

In the present embodiment, a space 340 is provided between the inner wall surface 341s of the first sub-frame 341 and a surface 33s on the opposite side of an end surface 33c of the solar cell element 33. The space 340 is provided with an air layer interposed therebetween.

Further, it is preferable that the interval d3 of the space 340 be disposed from a viewpoint of securing the constant space 340 between the inner wall surface 341s of the first sub-frame 341 and the surface 33s of the solar cell element 33 in consideration of the diameter of the through hole 320h, the dimensional tolerance of the through hole 320h, the outer diameter of the screw 35, and the positional tolerance of the screw hole 341h. For this, when the diameter of the through hole 320h is set as D3, the dimensional tolerance of the through hole 320h is set as Dt, the outer diameter of the screw 35 is set as E3, and the positional tolerance of the screw hole 341h is set as Ft, it is preferable to satisfy the following expression (3).

d3>(D3+Dt−E3)+Ft (3)

Further, it is preferable that the interval d3 of the space 340 be set such that the constant space 340 is secured between the inner wall surface 341s of the first sub-frame 341 and the surface 33s of the solar cell element 33 even when the light collector 32 is thermally expanded due to a change of the temperature per unit time. For this, when the maximum value of the temperature difference of the light collector 32 due to a change of the temperature per unit time is set as ΔT, the distance between the position restricting portion (center of the through hole 320h) of the light collector 32 and the end surface 32c is set as L3, and the linear expansion coefficient of the light collector 32 is set as K, it is preferable to satisfy the following expression (4).

d3>ΔT·L3·K (4)

Further, the maximum value of the temperature difference of the light collector 32 due to the change of the temperature per unit time can be set as follows. For example, when one day is set as the unit time, a temperature difference between the temperature (maximum temperature) of the light collector 32 at the time when the temperature is high during the daytime and the temperature (minimum temperature) of the light collector 32 at the time when the temperature is low during the nighttime is set as a maximum value of the temperature difference of the light collector 32.

When one year is set as the unit time, in consideration of the temperature change of seasons, a temperature difference between the temperature (maximum temperature) of the light collector 32 at the time when the temperature is high during the summer time and the temperature (minimum temperature) of the light collector 32 at the time when the temperature is low during the winter time is set as a maximum value of the temperature difference of the light collector 32.

For example, in a case where the maximum value ΔT of the temperature difference of the light collector 32 due to the temperature change per unit time is set as 90° C. and the distance L between the position restricting portion of the light collector 32 and the end surface 32c is set as 100 m, when a linear expansion coefficient K at the time when an acrylic plate is used as the light collector 32 is 70, the interval d3 of the space 340 is 0.63 mm. In this case, it is preferable that the interval d3 of the space 340 be set to be greater than 0.63 mm.

FIG. 29 is a plan view illustrating an arrangement position of the through holes 320h provided in the light collector 32.

As illustrated in FIG. 29, the through holes 320h are arranged on the outer peripheral portion of the light collector 32. Specifically, four through holes 320h in total are arranged one by one on four corners of the light collector 32. Further, the number of arranged through holes 320h is not limited thereto, and a plurality of through holes 320h can be arranged if necessary.

When compared to a case in which the through hole 320h is arranged in the center portion of the light collector 32, decrease in light collection efficiency of the light collector 32 with respect to the end surface 32c can be suppressed by arranging the through hole 320h in the outer peripheral portion of the light collector 32.

This is due to the following reasons. When light (for example, solar light) is incident on the light collector 32, the phosphor 321 scattered to the inside of the light collector 32 absorbs light and isotropically radiates fluorescence. The isotropically radiated fluorescence is guided to the inside of the light collector 32 and collected on the end surface 32c of the light collector 32.

Here, the light collection amount collected in a certain position of the end surface 32c of the light collector 32 using the above-described mechanism is defined as the “light collection amount obtained by light being incident the a certain position of the end surface 2.”

Even in a case where light is uniformly incident on the light collector 32, it does not mean that fluorescence is uniformly collected on the end surface 32c of the light collector 32. The light collection amount obtained by light being incident varies depending on the position of the end surface 32c of the light collector 32. That is, the light collection amount has positional dependency of the end surface 32c. In the present embodiment, when the positional dependency of the light collection amount on one side of the light collector 32 is considered, the light collection amount obtained by light being incident on the end portion of one side is smaller than the light collection amount obtained by the light being incident on the center portion of one side.

Therefore, when compared to the case in which the through hole 320h is arranged in the center portion of the light collector 32, decrease in light collection efficiency of the light collector 32 with respect to the end surface 32c can be suppressed by arranging the through hole 320h in the outer peripheral portion of the light collector 32.

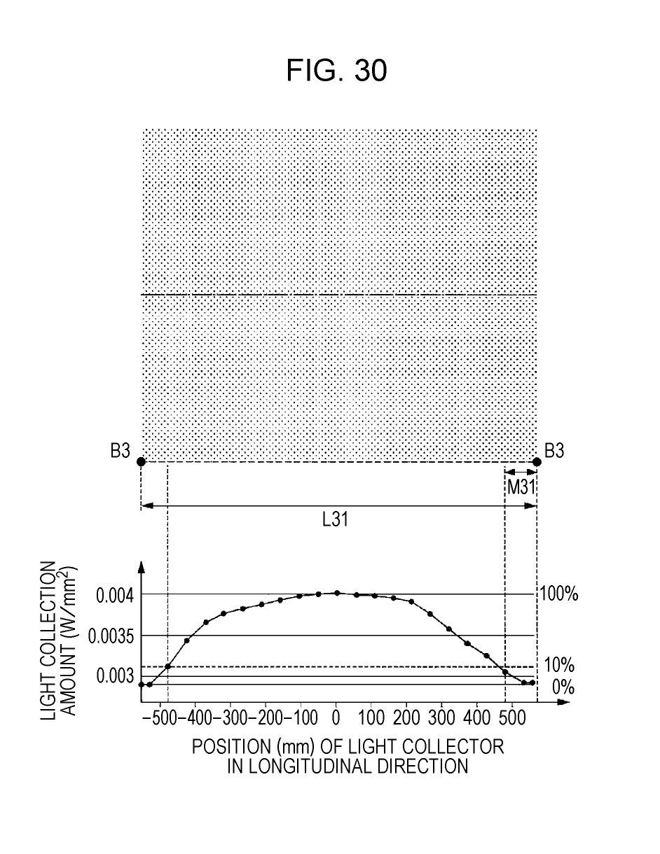

The inventors of the present application verified a relationship between the position of the light collector in the longitudinal direction and the light collection amount of the light collector by simulation. Hereinafter, the results of the simulation will be described with reference to FIG. 30.

The upper part of FIG. 30 is a plan view of the light collector. The lower part of FIG. 30 is a graph showing a relationship between the position (position of the light collector in the longitudinal direction) of the light collector in a direction along the line B3-B3 of the upper part and the light collection amount. Moreover, in the graph of the lower part, the horizontal axis represents the position of the light collector in the longitudinal direction. The vertical axis represents the light collection amount obtained by light being incident on the position of the light collector in the longitudinal direction. Here, the length of the long side of the light collector is set 1120 mm. The number “0” of the horizontal axis corresponds to the center of the position of the light collector in the longitudinal direction.

As shown in the graph of the lower part of FIG. 30, it is confirmed that the light collection amount obtained by light being incident on the center portion of the long side of the light collector is larger than the light collection amount obtained by light incident on the end portion of the long side of the light collector. Therefore, in order to reduce the influence on the light collection efficiency, it is understood that the arrangement position of the through hole is desirably set in the end portion of the long side of the light collector rather than the center portion of the long side of the light collector. That is, it is considered that the arrangement position of the through hole is desirably set on four corners of the light collector rather than the center portion of the light collector.

Further, on the right side of the vertical axis of FIG. 30, the light collection amount in the center of the position of the light collector in the longitudinal direction is set as 100% as the maximum value of the light collection amount and the light collection amount in the edge of the position of the light collector in the longitudinal direction is set as 0% as the minimum value of the light collection amount.

When the length of the long side of the light collector is set as L31, and the distance from the short side of the light collector to the position in which the light collection amount is 10% of the maximum light collection amount in the longitudinal direction is set as M31, the inventors of the present application found that the following equation (5) is satisfied.

M31=L31/10 (5)

Hereinafter, the short side of the light collector can be considered in the same manner as the above. Similarly to the equation (5), as illustrated in FIG. 29, when the length of the short side of the light collector is set as L32 and the distance from the short side of the light collector to the position in which the light collection amount is 10% of the maximum light collection amount in the short direction is set as M32, it is considered that the following equation (6) is satisfied.

M32=L32/10 (6)

Moreover, the distances M31 and M32 are set so as to satisfy the above-described equations (5) and (6). As illustrated in FIG. 29, reduction in light collection amount 2 is suppressed and thus the influence on the light collection efficiency can be decreased by arranging the through hole 320h in an arrangement region SA3 with the distances M31 and M32 set as described above.

As described above, according to the solar cell module 31 in the present embodiment, a relative position between the light collector 32 and the frame 34 is restricted be the screw 35. For this reason, since the solar cell element 33 is not required to be rigidly fixed by the frame 34, the problem of application of the stress to the solar cell element 33 is not generated. Further, the light collector 32 and the frame 34 are fixed by the screw 35, it is possible to prevent disposition of the frame 34 due to the external force and to prevent an impact from being applied to the solar cell element 33. According to the present embodiment, it is possible to prevent damage of the solar cell element 33.

In addition, according to the present embodiment, since a screw is used as a penetrating member of the position restricting member 35, it is possible to fix the light collector 32 and the frame 34 using a simple method. Further, the cost can be decreased because a screw is a general-purpose item.

Moreover, according to the present embodiment, since a forming material of the screw 35 is a metal, the surface of the screw 35 has a relatively high reflectance. Therefore, even when light propagating through the light collector 32 escapes from the through hole 320h, a part of the escaping light is reflected on the surface of the screw 35 and then returns to the inside of the light collector 32 again. Accordingly, light loss can be decreased.

Moreover, according to the present embodiment, since the frame 34 is formed so as to cover the solar cell element 33, it is possible to prevent foreign matters such as dust or rainwater from entering the solar cell element 33.

In addition, according to the present embodiment, since the space 340 is provided between the inner wall surface 34s of the frame 34 and the surface 33s of the solar cell element 33, when an impact is applied to the frame 34 or the light collector 32 due to the external force, it is possible to prevent the impact from being applied to the solar cell element 33 because of the space 340. Further, the stress generated due to deflection, curvature, thermal expansion, or the like of the light collector 32 can escape because of the space 340.

Therefore, it is possible to prevent damage of the solar cell element 33.

Further, the light collector 32 of the present embodiment is configured of a phosphor light collector containing a phosphor which absorbs incident light and emits fluorescence, but the configuration is not limited thereto. For example, the light collector 22 may be configured of a light collector containing no phosphor. Further, the light collector may be configured of a light collector on which a reflective surface that reflects incident light and changes the travelling direction of the light is provided.

Moreover, in the present embodiment, the configuration in which the position restricting member 35 restricts the relative position between the light collector 32 and the frame 34 in a direction parallel to the first main surface 32a and a direction vertical to the first main surface 32a has been described, but the present invention is not limited to the configuration. For example, a configuration in which the position restricting member 35 does not restrict the relative position between the light collector 32 and the frame 34 in the direction vertical to the first main surface 32a and restricts the relative position between the light collector 32 and the frame 34 in the direction parallel to the first main surface 32a may be employed.

### Fourteenth Embodiment

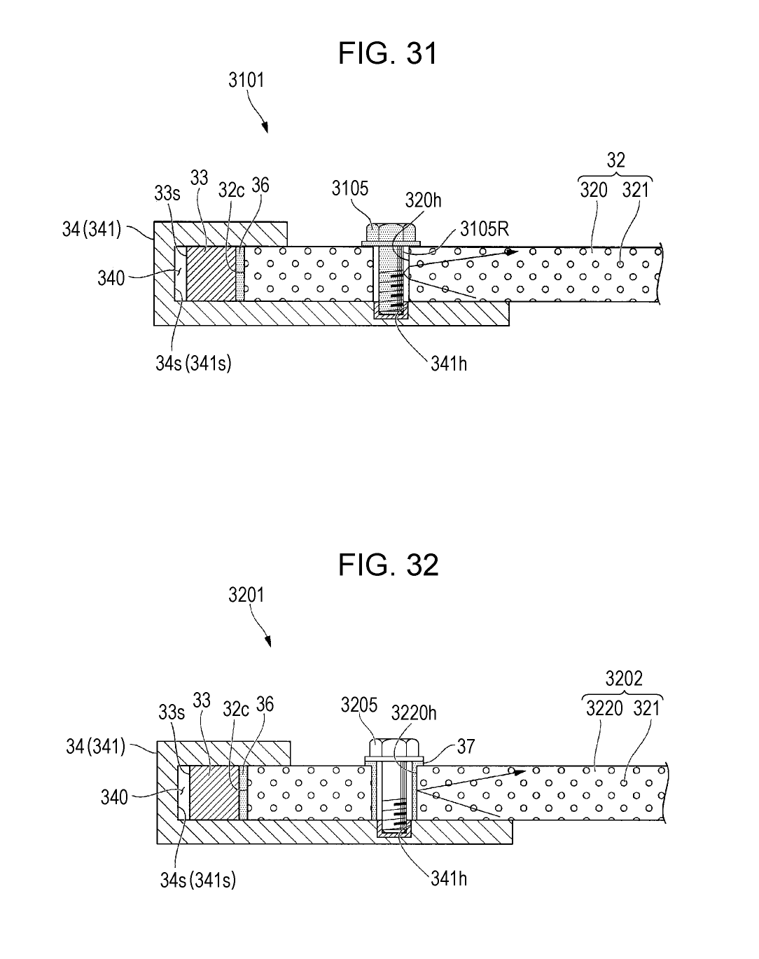

FIG. 31 is a cross-sectional view illustrating a solar cell module 3101 according to a fourteenth embodiment of the present invention, which corresponds to FIG. 28.

The basic configuration of the solar cell module 3101 of the present embodiment is the same as that of the thirteenth embodiment, but only a point in which a reflective layer 3105R is formed on the surface of a screw 3105 is different from the case of the thirteenth embodiment.

Accordingly, description of the basic configuration of the solar cell module 3101 will not be repeated in the present embodiment.

In the present embodiment, as illustrated in FIG. 31, a screw 3105 whose surface has a reflective film 3105R formed thereon is used as a position restriction member.

Moreover, in consideration of the wavelength of light propagating through the light collector 32, it is preferable that a forming material of the reflective film 3105R be made of a metal having a high reflectance with respect to light escaping from the through hole 320h. Hereinafter, an example of the reflectance for each wavelength of metals desirable for the forming materials of the reflective film 3105R is listed in [Table 1].

TABLE 1

| Forming material of | | | | | | |
|---|---|---|---|---|---|---|
| reflective film | | SUS | Al | Cu | Au | Ag |
| Wave- | 280 (UV region) | 37.6 | 92.3 | 33 | 37.8 | 25.2 |
| length | 400 (ultraviolet) | 41.2 | 92.4 | 47.5 | 38.7 | 94.8 |
| λ (nm) | | (λ = 361) | | | | |
| | 700 (red) | 68.8 | 89.9 | 97.5 | 97 | 98.5 |
| | 1000 (infrared region) | 72 | 93.9 | 98.5 | 98.2 | 98.9 |

In the present embodiment, the phosphor 321 that absorbs orange light and radiates red fluorescence is used. As listed in Table 1, the reflectance of SUS with respect to light having a wavelength of 700 nm to 1000 nm is approximately 70%. Meanwhile, the reflectance of Al, Cu, Au, or Ag is approximately in the range of 90% to 99%. The reflectance of Al, Cu, Au, or Ag is higher than that of SUS by a range of approximately 20% to 29%. Accordingly, a metal film such as Al, Cu, Au, or Ag is preferably used as the reflective film 3105R.

As a method of forming the reflective film 3105R, a method of performing a plating treatment on a surface of a base material of the screw 3105 or a method of coating the surface of the base material of the screw 3105 with a painting material such as paint can be exemplified.

When a plating treatment is performed, it is preferable to complexly use Ni from a viewpoint of obtaining high gloss and Cr or SnCo from a viewpoint of obtaining excellent corrosion resistance. From such viewpoints, Ni—Cr plating or Ni—SnCo plating can be generally used. From a viewpoint of obtaining high reflectance at low cost, Ag plating or the like is preferably used.

Moreover, when the reflective film 3105R is formed, a material without a screw thread in a portion of the surface of the base material of the screw 3105 not entering the screw hole 341h is preferably used as a base material of the screw 3105. In this manner, the surface of the reflective film 3105R, specifically, a portion of the reflective film 3105R that reflects light escaping from the through hole 320h can be smoothened.

According to the solar cell module 3101 of the present embodiment, since the surface of the screw 3105 has a high reflectance, a part of light escaping the through hole 320h is reflected on the surface of the screw 3105 and then easily returns to the inside of the light collector 32 again. Accordingly, light loss can be further decreased compared to the case in which the reflective film is not formed on the surface of the screw.

### Fifteenth Embodiment

FIG. 32 is a cross-sectional view illustrating a solar cell module 3201 according to a fifteenth embodiment of the present invention, which corresponds to FIG. 28.

The basic configuration of the solar cell module 3201 of the present embodiment is the same as that of the thirteenth embodiment, but only a point in which a reflective layer 37 is formed between a through hole 3220h and a screw 3205 is different from the case of the thirteenth embodiment. Accordingly, description of the basic configuration of the solar cell module 3201 will not be repeated in the present embodiment.

In the present embodiment, as illustrated in FIG. 32, the reflective film 37 is formed along the inner wall surface of the through hole 3220h. The reflective film 37 is formed between the screw head of the screw 3205 and an opening portion of the through hole 3220h in the light collector 3202.

In addition, as the reflective layer 37, a dielectric multilayer film such as ESR or a metal film such as Al, Cu, Au, or Ag may be used.

According to the solar cell module 3101 of the present invention, since light propagating through the light collector 3202 is reflected on the surface of the reflective film 37 even though the light reaches the through hole 3220h, escaping of the light from the through hole 3220h is prevented. Therefore, light loss can be further decreased compared to the configuration in which the reflective film 37 is not formed between the through hole 3220h and the screw 3205.

### Sixteenth Embodiment

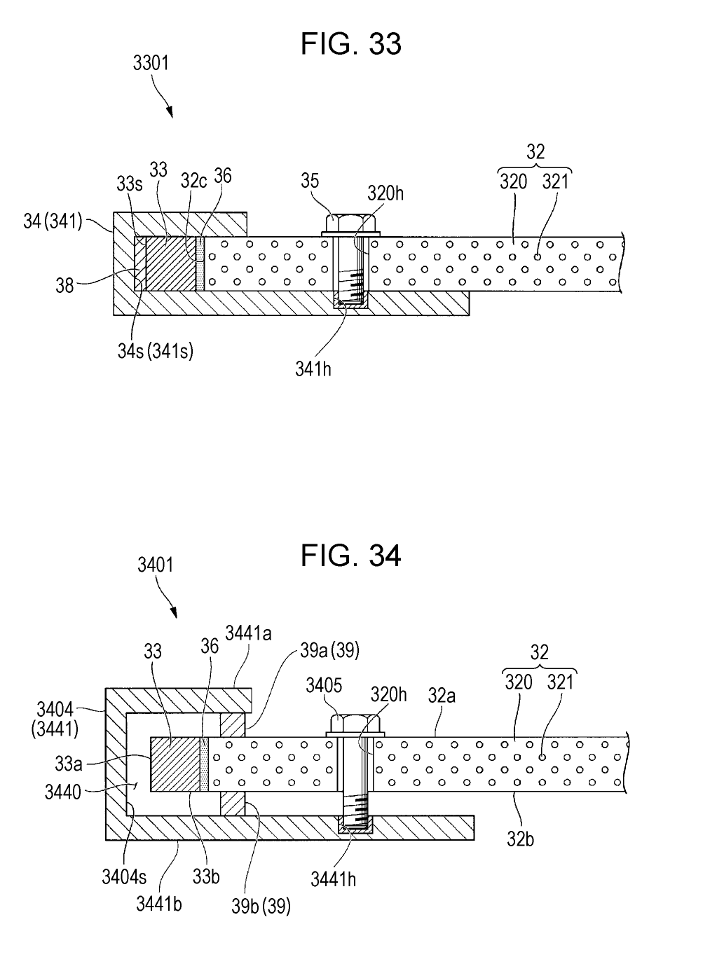

FIG. 33 is a cross-sectional view illustrating a solar cell module 3301 according to a sixteenth embodiment of the present invention, which corresponds to FIG. 28.

The basic configuration of the solar cell module 3301 of the present embodiment is the same as that of the thirteenth embodiment, but only a point in which a buffering layer 38 is formed between the inner wall surface 34s of the frame 34 and the surface 33s of the solar cell element 33 is different from the case of the thirteenth embodiment. Accordingly, description of the basic configuration of the solar cell module 3301 will not be repeated in the present embodiment.

In the present embodiment, as illustrated in FIG. 33, the buffering layer 38 is provided between the inner wall surface 341s of the frame 341 and the surface 33s of the solar cell element 33 without a space. Here, the configuration between the inner wall surface 34s of the frame 34 and the solar cell element 33 is described with reference to the figure illustrating that the buffering layer 38 is provided between the inner wall surface 341s of the first sub-frame 341 and the solar cell element 33 without a space. Further, the same buffering layer is provided between the inner wall surface of the second sub-frame 342 and the solar cell element 33 without a space. As the buffering material 38, urethane foam such as polyurethane can be used.

Accordingly, according to the solar cell module 3301 of the present embodiment, in a case where an impact is applied to the frame 34 or the light collector 32 due to the external force, the impact applied to the solar cell element 33 can be absorbed by the buffering layer 38. Therefore, it is possible to prevent damage of the solar cell element 33.

### Seventeenth Embodiment

FIG. 34 is a cross-sectional view illustrating a solar cell module 3401 according to a seventeenth embodiment of the present invention, which corresponds to FIG. 28.

The basic configuration of the solar cell module 3401 of the present embodiment is the same as that of the thirteenth embodiment, but only a point in which a reflective layer 39 (a first reflective layer 39a, a second reflective layer 39b) is provided between the light collector 32 and a frame 3404 is different from the case of the thirteenth embodiment. Accordingly, description of the basic configuration of the solar cell module 3401 will not be repeated in the present embodiment.

In the present invention, as illustrated in FIG. 34, the first reflective layer 39a is provided in a portion in which the light collector 32 and a top plate portion 3441a of a first sub-frame 3441. The first reflective layer 39a is provided in a portion in which the first main surface 32a of the light collector 32 faces the top plate portion 3441a of the first sub-frame 3441. Meanwhile, the second reflective layer 39b is provided in a portion in which the light collector 32 is overlapped with a bottom plate portion 3441b of the first sub-frame 3441. The second reflective layer 39b is provided in a portion facing the first reflective layer 39a by interposing the light-collection plate 32. As the first reflective layer 39a and the second reflective layer 39b, a reflective layer formed of a dielectric multilayer film such as ESR or a reflective layer made of a metal film such as Al, Cu, Au, or Ag may be used.

An air layer 3440 is provided in a portion in which the first reflective layer 39a and the second reflective layer 39b are not arranged in a state of being interposed between the light collector 32 and the first sub-frame 3441. Further, although not illustrated, the same reflective layer is provided between the light collector 32 and the second sub-frame. An air layer is provided in a portion in which the reflective layer is not arranged in a state of being interposed between the light collector 32 and the second sub-frame.

According to the solar cell module 3401 of the present embodiment, light propagating through the light collector 32 is reflected on the surface of the first reflective layer 39a, the surface of the second reflective layer 39b, and returns to the inside of the light collector 32 again. Since a refractive index difference between the refractive index of the light collector 32 and the refractive index of the air layer 3440 is large, the light propagating through the light collector 32 is easily totally reflected on the interface between the light collector 32 and the air layer 3440. Accordingly, light loss can be decreased. For example, when the refractive index of the light collector 32 is set as 1.5 and the refractive index of the air layer 3440 is set as 1.0, the critical angle on the interface between the light collector 32 and the air layer 3440 is approximately 42° from Snell's law.

Since the conditions of the critical angle is satisfied while the incident angle of light into the interface is larger than 42° which is the critical angle thereof, the light is totally reflected on the interface.

Further, according to the present embodiment, the air layer 3440 is provided between an inner wall surface 3404s of the frame 3404 and the surface 33s of the solar cell element 33 and the air layer 3440 is also provided between the top plate portion 3441a and an upper surface 33a of the solar cell element 33 or the bottom plate 441b and a lower surface 33b of the solar cell element 33. Accordingly, in a case where an impact is applied to the frame 3404 or the light collector 32 due to the external force, it is possible to prevent the impact from being applied to the solar cell element 33 because of the air layer 3440. Therefore, it is possible to prevent damage of the solar cell element 33.

### Eighteenth Embodiment

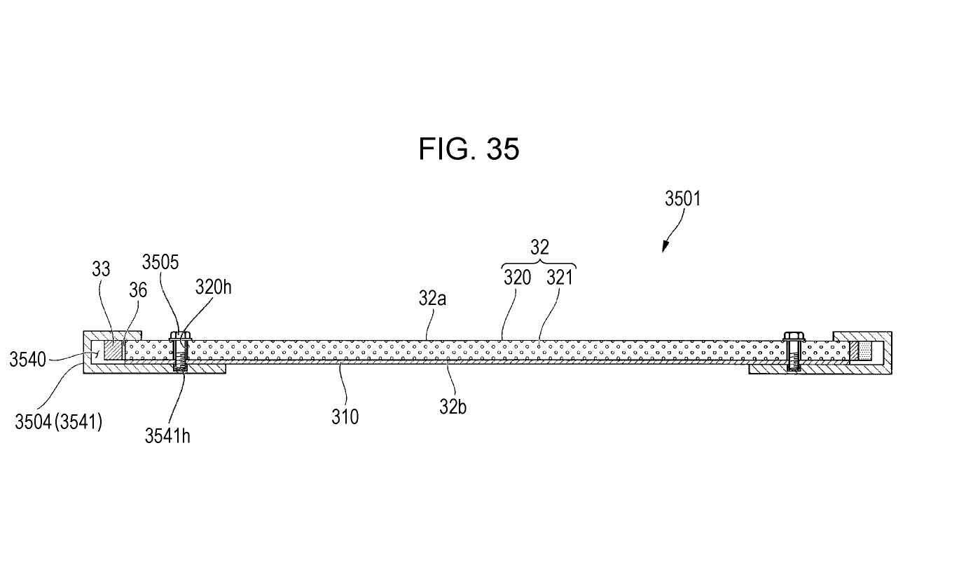

FIG. 35 is a cross-sectional view illustrating a solar cell module 3501 according to an eighteenth embodiment of the present invention.

The basic configuration of the solar cell module 3501 of the present embodiment is the same as that of the thirteenth embodiment, but only a point in which a reflective layer 310 is provided on the second main surface 32b side of the light collector 32 is different from the case of the thirteenth embodiment. Accordingly, description of the basic configuration of the solar cell module 3501 will not be repeated in the present embodiment.

In the present embodiment, as illustrated in FIG. 35, a reflector 310 is provided in a direct contact with the second main surface 32b of the light collector 32. The reflector 310 reflects light (light radiated from the phosphor) traveling toward the outside from the inside of the light collector 32 or light which is incident from the first main surface 32a and emitted from the second main surface 32b without being absorbed by the phosphor 321 toward the inside of the light collector 32. Further, the reflector 310 may be provided on the second main surface 32b through an air layer.

As the reflector 310, a reflector in which a reflective layer made of a metal film such as silver or aluminum is arranged on the surface of a substrate or a reflective layer made of a dielectric multilayer film such as ESR is arranged may be used. Further, the reflective layer may be a mirror reflective layer that performs mirror-reflection on incident light or may be a scattering reflective layer that performs scattering reflection on incident light. In a case where a scattering reflective layer is used for the reflective layer, since the light amount of light directly heading for a direction of the solar cell element 33 is increased, light collection efficiency with respect to the solar cell element 33 is increased so that the power generation amount is increased. Further, since reflected light is scattered, a change in power generation amount due to the time or the season is averaged. In addition, as the scattering reflective layer, microfoam polyethylene terephthalate (PET) (manufactured by Furukawa Electric Co., Ltd.) or the like can be used.

Since the reflector 310 is provided on the second main surface 32b of the light collector 32, an air layer 3540 is provided between the lower surface of the solar cell element 33 and the frame 3504.

According to the solar cell module 3501 of the present embodiment, light propagating through the light collector 32 is reflected on the surface of the reflector 310 and then returns to the inside of the light collector 32 again. Accordingly, light loss can be decreased. Moreover, in a case where an impact is applied to the frame 3504 or the light collector 32 due to the external force, it is possible to prevent the impact from being applied to the solar cell element 33 using the air layer 3540.

(Modified Example of Position Restricting Member)

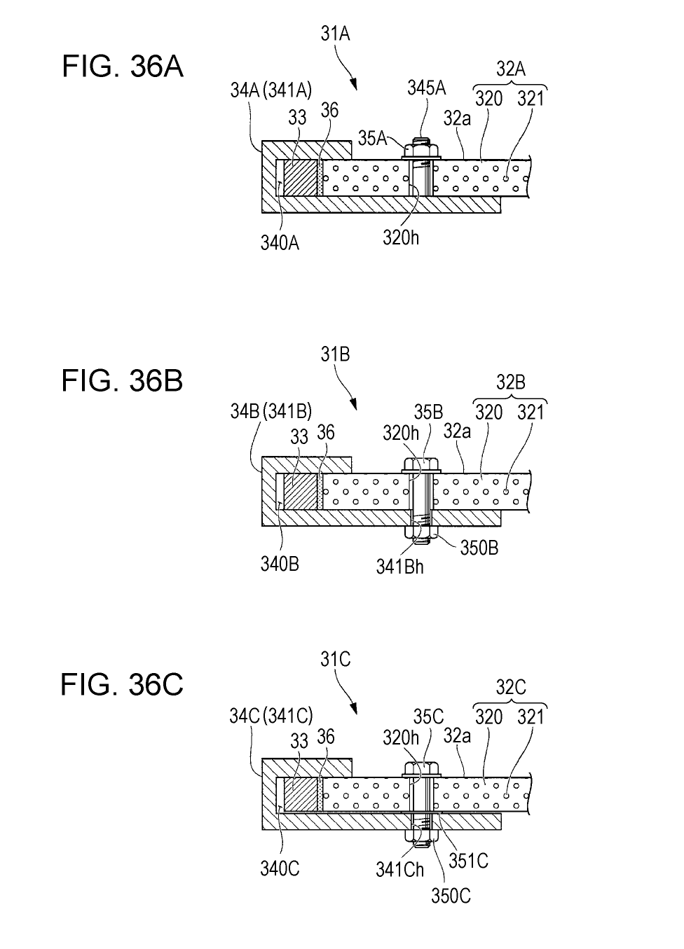

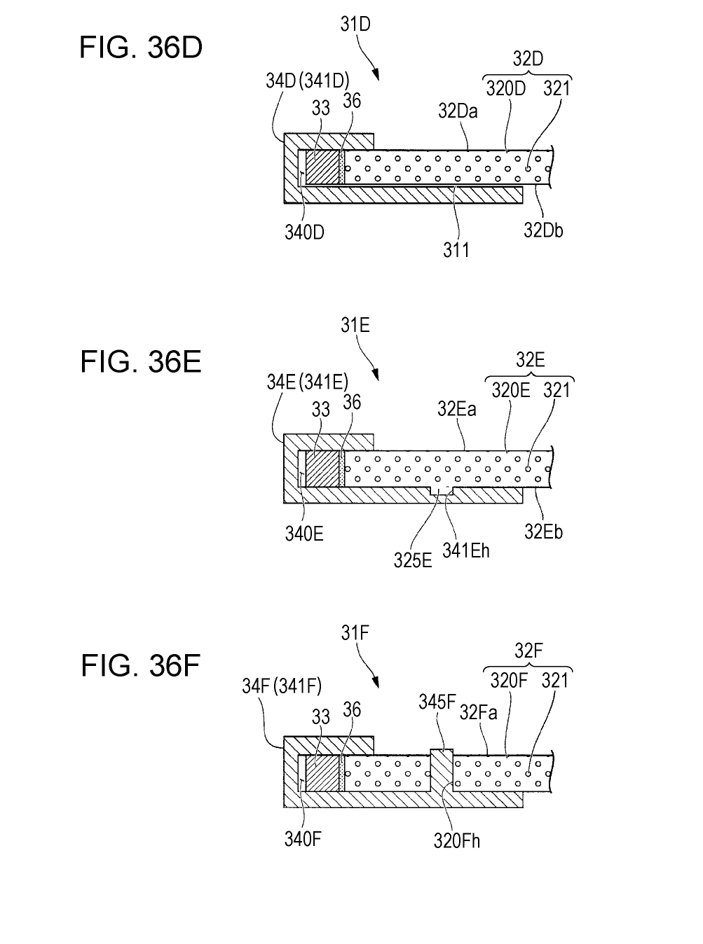

Hereinafter, modified examples of the position restricting member in the solar cell module of the above-described embodiment will be described with reference to FIGS. 36A and 36F.

### First Modified Example C

FIG. 36A is a cross-sectional view illustrating a first modified example of a position restricting member.

In the present embodiment, a penetrating member as the position restricting member is a screw and the screw is fixed to a screw hole of a frame through a through hole of a light collector. Meanwhile, the position restricting members of a solar cell module 31A of the present modified example are a pin 345A and a nut 35A as illustrated in FIG. 36. The pin 345A is provided in a portion in which the frame 34A is not overlapped with the through hole 320h. The nut 35A is fixed to a threaded portion of a tip portion of the pin 345A. In this manner, the relative position between the frame 34A and the light collector 32 in a direction parallel to the first main surface 32a and a direction vertical to the first main surface 32a is restricted.

Even in the solar cell module 31A of the present modified example, it is possible to prevent damage of the solar cell element 33.

### Second Modified Example C

FIG. 36B is a cross-sectional view illustrating a second modified example of a position restricting member.

The position restricting members of the solar cell module 31B of the present modified example are a bolt 35B and a nut 350B as illustrated in FIG. 36B. The through hole 341Bh is provided in a portion in which the frame 34B is overlapped with the through hole 320h. The tip portion of the bolt 35B protrudes from the through hole 341Bh of the frame 34B. The nut 350B is fixed to the tip portion of the bolt 35B. In this manner, the relative position between the frame 34B and the light collector 32 in a direction parallel to the first main surface 32a and a direction vertical to the first main surface 32a is restricted.

Even in the solar cell module 31B of the present modified example, it is possible to prevent damage of the solar cell element 33.

### Third Modified Example C

FIG. 36C is a cross-sectional view illustrating a third modified example of a position restricting member.

The position restricting members of a solar cell module 31C of the present modified example are a bolt 35C as illustrated in FIG. 36, a nut 350C, and a washer 351C. A through hole 341Ch is provided in a portion in which a frame 34C is overlapped with the through hole 320h. The washer 351C is arranged in a portion which is overlapped with the through hole 341Ch. The washer 351C is interposed between the light collector 32 and the frame 34. An air layer 340C is provided in a portion in which the washer 351C is not arranged in a state of being interposed between the light collector 32 and the frame 34C. A tip portion of the bolt 35C protrudes from the through hole 341Ch of the frame 34C. The nut 350C is fixed to the tip portion of the bolt 35C. In this manner, the relative position between the light collector 32 and the frame 34C in a direction parallel to the first main surface 32a and a direction vertical to the first main surface 32a is restricted.

Even in the solar cell module 31C of the present modified example, it is possible to prevent damage of the solar cell element 33. Moreover, in a case where an impact is applied to the frame 34C or the light collector 32 due to the external force, it is possible to prevent the impact from being applied to the solar cell element 33 using the air layer 340C.

### Fourth Modified Example C

FIG. 36D is a cross-sectional view illustrating a fourth modified example of a position restricting member.

The position restricting member of a solar cell module 31D of the present modified example is an adhesive 311. As illustrated in FIG. 36D, in the present modified example, a light collector 32D is not provided with a through hole. In addition a frame 34D is not provided with a screw hole or a through hole. The light collector 32D is bonded to the frame 34D by the adhesive 311. The adhesive 311 is arranged between a second main surface 32Db of the light collector 32D and the frame 34D. In this manner, the relative position between the light collector 32D and the frame 34D in a direction parallel to a first main surface 32Da and a direction vertical to the first main surface 32Da is restricted. A thermosetting adhesive such as an ethylene-vinyl acetate copolymer (EVA), an epoxy-based adhesive, a silicone-based adhesive, or a polyimide-based adhesive is preferable for the adhesive 311.

Since the adhesive 311 is provided between the second main surface 32Db of the light collector 32D and the frame 34D, an air layer 340D is interposed between the lower surface of the solar cell element 33 and the frame 34D.

Even in the solar cell module 31D of the present modified example, it is possible to prevent damage of the solar cell element 33. Moreover, in a case where an impact is applied to the frame 34D or the light collector 32D due to the external force, it is possible to prevent the impact from being applied to the solar cell element 33 using the air layer 340D.

Further, metal particles are not dispersed into the adhesive 311. In this manner, light propagating through the light collector 32 is reflected by the metal particles contained in the adhesive 311 and returns the inside of the light collector 32D again. Therefore, light loss can be decreased.

### Fifth Modified Example C

FIG. 36E is a cross-sectional view illustrating a fifth modified example of a position restricting member.

The position restricting member of a solar cell module 31E of the present modified example is a convex portion 325E. As illustrated in FIG. 36E, a concave portion 341Eh is provided in a part of a portion in which a frame 34E is overlapped with a light collector 32E. The convex portion 325E is provided in a portion in which the concave portion 341Eh is overlapped with a second main surface 32Eb of the light collector 32E. The convex portion 325E is fixed to the concave portion 341Eh by press-fitting. In this manner, the relative position between the light collector 32E and the frame 34E in a direction parallel to a first main surface 32Ea and a direction vertical to the first main surface 32Ea is restricted.

Even in the solar cell module 31E of the present modified example, it is possible to prevent damage of the solar cell element 33.

### Sixth Modified Example C

FIG. 36F is a cross-sectional view illustrating a sixth modified example of a position restricting member.

The position restricting member of a solar cell module 31F of the present modified example is a convex portion 345F. As illustrated in FIG. 36F, the convex portion 345F is provided in a portion in which a frame 34F is overlapped with a through hole 320Fh. The convex portion 345F is fixed to the through hole 320Fh by press-fitting. In this manner, the relative position between the light collector 32F and the frame 34F in a direction parallel to a first main surface 32Fa and a direction vertical to the first main surface 32Fa is restricted. Further, as a method of assembling the light collector 32F in the frame 34F, a method of making a first sub-frame 341F have a divided structure or a method of separating a convex portion 345F from the first sub-frame 341F to make a separate component can be exemplified.

Even in the solar cell module 31F of the present modified example, it is possible to prevent damage of the solar cell element 33.

(Modified Example of Light Collector)

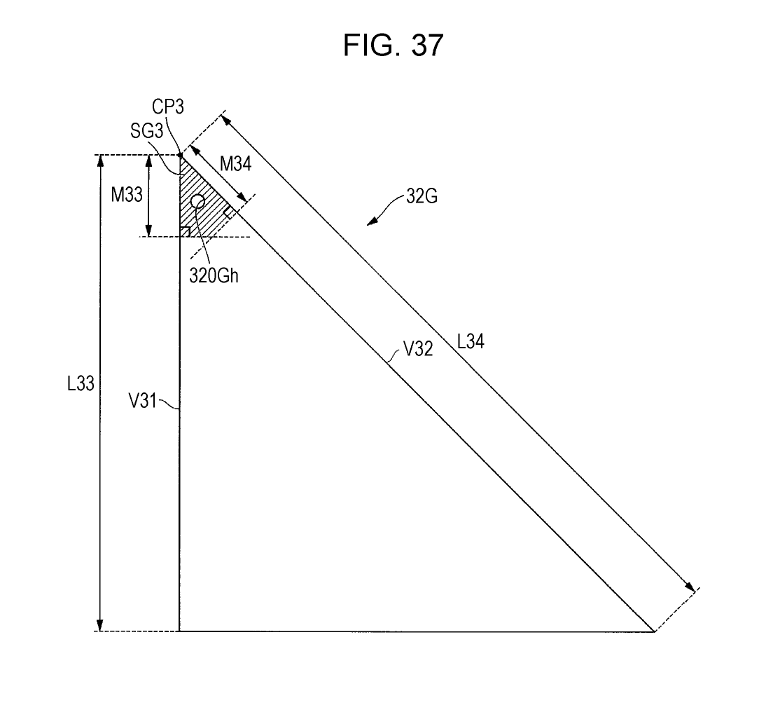

Hereinafter, a modified example of the light collector in the solar cell module of the above-described embodiments will be described with reference to FIG. 37.

### First Modified Example D

FIG. 37 is a plan view illustrating a first modified example of a light collector.

In the above-described embodiments, the light collector has a shape of a rectangle in a plan view. On the contrary, a light collector 32G of the present modified example has a shape of a triangle in a plan view as illustrated in FIG. 37. Through holes 320Gh are provided on three corners of the light collector 32G.

As illustrated in FIG. 37, an arrangement region of the through hole 320Gh to be arranged on one corner among three corners of the light collector 32G is set as SG3. The arrangement region SG3 has a shape of a square in a plan view. The length of a side V31 of the light collector 32G is set as L33. The length of a side V32 of the light collector 32G is set as L34. The length of the side of the arrangement region SG3 along the side V31 is set as M33. The length of the side of the arrangement region SG3 along the side V32 is set as M34. The top of the light collector 32G is set as CP3.

Here, similar to the equations (5) and (6), a relationship between the position of a direction of the side V31 of the light collector 32G and the light-collection amount of the light collector 32G is considered. Specifically, the length M33 of the side of the arrangement region SG3 is made to correspond to a distance from the top CP3 to a position in a direction along the side V31 in which the light collection amount is 10% of the maximum light collection amount.

In the same manner, the length M34 of the side of the arrangement region SG3 is made to correspond to a distance from the top CP3 to a position in a direction along the side V32 in which the light collection amount is 10% of the maximum light collection amount. At this time, the following equations (7) and (8) are satisfied.

M33=L33/10 (7)

M34=L34/10 (8)

In addition, distances M33 and M34 are set so as to satisfy the equations (7) and (8). By arranging the through hole 320Gh in the arrangement region SG3 whose distances M33 and M34 are set in the above-described manner, a decrease in light collection amount 32G is suppressed and the influence on the light collection efficiency can be minimized.

Even in the light collector 32G of the present modified example, a decrease in light collection amount is suppressed and the influence on the light collection efficiency can be minimized.

In addition, the shape of the light collector is not limited to a triangle in a plan view, but the shape thereof may be a shape of a polygon such as a pentagon in a plan view or a hexagon in a plan view.

[Solar Power Generation Device]

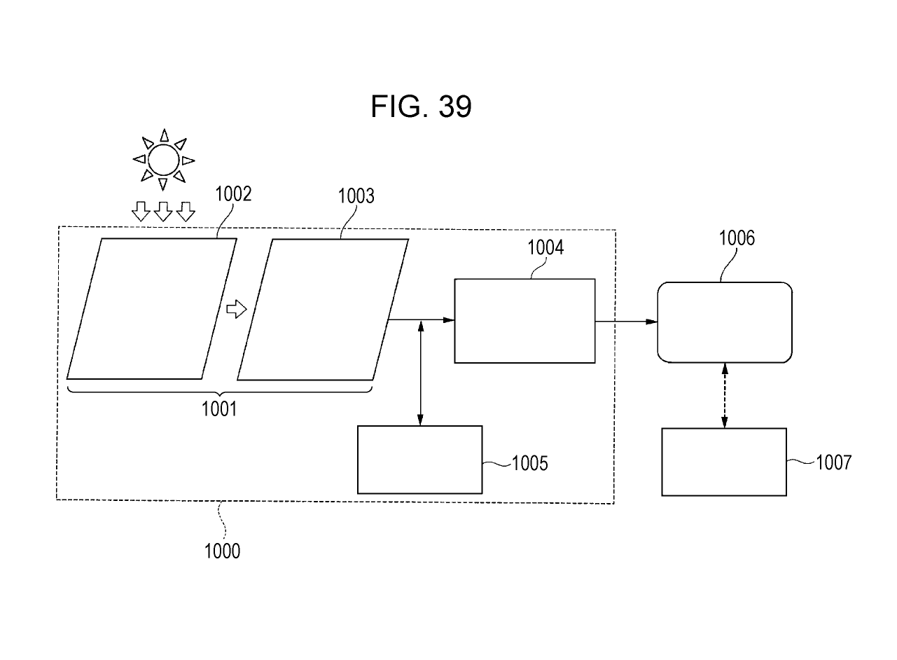

FIG. 39 is a configuration view schematically illustrating a solar power generation device 1000.

The solar power generation device 1000 includes a solar cell module 1001 which converts energy of solar light into power; an inverter (DC-AC converter) 1004 that converts DC power output from the solar cell module 1001 into AC power; and a storage battery 1005 which stores DC power output from the solar cell module 1001.

The solar cell module 1001 includes a light collector 1002 which collects solar light and a solar cell element 1003 which perform power generation using solar light collected by the light collector 1002. For example, the above-described solar cell module is preferably used as the solar cell module 1001.

The solar power generation device 1000 supplies power with respect to electronic equipment 1006 positioned in the outside. Power is supplied to the electronic equipment 1006 from an auxiliary power source 1007 if necessary.

Since the solar power generation device 1000 with such a configuration includes the solar cell module according to the present invention described above, high power generation efficiency can be easily maintained for a long period of time.

Hereinbefore, preferred embodiments according to the present invention have been described with reference to the accompanying figures, but the present invention is not limited thereto. The shapes or combinations of respective constituent members described in the examples above are merely examples and various modifications based on design requirements can be made within the range not departing from the scope of the present invention.

Further, detailed description on the shapes, numbers, arrangement, materials, and formation methods of respective constituent elements of the solar cell module is not limited to the above-described embodiments and can be appropriately changed.

For example, in the first to fourth embodiments, the example in which the through holes or the notched portions are provided on opposite sides with respect to the center line of the light collector, but the present invention is not limited thereto. Since a function of discharging rainwater on the main surface to the rear surface side is exhibited even when the through holes provided in the light collector or the through holes formed in the notched portion and the frame are positioned on the same side with respect to the center line of the light collector, contamination is hard to remain on the main surface and the solar cell module is capable of continuously performing power generation in an efficient manner.

### EXAMPLES

Hereinafter, the above-described embodiments will be described with reference to examples, but the present invention are not limited thereto.

### Examples 1A and 2A

In examples, the solar cell module illustrated in FIGS. 1A and 1B according to the first embodiment described above are prepared.

The phosphor light collector of the solar cell module used in Examples 1A and 2A has an external shape of a rectangle in a plan view with dimensions of 100 cm×100 cm×4 mm. In the phosphor light collector, PMMA (refractive index: 1.49) is used as a transparent base material and Lugen R305 (PL wavelength: 610 nm, absorption wavelength: up to 600 nm) is used as a phosphor.

Further, as the solar cell element of the solar cell module, a GaAs solar cell element (release voltage (Voc) 1V, power generation efficiency: 20%) having a size of the light receiving surface of 5 cm×4 mm is used. Such solar cell elements are arranged on the end surface of the phosphor light collector by being aligned in the long axis direction. Twenty solar cell elements are serially connected to one another per side of the phosphor light collector and then arranged on adjacent two sides. In the description below, twenty solar cell elements arranged on each side are referred to as a “solar cell element group” in some cases. one solar cell element group has a release voltage of 20 V. The solar cell element groups on adjacent sides are serially connected to one another.

In the solar cell module, reflective layers made of silver (Ag) are formed on remaining two sides on which the solar cell element groups are not formed.

Further, in the solar cell module, a through hole having a diameter of 1 cm which is vertical to the main surface is formed in the vicinity of the corner interposed between two sides on which the reflective layers are formed in the phosphor light collector. The through hole is provided in a position which is exposed from the frame in a plan view and is separated from the corner on the inner periphery of the frame by a distance of 3 cm in the diagonal direction. Moreover, a reflective layer made of Ag is formed on the surface of the through hole.

In such a solar cell module, an example in which the main surface is not subjected to a hydrophilic treatment is set as Example 1A and an example in which the main surface is subjected to a hydrophilic treatment is set as Example 2A. The contact angle of the main surface is 30° in the solar cell module of Example 1A and the contact angle of the main surface is 5° in the solar cell module of Example 2A.

In Examples, such a solar cell module is disposed in a state (θ11=30°, θ12=10°) of FIG. 4 described above.

### Reference Example

In the solar cell module used in Reference Example, crystalline Si solar cell elements whose size of a light receiving surface of 15 cm×15 cm are disposed in series by the number of 6×6, that is, 36 in total on the main surface having a size of 100 cm×100 cm with a shape of a rectangle in a plan view. Such solar cell module is disposed whose one side is inclined downward by 30°.

In Examples 1A and 2A, and Reference Example, water is wiped under the condition specified by ASTM G26 with respect to the main surface and set as a model of rainfall. The conditions are as follows. (conditions of rainfall model) pressure: 0.08 MPa to 0.13 MPa, water amount: 2100±100 mL/min, time of water injection: 18 minutes during irradiation for 120 minutes (water injection for 18 minutes+being left as it is for 102 minutes), quality of water: pH of 6.0 to 8.0, conductivity: 200 μs/cm or less, temperature of water: 16±5° C.

In Examples and Reference Examples, soil is arranged on the main surface of the solar cell module, water is repeatedly injected to the main surface of the solar cell module under the above-described conditions, and a state in which the soil is deposited on the solar cell module is schematically simulated. The same amount of soil is placed in Examples 1A and 2A and Reference Example, and the soil on the main surface is washed away by injecting water under the above-described conditions of the rainfall model. A cycle from the arrangement of soil to the injection of water is set as one set and this process is repeatedly performed by five sets. Subsequently, in regard to each of the solar cell modules, the initial states and the power generation amounts with solar light of 1 Sun (1000 W/m²) after soil is arranged on the main surface are compared to one another.

As a result of evaluation, in Example 1A, the soil is washed away due to the injection of water. The soil slightly remaining on the main surface is aggregated in sites during a drying process and then solidified into a bulk shape. The area with a bulk of soil reaches 15% of the area (hereinafter, also referred to as an “effective area”) of the phosphor light collector in a plan view exposed from the frame in a plan view and the power generation amount of the solar cell module is decreased from the initial state by 15%.

The soil is washed away by the injection of water even in Example 2A. The area of a bulk generated by the soil slightly remaining on the main surface is only 5% of the effective area of the phosphor light collector exposed from the frame in a plan view and the power generation amount of the solar cell module is decreased from the initial state only by 5%.

In Reference Example, the soil is deposited on 10% of the region from the lower end of the inclined main surface. The light transmittance of the region on which the soil is deposited is 30% from that of the initial state. In the solar cell module of Reference Example, since all of the solar cell elements are serially connected to one another, the power generation amount is 10% (a decrease of 90%) from that of the initial state due to the influence of the element whose property is degraded by the deposition of the soil.

From the above-described results, it is confirmed that both of prevention of contamination from remaining on the main surface and efficient power generation can be achieved by the present invention.

### Example B

Hereinafter, the above-described present embodiments will be described with reference to Example B and Comparative Example B, but the embodiments are not limited thereto.

The inventors of the present application verified the effects of the solar cell module of the present invention. Hereinafter, the verification results are described with reference to Table 1.

As the light collector, a plate having dimensions of a length of the long side of approximately 100 cm, a length of the short side of approximately 90 cm, and a thickness of 4 mm is used. A PMMA resin (refractive index: 1.49) is used as a plate material of the light collector. As the phosphor, Lumogen R305 (trade name, manufactured by BASF Corporation) is used.

As the frame, a frame with a configuration in which the light collector is interposed between the first main surface side and the second main surface side in the vertical direction is used. The thickness of the frame is set as approximately 2 mm. Al is used as the forming material of the frame.

As the solar cell module of “Comparative Example B,” a solar cell module in which the solar cell elements are fixed to both members of the light collector and the frame is used.

FIG. 26 is a cross-sectional view illustrating a solar cell module 21X of a comparative example. As illustrated in FIG. 26, the solar cell element 23X is bonded to a first main surface 22Xa of a light collector 22X by a transparent adhesive 27X. The inner wall surface of a top plate portion 24Xa of a frame 24X is in contact to the surface on the opposite side of the first main surface 22Xa of the solar cell element 23X. In this manner, in the solar cell module 21X of Comparative Example, the light collector 22X and the solar cell element 23X are fixed without a gap in a state of being interposed by the frame 24X. The position of the solar cell element 23X is restricted by pressing force of the frame 24X. Accordingly, the frame 24X, the light collector 22X, and the solar cell element 23X are rigidly fixed.

As the solar cell module of “Example B,” a solar cell module in which the solar cell element is fixed to one of members of the light collector and the frame is used.

### Example 1B

As the solar cell module, a solar cell module in which the solar cell element is fixed to the light collector is used. A solar cell module in which an air layer is formed between the inner wall surface of the top plate portion of the frame and the surface on the opposite side of the first main surface of the solar cell element is used. The solar cell module of Example 1B corresponds to the solar cell module 21 of the fifth embodiment.

### Example 2B

As the solar cell module, a solar cell module in which the solar cell element is fixed to the frame is used. A solar cell module in which a filler is filled between the light collector and the solar cell element is used. The solar cell module of Example 2B corresponds to the solar cell module 2501 of the tenth embodiment.

### Example 3B

As the solar cell module, a solar cell module in which the solar cell element is fixed to the frame is used. A solar cell module in which an air layer is formed between the light collector and the solar cell element is used. The solar cell module of Example 3B corresponds to the solar cell module 2601 of the eleventh embodiment.

In regard to Comparative Example B and each Example B, during a process of producing the solar cell module or at the time of usage, it is confirmed that whether the solar cell element is damaged, for example, cracks or fragment. Further, a temperature cycle test is performed on the solar cell element so that the damage of the solar cell element is confirmed. Moreover, in the temperature cycle test, the temperature of the solar cell module is changed by 50° C. or higher. The results thereof are listed in [Table 2].

TABLE 2

| | | Presence of damage of solar cell element | | |
|---|---|---|---|---|
| | | During production | At time | Temperature |
| | | process | of usage | cycle test |
| Comparative Example | | Present | Present | Present |
| B | | | | |
| Example B | 1B | Absent | Absent | Absent |
| | 2B | Absent | Absent | Absent |
| | 3B | Absent | Absent | Absent |

As listed in Table 2, in “Comparative Example B,” it is confirmed that the solar cell element is damaged during the process of producing the solar cell module and at the time of usage. For this reason, in Comparative Example B, it is considered that the light collector and the solar cell element are interposed without a gap by the frame and then fixed, there is no place for the stress, which is generated due to deflection, curvature, thermal expansion, or the like of the light collector, to escape so that the excessive stress is applied to the solar cell element in some cases.

On the contrary, in “Example B,” it is not confirmed that the solar cell element is damaged during the process of producing the solar cell module and at the time of usage in any of “Example 1B,” “Example 2B,” and “Example 3B.” Moreover, it is not confirmed the damage of the solar cell element during the temperature cycle test.

Further, the inventors of the present application verified the effects of a configuration in which a white scattering layer is formed on the surface of the frame by through a simulation. Hereinafter, the results of the simulation will be described with reference to Table 2.

As the solar cell module of “Comparative Example B,” a solar cell module in which a chromite treatment is applied to the surface of the frame is used. As the solar cell module of “Example B,” a solar cell module in which a white scattering layer is formed on the surface of the frame is used. The solar cell module of Example B corresponds to the solar cell module 2201 of the seventh embodiment.

In “Comparative Example B” and “Example B,” solar light of 1 Sun (100 mW/cm²) is directly incident on the solar cell module, and a surface temperature of the solar cell element and a decrease rate of the power generation amount are acquired. The results are listed in [Table 3].

TABLE 3

| | | Surface | |
|---|---|---|---|
| | | temperature of | Decrease rate of |
| | Surface of frame | solar cell element | power generation |
| Comparative | Chromite treatment | 70° C. | 20% |
| Example B | | | |
| Example B | Formation of white | 40° C. | 10% |
| | scattering layer | | |

In addition, in Table 3, the decrease rate of the power generation amount is based on the power generation amount measured when the surface temperature of the solar cell element is 25° C.

As listed in Table 3, the surface temperature of the solar cell element is increased by 70° C. in “Comparative Example B.” Further, the decrease rate of the power generation amount is 20%. On the contrary, the surface temperature of the solar cell element is increased by 40° C. in “Example B.” Further, the decrease rate of the power generation amount is only 10%.

From the results of “Comparative Example B” and “Example B”, it is understood that a decrease in power generation amount can be suppressed by forming a white scattering layer on the surface of the frame.

### Example C

Hereinafter, the above-described embodiments will be described with reference to Example C and Comparative Example C, but the present embodiments are not limited thereto.

The inventors of the present application verified the light collection efficiency of light on the end surface of the light collector through simulation. Hereinafter, the simulation results are described with reference to Table 2.

As the light collector, a plate having dimensions of a length of the long side of approximately 100 cm, a length of the short side of approximately 90 cm, and a thickness of 4 mm is used. A PMMA resin (refractive index: 1.49) is used as a plate material of the light collector. As the phosphor, Lumogen R305 (trade name, manufactured by BASF Corporation) is used.

As the light collector of “Comparative Example C,” a plate in which a through hole is not formed is used. As the light collector of “Example C,” a plate in which a through hole is formed is used.

### Example 1C

Four through holes are arranged on each corner of the light collector. A solar cell module in which a reflective film is not formed between the through hole and the screw is used. The solar cell module of Example 1C corresponds to the solar cell module 31 of the thirteenth embodiment.

### Example 2C

Four through holes are arranged in the center portion of the light collector. A solar cell module in which a reflective film is not formed between the through hole and the screw is used. The positions of the through hole of the solar cell module of Example 2C are different from those of the solar cell module of Example 1C.

### Example 3C

Four through holes are arranged on each corner of the light collector. A solar cell module in which a reflective film is formed between the through hole and the screw is used. The solar cell module of Example 3C corresponds to the solar cell module 3201 of the fifteenth embodiment.

### Example 4C

Four through holes are arranged in the center portion of the light collector. A solar cell module in which a reflective film is formed between the through hole and the screw is used. The positions of the through holes of the solar cell module of Example 4C are different from those of the solar cell module of Example 3C.

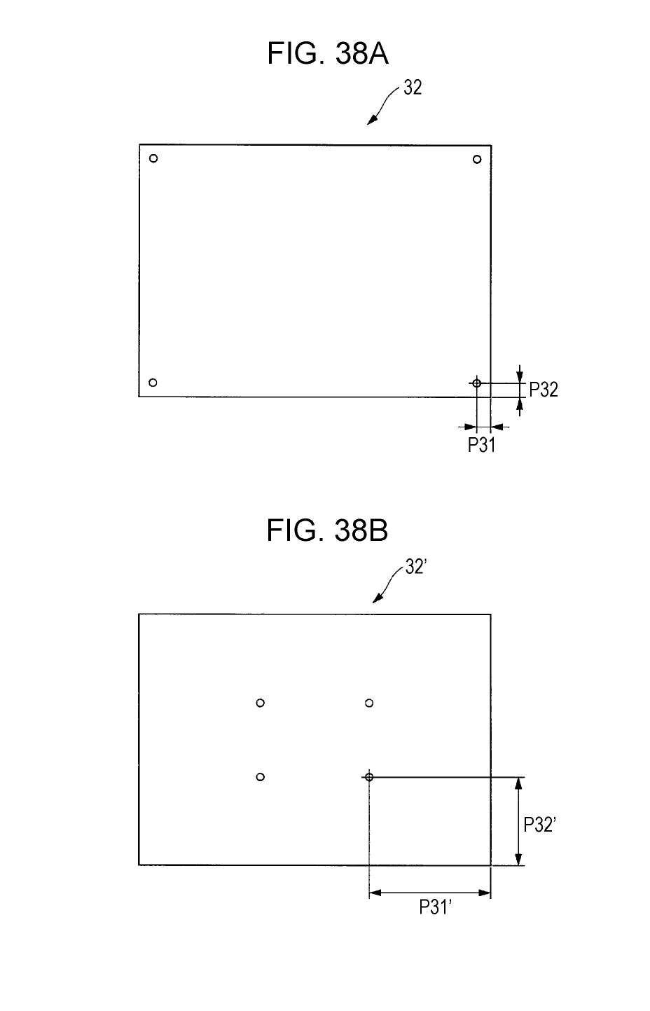

FIGS. 38A and 38B are schematic views illustrating the positions of the through holes provided in the light collector. FIG. 38A is a plan view illustrating the light collector 32 of Examples 1 and 3 in which the through holes are provided on four corners of the light collector. FIG. 38B is a plan view the light collector 32′ of Examples 2C and 4C in which the through holes are provided in the center portion of the light collector. In addition, in FIG. 38A, a symbol P31 represents a distance between the center of the through hole and the short side of the light collector 32. A symbol P32 represents a distance between the center of the through hole and the long side of the light collector 32. In FIG. 38B, a symbol P31′ represents a distance between the center of the through hole and the short side of the light collector 32′. A symbol P32′ represents a distance between the center of the through hole and the long side of the light collector 32′.

The “positions of the through holes” are set as follows. In the light collector 32, the distance P31 and the distance P32 are respectively set as 4 cm. In the light collector 32′, the distance P31′ is set as 33 cm and the distance P32′ is set as 30 cm. Moreover, the diameters of the through holes are respectively set as 4.5 mm in the light collector 32 and the light collector 32′.

In Comparative Example and each Example, the light collection efficiency of light with respect to the end surface of the light collector is acquired through tracking simulation of light beams. The results thereof are listed in [Table 4].

TABLE 4

| | | Pre- | Positions | Number | Pre- | Light |
|---|---|---|---|---|---|---|
| | | sence of | of | of | sence of | collection |
| | | through | through | through | reflective | efficiency |
| | | holes | holes | holes | film | (%) |
| Comparative | | Absent | — | 0 | — | 100 |
| Example C | | | | | | |
| Exam- | 1C | Present | Four corners | 4 | Absent | 98.9 |
| ple C | | | of light | | | |
| | | | collector | | | |
| | 2C | Present | Center portion | 4 | Absent | 98.7 |
| | | | of light | | | |
| | | | collector | | | |
| | 3C | Present | Four corners | 4 | Present | 99.6 |
| | | | of light | | | |
| | | | collector | | | |
| | 4C | Present | Center portion | 4 | Present | 99.9 |
| | | | of light | | | |
| | | | collector | | | |

Further, in Table 4, the light collection efficiency indicates that the light collection efficiency of the solar cell module of “Comparative Example C” is 100%. Moreover, values of the light collection efficiency of “Example 3C” and “Example 4C” are obtained by calculating the reflectance of the reflective film formed between the through hole and the screw as 100%.

As listed in Table 4, the results of the light collection efficiency of the solar cell module of “Example C” are as follows. The light collection efficiency of “Example 1C” is 98.9%. The light collection efficiency of “Example 2C” is 98.7%. The light collection efficiency of “Example 3C” is 99.6%. The light collection efficiency of “Example 4C” is 99.9%.

From the results of “Comparative Example C,” “Example 1C,” and “Example 2C,” it is confirmed that a decrease in light collection efficiency due to the through holes provided in the light collector is approximately 1.2% and the influence with respect to the light collection efficiency is exceedingly small. It is confirmed that the influence with respect to the light collection efficiency is small when the through holes are arranged on four corners of the light collector rather than the center portion of the light collector.

From the results of “Example 1C,” “Example 2C,” “Example 3C,” and “Example 4C,” it is confirmed that the light collection efficiency can be increased by 1% through arrangement of the reflective film between the through hole and the screw. In this manner, it is understood that a decrease in light collection efficiency can be suppressed when the reflective film is disposed between the through hole and the screw.

### INDUSTRIAL APPLICABILITY

The present invention can be applied to a solar cell module and a solar power generation device.

### REFERENCE SIGNS LIST

11A to 11G, 21, 31, 31A, 31B, 31C, 31D, 31E, 31F, 1001, 1100, 1110, 1500, 2101, 2201, 2301, 2401, 2501, 2601, 2701, 2101A, 2101B, 2101C, 3101, 3201, 3301, 3401, 3501 SOLAR CELL MODULE
12A TO 12G, 22, 32, 32D, 32E, 32F, 10021200, 1210, 1501, 2302, 2402, 3202 LIGHT COLLECTOR
12a FIRST END SURFACE
12b SECOND END SURFACE
12c THIRD END SURFACE
12d FOURTH END SURFACE
12x MAIN SURFACE
12y REAR SURFACE
12z END SURFACE
13, 13a TO 13d, 25, 39, 212, 2105, 2112, 2112C, 2305, 2312, 2412, 2712 REFLECTIVE LAYER
14, 14a TO 14g, 23, 33, 1400, 1410, 1502, 2503, 2603, 2703, 1003 SOLAR CELL ELEMENT
15: FRAME
16: BASE MATERIAL
17: PHOSPHOR
22a, 32a, 32Da, 32Ea, 32Fa, 2302a, 2402a FIRST MAIN SURFACE
22b, 32b, 32Db, 32Eb, 2302b, 2402b SECOND MAIN SURFACE
22c, 32c, 2302c, 2402c END SURFACE
24, 2104, 2304, 2404, 2704 FRAME
33s SURFACE (SURFACE ON OPPOSITE SIDE OF END SURFACE OF LIGHT COLLECTOR OF SOLAR CELL ELEMENT)
34, 34A, 34B, 34C, 34D, 34E, 34F, 3404, 3504 FRAME
35, 3105, 3205 SCREW (PENETRATING MEMBER, POSITION RESTRICTING MEMBER)
35A, 350B, 350C NUT (POSITION RESTRICTING MEMBER)
35B, 35C BOLT (POSITION RESTRICTING MEMBER)
37, 3105R REFLECTIVE FILM
120, 121, 125 to 127, 320h, 3220h THROUGH HOLE
120a SURFACE
122 to 124 NOTCHED PORTION
130 JOINING MEMBER
38, 216, 2316 BUFFERING LAYER (ELASTIC MEMBER)
39a FIRST REFLECTIVE LAYER (REFLECTIVE LAYER)
39b SECOND REFLECTIVE LAYER (REFLECTIVE LAYER)
218 DRYING AGENT
310 REFLECTOR
311 ADHESIVE (POSITION RESTRICTING MEMBER)
340 SPACE
340C, 340D, 3440, 3540 AIR LAYER
341, 3441 FIRST SUB-FRAME
341h SCREW HOLE
341s INNER WALL SURFACE
342 SECOND SUB-FRAME
345A PIN (POSITION RESTRICTING MEMBER)
345F CONVEX PORTION (POSITION RESTRICTING MEMBER)
1005 STORAGE BATTERY
1006 ELECTRONIC EQUIPMENT
1007 AUXILIARY POWER SOURCE
2304d INCLINED SURFACE (INCLINED SURFACE ON INNER SURFACE OF FRAME)
2540 FILLER
2640 AIR LAYER
2741 UPPER FRAME
2742 LOWER FRAME
C1, C11 TO C16 CENTER LINE
FL1 FLUORESCENCE
L1 EXTERNAL LIGHT
L11, La1 FIRST REFERENCE LINE
L12, Lc1 OPPOSING LINE
Lb1 SECOND REFERENCE LINE
S11, Sb1 LINE SEGMENT
Sa1 BOWSTRING
T1 GROOVE
T11 INCLINED SURFACE
T12 SURFACE
T13 RIDGE LINE

1-65. (canceled)

66. A solar cell module comprising:
a light collector which includes a main surface and an end surface, allows external light to be incident from the main surface, and allows the light to propagate through the inside to be emitted from the end surface;
a solar cell element facing the end surface and receiving the light emitted from the end surface to perform photoelectric conversion; and
a frame which holds a peripheral edge portion of the light collector,
wherein the light collector includes a through hole which is provided in the inside in relation to the frame when seen from the main surface side and penetrates the light collector in a thickness direction, or includes a notched portion which is provided in the inside in relation to the frame when seen from the main surface side and extends from the main surface to a rear surface in the peripheral edge portion, and
the light collector is a phosphor light collector containing a phosphor which absorbs incident light and emits fluorescence.

67. The solar cell module according to claim 66, wherein the through hole or the notched portion and the solar cell element are provided on opposite sides with respect to a center line of the light collector.

68. The solar cell module according to claim 66, wherein the main surface is subjected to a hydrophilic treatment.

69. The solar cell module according to claim 66,
wherein the light collector includes the notched portion,
a plurality of the light collectors allow each of the notched portions to be adjacent to one another to be arranged in a concentric circle shape such that a large-sized light collector in a concave shape is formed, and
the plurality of notched portions are integrated with one another to form a through hole penetrating the large-sized light collector.

70. The solar cell module according to claim 66,
wherein at least the main surface of the light collector is in a concave shape, and
the through hole which penetrates the light collector in the thickness direction is provided in a position most recessed in the main surface.

71. The solar cell module according to claim 66, further comprising a position restricting member that restricts a relative position between the light collector and the frame,
wherein the light collector includes the through hole,
the through hole is provided in a portion in which the light collector is overlapped with the frame when seen from a direction normal to the main surface, and
the position restricting member is provided in the through hole.

72. The solar cell module according to claim 71,
wherein a screw hole is provided in a portion in which the frame is overlapped with the through hole, and
the screw is fixed to the screw hole through the through hole.

73. The solar cell module according to claim 72,
wherein the frame includes a first sub-frame and a second sub-frame, and
the screw hole is provided in a portion in which the first sub-frame is overlapped with the through hole.

74. The solar cell module according to claim 71, wherein a reflective film is formed on the surface of the position restricting member.

75. The solar cell module according to claim 71,
wherein a shape of the light collector is a rectangle in a plan view,
when a length of a long side of the light collector is set as L31, a length of a short side of the light collector is set as L32, a distance from the short side of the light collector to a position in which the light collection amount is 10% of the maximum light collection amount in the longitudinal direction is set as M31, and a distance from the long side of the light collector to a position in which the light collection amount is 10% of the maximum light collection amount in the short direction is set as M32, the distance M31 satisfies a relationship of “M31=L31/10” and the distance M32 satisfies a relationship of “M32=L32/10”, and
in this case, the through hole is arranged in an arrangement region to which the distances M31 and M32 are set.

76. The solar cell module according to claim 71, wherein the frame is formed so as to cover the solar cell element.

77. The solar cell module according to claim 76, wherein an inner wall surface of the frame is separated from the solar cell element.

78. The solar cell module according to claim 77, wherein a space is provided between the inner wall surface of the frame and a surface on the opposite side of the end surface of the solar cell element.

79. The solar cell module according to claim 78, wherein when an interval of the space is set as d3, a maximum value of a temperature difference of the light collector due to a change in temperature per unit time is set as ΔT, a distance from a position restricting portion to the end surface of the light collector is set as L3, and a linear expansion coefficient of the light collector is set as K, the interval d3 satisfies a relationship of “d3>ΔT·L3·K.”

80. The solar cell module according to claim 77, wherein a buffering material is provided between the inner wall surface of the frame and the surface on the opposite side of the end surface of the solar cell element.

81. The solar cell module according to claim 71, wherein a reflective layer is provided between the light collector and the frame.

82. The solar cell module according to claim 81,
wherein the reflective layer is arranged in a portion between the light collector and the frame, and
a portion in which the reflective layer is not arranged is provided with an air layer between the light collector and the frame.

83. The solar cell module according to claim 71, wherein a reflector which reflects light transmitted from a second main surface side of the light collector is provided on the second main surface side which is the opposite side of the first main surface of the light collector.

84. A solar power generation device comprising the solar cell module according to claim 66.
